(19) United States
(12) Patent Application Publication
(10) Pub. No.: US 2002/0174286 A1
(43) Pub. Date: Nov. 21, 2002

(54) Ic card recording and/or reproducing device

(76) Inventor: Renji Tamura, Kanagawa (JP)

Correspondence Address: Jay H Maioli, Cooper & Dunham, 1185 Avenue of the Americas, New York, NY, 10036, US

(21) Appl. No.: 10/069,088

(22) PCT Filed: Jun. 8, 2001
(86) PCT No.: PCT/JP01/04876

(30) Foreign Application Priority Data
Jun. 9, 2000 (JP) 2000-174307
Jun. 13, 2000 (JP) 2000-177643
Jun. 26, 2000 (JP) 2000-191615
Sep. 12, 2000 (JP) 2000-277020

(51) Int. Cl. G06F 12/00; G11C 5/00

(52) U.S. Cl. 711/4; 711/100

(57) ABSTRACT

Disclosed herein is an apparatus for recording and/or reproducing data in and/or from memory cards used as recording media, each shaped like a plate and incorporating a memory. The apparatus comprises a storage section, a writing/reading section, and a transport mechanism. The storage section holds a plurality of memory cards. The writing/reading section writes and read data into and from the memory cards held in the storage section. The transport means moves either the storage section or the writing/reading section, so that data may be written into and read from the memories incorporated in the memory card that are held in the storage section. The transport means is driven, removing any selected card from the storage section, and data is read from or written into the card selected. The storage section is so designed that a part of the label on the memory card is seen from outside. The label can therefore be read, though the memory card is held in the storage section.

### TECHNICAL FIELD

The present invention relates to an apparatus to which a plurality of IC cards may be connected and which record data and/or reproduce data in and/or from these IC cards. More particularly, the invention relates to an apparatus for recording and/or reproducing data in and/or from a plurality of IC cards, each incorporating a nonvolatile memory.

### BACKGROUND ART

Hitherto, apparatuses for recording and/or reproducing data in and/or from IC cards, each using a semiconductor memory such as a flash memory as a storage element, have an IC card slot in the operating surface of the main body. Each apparatus comprises a loading mechanism provided in the main body and designed to load an IC card inserted through the IC card slot. A data-recording and/or reproducing apparatus that can hold a plurality of IC cards has a plurality of slots and a plurality of loading mechanisms associated with the slots, respectively. In order to know the contents recorded in his or her IC card by using a data-recording and/or reproducing apparatus of this type, a user pulls the IC card from the main body and reads the data written on the label attached to the IC card. Alternatively, the user may operates the apparatus, causing the apparatus to read the data from the IC card inserted in its main body and to display the data at its display section.

With the data-recording/reproduction apparatus described above, the user needs to pull the IC card from the main body in order to confirm the contents of the IC card. It is troublesome for the user to take the IC card out of the main body of the apparatus. Alternatively, the user needs to operate the apparatus, causing he apparatus to read the data from the IC card inserted in its main body and to display the data at its display section. To operate the apparatus is troublesome, too.

Every time the user pulls the IC card from the main body to confirm the contents recorded in the IC card, the terminal section of the IC card contacts the connection terminals of the data-recording and/or reproducing apparatus. As this contact is repeated, the terminals of the IC card and those of the apparatus will quickly wear due to friction.

Since IC cards are small, each user likely have more and more IC cards. It is tedious for the user to manage the use of IC cards well.

IC cards have but a smaller storage capacity than disc-shaped recording media such as optical discs. One IC card cannot store such a great amount of data as a plurality of music data items that a disc-shaped recording medium can hold. A plurality of IC cards must be used to record the music data that is usually recorded in a single disc-shaped recording medium.

Hitherto, IC cards must be used one by one. It is tiresome for users to insert and pull IC cards, one by one, into and from the apparatus.

### DISCLOSURE OF THE INVENTION

Accordingly, an object of this invention is to provide an apparatus that records data and/or reproduces data in and/or from IC cards and into which a plurality of IC cards can be inserted each with a label visually recognizable from outside, thereby enhancing the operability of the apparatus.

Another object of the present invention is to provide an apparatus which records data and/or reproduces data in and/or from IC cards, which has a card storage mechanism for holding a plurality of IC cards, thus making it easy to manage the IC cards, and which can record or reproduce a great amount of data by using a plurality of IC cards.

To achieve the objects described above, an apparatus according to the invention is designed to record and/or reproduce data in and/or from memory cards used as recording media, each shaped like a plate and incorporating a memory. The apparatus comprises a receptacle and a transmitting/receiving section. The receptacle holds the memory cards in such a position that a part of the label on the each memory card can be seen from outside. The transmitting/receiving section can transmit and receive data to and from the memory cards held in the receptacle. Data can be written and read into and from any memory card through the transmitting/receiving section.

The recording and/or reproducing apparatus may have a stepwise groove that is made in any one surface of the main body. The groove has steps, each holding one storage means, holding the transmitting/receiving section at one end and having an inclined part at the other end. The memory card inserted into the storage section held in the lowest stage of the stepwise groove is guided along the inclined part to connect the terminal of the memory card to the transmitting/receiving section.

The recording and/or reproducing apparatus according to the invention may further comprises control means for controlling the reading section provided in a memory card connected to the transmitting/receiving means of any storage section, thereby causing the reading section to access an address in the memory incorporated in the memory card, in accordance with a user's instruction, thereby to read the data stored at the address provided in the memory.

The control means controls the writing section provided in a memory card connected to the data-transmitting/receiving section of any storage section, thereby causing the writing means to access an address in the memory incorporated in the memory card, in accordance with a user's instruction, thereby to write the data at the address provided in the memory.

Further, the control means transfers a command and an address in the memory, to the memory card via the transmitting/receiving section in accordance with the user's instruction, said command designating the reading or writing of data from or into the memory and said address being one at which the reading or writing of data is to be initiated.

The recording and/or reproducing apparatus may further comprise detecting means and a setting section. The detecting means is provided to detect the memory cards stored in said plurality of storage sections. The setting section is provided to set the order in which the memory cards should be subjected to data reproduction. The control means controls the memory cards such that the memory cards are accessed in the order set by the setting section, thereby to read data from the memory cards.

The recording and/or reproducing apparatus according to the invention may further comprise data-source designating means and data-destination means. The data-source designating means is provided to designate one of the memory cards stored in the storage sections, from which data should be transmitted, and to designate a track stored in the memory provided in the memory card designated. The data-destination designating means is provided to designate another of the memory cards stored in the storage sections, to which data should be transmitted. The control means controls the memory cards, whereby the tracks are read from the memory incorporated in the memory card designated by the data-source designating means and the tracks are written in a vacant region of the memory incorporated in the memory card designated by the data-destination designating means.

A recording and/or reproducing apparatus according to the invention comprises: a storage section configured to store a plurality of memory cards, each shaped like a plate and incorporating a memory; a writing/reading section configured to write and read data into and from the memory cards stored in the storage section; and a transport mechanism for moving the storage section and the writing/reading section relative to each other, thereby to set the writing/reading section at a position where data can be written and read into and from the memory cards stored in the storage section.

A recording and/or reproducing apparatus according to this invention comprises: a plurality of storage sections provided on any surface of the main body of the apparatus, for storing a plurality of memory cards shaped like a plate and each incorporating a memory and having a label, each so positioned that a part of the label is seen from outside the apparatus; receiving/transmitting means provided in each of the storage section and configured to receive and transmit data from and to the memory card stored in the storage section; a transport mechanism configured to move the storage sections between an insertion/removal position where the memory cards are inserted and removed into and from the storage sections, and a writing/reading position where data is written and read into and from the memory cards; and a plurality of grooves made in any surface of the main body of the apparatus, for receiving the storage means, respectively, that can be moved by the transport mechanism.

The recording and/or reproducing apparatus may further comprise a holding mechanism that hold the memory cards stored in the storage section. The holding mechanism has a holding member and a cam section. The holding member is designed to rotate between a support position where it supports the memory cards and a non-support position where it does not support the memory card. The cam section is provided on the main body of the apparatus and designed to rotate the holding member to the support position when the storage section moves to the writing/reading position.

An apparatus according to the present invention is designed to record and/or reproduce data in and/or from memory cards used as recording media, each shaped like a plate and incorporating a memory. This apparatus comprises: a plurality of storage sections provided in the main body of the apparatus, for storing a plurality of memory cards; a receiving/transmitting section provided at one end of the storage sections and configured to receive and transmit data from and to the memory cards stored in the storage means; and a support mechanism supporting the storage sections, allowing the storage sections to rotate between an insertion/removal position where the memory cards are inserted and removed into and from the storage sections, and a storage position where the memory cards are held in the storage sections.

An apparatus according to this invention is designed to record and/or reproduce data in and/or from memory cards used as recording media, each shaped like a plate and incorporating a memory. The apparatus comprises a storage mechanism and a holding section. The storage mechanism has a receptacle, a support plate, a bias member, and a stopper section. The receptacle is configured to hold the memory cards, each shaped like a plate and incorporating a memory, and having an opening through which the memory cards can be inserted and removed. The support plate is provided in the receptacle to move in the direction in which the memory cards are arranged one above another and configured to support the memory cards. The bias member biases the support plate toward the opening. The stopper section is configured to inhibit the support plate biased by the bias member from moving. The holding section holds the storage mechanism and has a data-transmitting/receiving section for transmitting and receiving data to and from the transmitting/receiving section provided at one end of each memory card.

The other objects of the invention and the specific advantages of the invention will be apparent from the embodiments that will be described below.

### BRIEF DESCRIPTION OF THE DRAWINGS

FIG. 1 is a perspective view of an IC card that is used in a recording/reproducing apparatus according to the present invention;

FIG. 2 is a perspective view of the IC card, as seen from its bottom;

FIG. 3 is a block diagram showing the internal structure of the IC card;

FIG. 4 is a perspective view of the recording/reproduction apparatus according to the present invention;

FIG. 5 is an exploded view, showing the card holding section for holding an IC card;

FIG. 6 is a plan view of the card holding member that assumes an IC-card insertion/removal position;

FIG. 7 is a sectional view, illustrating an IC card being inserted into the card holding member;

FIG. 8 is a plan view, depicting an IC card inserted in the card holding member located at the IC-card insertion/removal position;

FIG. 9 is a plan view, showing the card holding member holding an IC card and moved to the recording/reproducing position;

FIG. 10 is a sectional view, illustrating the card holding member holding an IC card and moved to the recording/reproducing position;

FIG. 11 is a perspective view showing the major components of the card holding mechanism that moves an IC card into the card holding member located at the recording/reproducing position;

FIG. 12 is a perspective view of the card holding mechanism and the card holding member holding the IC card and moved to the recording/reproducing position;

FIG. 13 is a block diagram of the recording/reproduction apparatus according to the present invention;

FIG. 14 is a diagram explaining the interface between an IC card and the recording/reproduction apparatus;

FIG. 15 is a flowchart explaining the continuous reproduction mode in which the apparatus continuously reproduces data from a plurality of IC cards;

FIG. 16 is a flowchart explaining a transfer-mode process of transferring the data recorded in one IC card to another IC card;

FIG. 17 is a perspective view of another example of a card holding section, and FIG. 18 is a sectional view thereof;

FIG. 19 is a perspective view of another recording/reproduction apparatus according to the present invention;

FIG. 20 is a perspective view showing major components, for explaining the card holding section of the recording/reproduction apparatus;

FIG. 21 is a diagram for explaining the card holding section which holds an IC card;

FIG. 22 is a block diagram of the recording/reproduction apparatus shown in FIG. 19;

FIG. 23 is a perspective view of another recording/reproduction apparatus according to this invention;

FIG. 24 is a perspective view of the storage mechanism provided in the card holding section of the recording/reproduction apparatus;

FIG. 25 is a perspective view of a further recording/reproduction apparatus according to the present invention;

FIG. 26 is a sectional view of the storage mechanism provided in the card holding section of the recording/reproduction apparatus;

FIG. 27 is a sectional view of the storage mechanism holding no IC cards;

FIG. 28 is a sectional view of the storage mechanism holding an IC cards;

FIG. 29 is a sectional view illustrating the card holding section provided in the main body of the apparatus and the storage mechanism set in the card holding section;

FIG. 30 is a block diagram of the recording/reproduction apparatus mentioned above;

FIG. 31 is a perspective view of major components, for explaining the another recording/reproduction apparatus according to this invention;

FIG. 32 is a perspective view of the storage mechanism of the recording/reproducing apparatus mentioned above;

FIG. 33 is a sectional view of the storage mechanism holding no IC cards;

FIG. 34 is a sectional view of the storage mechanism holding IC cards;

FIG. 35 is a perspective view showing major component, for explaining the cover that closes and opens a recess provided in the front of the main body of the apparatus and configured to hold the storage mechanism;

FIG. 36 is an exploded view of the operation mechanism for moving the storage mechanism;

FIG. 37 is a perspective view depicting major components, illustrating the storage mechanism moved, by the operation mechanism, to a position outside the main body, where IC cards can be inserted into and removed from the main body;

FIG. 38 is a perspective view depicting major components, showing the storage mechanism moved, by the operation mechanism, to a position within the main body, where IC cards can be stored;

FIG. 39 is a sectional view illustrating the card holding section provided in the main body of the apparatus and the storage mechanism set in the card holding section;

FIG. 40 is a perspective view of another recording/reproduction apparatus according to the invention, which uses IC cards as recording media;

FIG. 41 is a perspective view showing the card holding members provided in the recording/reproduction apparatus and the storage housing for storing IC cards stacked one above another;

FIG. 42 is a perspective view of a connector to which an IC card is connected;

FIG. 43 is a perspective view explaining an elevator mechanism that moves up and down the storage housing;

FIG. 44 is a diagram explaining the operation of the elevator mechanism; FIG. 44A showing the storage housing at the lowest stage, FIG. 44B illustrating the storage housing moving up toward the second stage, and FIG. 44C depicting the storage housing set at the second stage;

FIG. 45 is a perspective view of a loading mechanism that moves the members holding IC cards, between a card storage position and a recording/reproducing position;

FIG. 46 is a perspective view of an ejecting mechanism that moves the members holding IC cards, between a storage position and a card-replacing position;

FIG. 47 is a diagram explaining the relation between the rack gear provided in a holding member and the gear provided in the ejecting mechanism;

FIG. 48 is a block diagram showing the recording/recording apparatus and the circuit configured to record data on and reproduce data from IC cards;

FIG. 49 is a diagram showing the holding member at the address #1, moved to the card-replacing position;

FIG. 50 is a diagram depicting the holding member at the address #1, moved to the storage position;

FIG. 51 a diagram representing the holding member at the address #1, lifted to a position from which it can be moved to the recording/reproducing position;

FIG. 52 is a diagram showing the holding member at the address #1, moved to the recording/reproducing position;

FIG. 53 is a diagram another configuration of a recording/reproduction apparatus according to the present invention;

FIG. 54 is a perspective view of an IC card that exchange data by radio with the recording/reproduction apparatus;

FIG. 55 is a side view of the recording/reproduction apparatus illustrated in FIG. 53;

FIG. 56 is a plan view of a storage unit designed to store IC cards;

FIG. 57 is a block diagram illustrating the circuit configuration of the transmitting/receiving section provided in the recording/reproduction apparatus;

FIG. 58 is a circuit diagram of an amplitude-modulation/amplification circuit; and

FIG. 59 is a block diagram representing the circuit configuration of the transmitting/receiving section provided in an IC card.

### BEST MODE FOR CARRYING OUT THE INVENTION

Recording/reproduction apparatuses will be first described, which the present applicant has applied for patent and which is designed to record data on and reproduce data from IC cards, each incorporating a nonvolatile memory.

U.S. patent application Ser. No. 09/523,280 filed by the applicant discloses a recording/reproduction apparatus. The apparatus implements a seamless access to a plurality of IC cards. The apparatus can therefore continuously record on and reproduce data from the IC cards.

Japanese Patent Application No. 2000-126262 filed by the applicant, too, discloses a recording/reproduction apparatus. This apparatus has grooves, in which IC cards of different shapes are fitted. The apparatus can access to the IC cards of different types.

Recording/reproduction apparatuses according to the present invention, which record data on and reproduce data from IC cards, will be described with reference to the accompanying drawings.

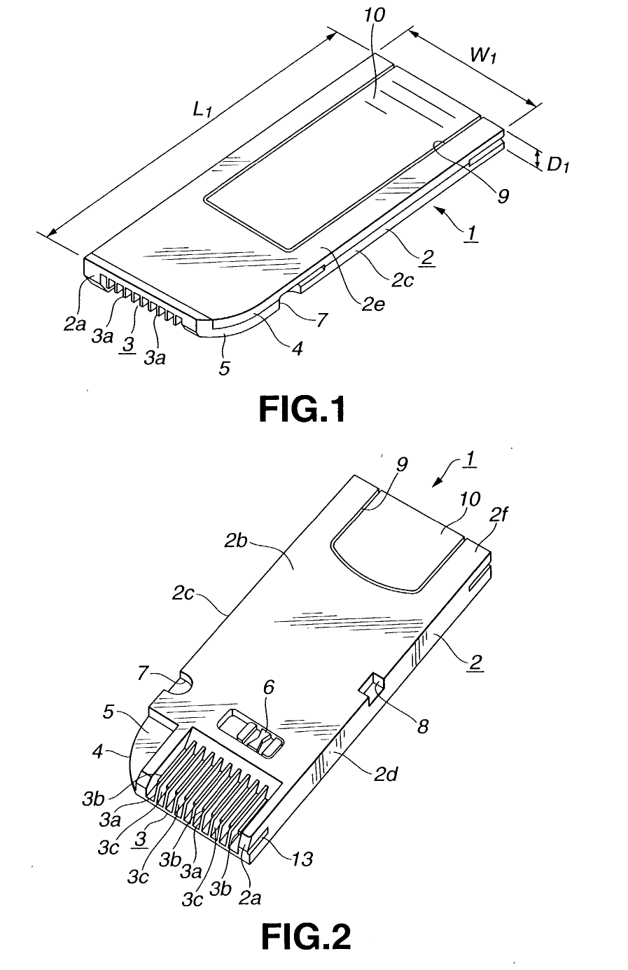

The recording/reproduction apparatuses according to the invention use an IC card 1 of the type shown in FIGS. 1 and 2. The IC card 1 comprises a housing 2 shaped like a plate. The housing 2 is made of synthetic resin and formed by molding. The housing 2 contains a semiconductor memory element such as a flash memory that has a large storage capacity of, for example, 4 MB, 16 MB, 32 MB, 64 MB or 128 MB.

The IC card 1 may be a memory stick (trademark), an SD memory card (trademark), a compact flash (trademark), a small media (trademark), a multimedia card (trademark), a micro-drive (trademark), an ID format (trademark), a ThumbDrive (trademark), or the like.

The IC card 1 used in this invention is a rectangular one. As shown in FIG. 1, for example, the IC card 1 has a length W1 of about 21.45 mm at the short sides, a length L1 of about 50 mm at the long sides, and a thickness D1 of about 2.8 mm.

As FIGS. 1 and 2 shows, a terminal section 3 is formed on the front 2a (i.e., one short side) and bottom 2b of the housing 2. A plurality of electrodes 3b are provided on the terminal section 3 and isolated from one another by partition walls 3a. Data is read into and written from the memory element incorporated in the housing 2, through the electrodes 3b provided on the terminal section 3. The terminal section 3 has engagement recesses 3c that are defined by the partition walls 3a. The electrodes 3b are laid on the bottoms of the recesses 3c and protected from the contact with fingers or the like. Ten electrodes 3b (3b₁ to 3b₁₀) are provided in the recesses 3c, respectively.

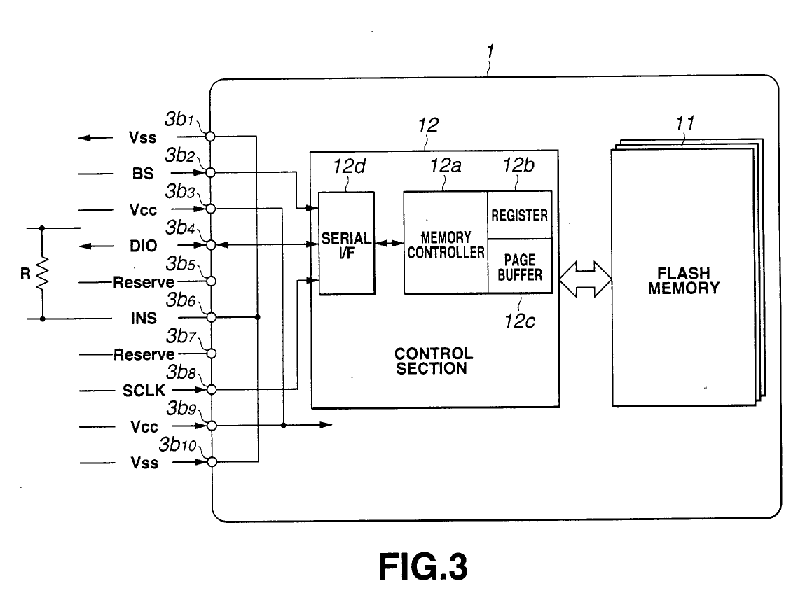

The electrodes 3b₁ to 3b₁₀ will be described. As shown in FIG. 3, the electrodes 3b₁ and 3b₁₀ are used as terminals for a detection voltage VSS. The electrode 3b₂ is used as the input terminal for a serial protocol bus-state signal BS. The electrodes 3b₃ and 3b₉ serve as terminals for a power-supply voltage VCC. The electrode 3b₄ is used as a data terminal, i.e., the input/output terminal for a serial protocol data signal. The electrodes 3b₅ and 3b₇ are provided as reserved terminals. The electrode 3b₆ serves to determine whether an IC card 1 has been inserted into a recording/reproduction apparatus. The electrode 3b₈ is used as an input terminal for a serial clock signal SCLK.

As FIGS. 1 and 2 show, the corner on the front 2a of the housing 2, which has the terminal section 3, has a sector-shaped cutout 4. The cutout 4 indicates the direction of inserting the IC into the recording/reproduction apparatus. The side 2c of the housing 2, in which the cutout 4 is partly made, has a groove 5 as is illustrated in FIG. 2, to prevent erroneous insertion of the IC card 1. The groove 5 opens at the bottom 2b of the housing 2 and is continuous to the cutout 4. The cutout 4 and the groove 5 allow the user to insert the IC card 1 in only one direction, thus preventing erroneous insertion of the IC card 1.

As shown in FIG. 2, a switch 6 is provided on the bottom 2b of the housing 2, in the vicinity of the terminal section 3, to prevent erroneous writing of data signals into the semiconductor memory. The switch 6 is coupled with an operation member provided in the housing 2. When the switch 6 is slid in one direction, it allows the recording of data signals. When it is slid in the other direction, it prevents the over-writing of new data signals. A recess 7 is made in the side 2c of the housing 2. The recess 7 receives an elastic engagement strip provided in the recording/reproduction apparatus when the IC card 1 is inserted into the apparatus. Once the engagement strip is fitted in the recess 7, it prevents the IC card 1 from slipped out of the recording/reproduction apparatus. An engagement recess 8 is cut in the other side 2d of the housing 2. When the recess 8 receives the detection section provided on the recording/reproduction apparatus, it is detected that the IC card 1 has been inserted into the apparatus. An insertion guide groove 13 is made in the other side 2d of the housing 2 and located near the terminal section 3. The groove 13 guides the IC card 1 while the IC card 1 is being inserted into the recording/reproduction apparatus. The groove 13 prevents an erroneous insertion of the IC card 1, too.

As FIGS. 1 and 2 show, the housing 2 of the IC card 1 has a label section 9 on the top 2e, back 2f and bottom 2b of the housing 2. The label section 9 is a recess cut in the top 2e, back 2f and bottom 2b. The label section 9 is so deep that the label 10 bonded to it may not protrude from the outer surfaces of the housing 2 or may lie in flush with the outer surfaces thereof. As shown in FIG. 1, that part of the label section 9, which is provided on the top 2e, extends from the back 2f to a position near the front 2a of the housing 2. The label 10 bonded to the label section 9 shows which types of apparatuses that can record and reproduce data in and from the IC card 1 and what information is recorded in the IC card 1.

The FAT (File Allocation Table) system is employed as a system that records and reproduces data in and from IC cards of this type. Data is written into the IC card 1 at speed of 1500 KB/sec to 330 KB/sec and read from the IC card 1 at speed of 2.45 MB/sec. Data is written in units of 512 bytes and erased in units of data blocks having a size of 8 KB or 16 KB. The power-supply voltage VCC ranges from 2.7V to 3.6V. The serial clock signal SCLK used has a maximum frequency of 20 MHz.

The circuit configuration of the IC card 1 will be explained. As FIG. 3 shows, the IC card 1 comprises a flash memory 11 and a control section 12. The flash memory 11 stores data. The control section 12 controls the writing of data into the memory 11 and the reading of data therefrom.

The flash memory 11 stores moving-picture data, still-picture data, sound data and control data that are supplied from the recording/reproduction apparatus. The flash memory 11 stores data to be processed by computers.

The control section 12 comprises a memory controller 12a, a register 12b, a page buffer 12c, and a serial interface 12d. The memory controller 12a controls the writing data into the flash memory 11 and the reading of data from the flash memory 11. The register 12b holds various parameters that are used to write data and read data. The page buffer 12c temporarily stores data. The serial interface 12d supplies data to and receives data from the recording/reproduction apparatus. The memory controller 12a transfers data between the flash memory 11 and the page buffer 12c in accordance with the parameters set in the register 12b.

The memory controller 12a of the control section 12 receives a serial protocol bus-state signal BS from the electrode 3b₂, and a serial clock signal SCLK from the electrode 3b₈. To write data into the flash memory 11, the memory controller 12a makes the page buffer 12c temporarily store the data input from the electrode 3b₄ via the serial interface 12d, in accordance with the serial protocol bus-state signal BS and the serial clock signal SCLK. The data is then stored into the flash memory 11. To read data from the flash memory 11, the memory controller 12a reads the data from the flash memory 11 into the page buffer 12c in accordance with the serial protocol bus-state signal BS and the serial clock signal SCLK. The controller 12a then outputs the data from the electrode 3b₄ to the recording/reproduction apparatus through the serial interface 12d. The detection voltage VSS is applied to the electrode 3b₆. In the recording/reproducing apparatus, a resistor R detects the voltage on the electrode 3b₆. From the voltage detected it is determined whether the IC card 1 has been reliably inserted into the recording/reproduction apparatus.

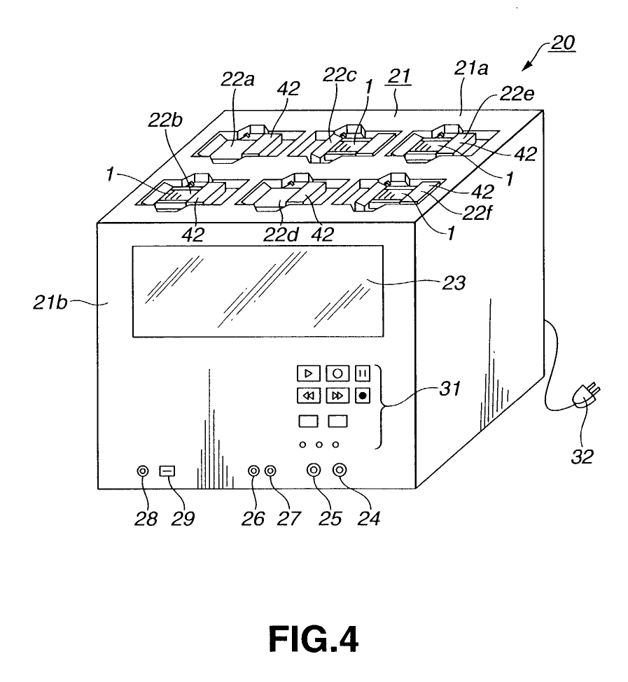

The recording/reproduction apparatus 20 that uses the IC card 1 as a recording medium will be described with reference to some drawings. As may be seen form FIG. 4, the recording/reproduction apparatus 20 is a stationary one. The apparatus 20 has a rectangular main body 21. Speakers, a disc drive and the like are connected to the main body 21. Card holding sections 22a to 22f are arranged in a matrix on the upper surface 21a, or the top, of the main body 21. Since the card holding sections are provided on the upper surface 21a of the main body 21, IC cards 1 can be easily inserted into and removed from them. IC cards 1 can be inserted into the card holding sections 22a to 22f, respectively. In the case illustrated in FIG. 4, the card holding sections 22a to 22f are arranged in two rows and three columns. The card holding sections 22a to 22f will be described later in detail.

A display section 23, which is a liquid crystal display or the like, is mounted on the front 21b of the main body 21. The front 21b serves as the control panel. The display section 23 displays the information about the contents of audio data, such as the title, when the audio data is read from an IC card 1. The display section 23 may display messages such as operation guidance.

A headphone terminal 24 and a microphone terminal 25 are provided in the front 21b of the main body 21. A headphone incorporating an electro-acoustic transducer may be connected to the headphone terminal 24. A microphone for collecting sound and speech may be connected to the microphone terminal 25. The user can hear audio data recorded in an IC card 1 if the headphone he or she wears, for example, is connected to the headphone terminal 24. Once a microphone has been connected to the microphone terminal 25, the user can record sound and speech in an IC card 1.

A line-output terminal 26 and a line-input terminal 27 are provided in the front 21b of the main body 21, too. External devices, such as a speaker and an optical disc drive can be connected to the terminals 26 and 27. Further, a digital input terminal 28 is provided in the front 21b. Once a speaker has been connected to the line-output terminal 26, the user can hear the audio data recorded in an IC card 1. If an optical disc drive is connected to the line-output terminal 26, the user can dub the audio data recorded in an IC card 1, on the rewritable optical disc set in the optical disc drive. If an optical disc drive is connected to the line-input terminal 27, the data, such as music data, recorded on the optical disc set in the optical disc drive can be dubbed in an IC card 1. A device that can output digital data, such as an optical disc drive, may be connected to the digital input terminal 28 by an optical cable or the like. In this case, the digital data recorded on the optical disc set in the disc drive can be dubbed in an IC card 1.

A USB (Universal Serial Bus) connector 29 is provided in the front 21b of the main body 21. To the USB connector 29 there may be connected a computer or the like that has, for example, a USB interface. The data the computer has processed can therefore be recorded in an IC card 1, and the data recorded in the IC card 1 can be read into the computer. An SCSI (Small Computer System Interface) connector, an RS-232C (Recommendation Standard 232C) connector, an IEEE (Institute of Electrical and Electronic Engineers) 1394 connector, and the like can be provided on the main body 21.

An operation section 31 is provided on the front 21b of the main body 21. The operation section 31 comprises a power-supply button, a reproduction button, a recording button, a volume button, an edition button, a menu button and the like. The power-supply button is pushed to start or stop the supply of power. The reproduction button is depressed to start the reproduction of the data recorded in IC cards 1. The record button is operated to start the recording of data in IC cards 1. The volume button is depressed to control the volume of sound reproduced. The edition button is pushed to start the edition of the data recorded in IC cards 1. The menu button is pushed to select one of various operation menu items of the main body 21. Operations signals generated in the operation section 31 are input to a CPU. The CPU performs the functions designated by the operation signals.

The main body 21 of the apparatus has a power-supply connector 32 that supplies power to the main body 21. The operating power supply of the main body 21 is the commercially available one. The operating power supply may, of course, be replaced by a primary battery or a secondary buttery.

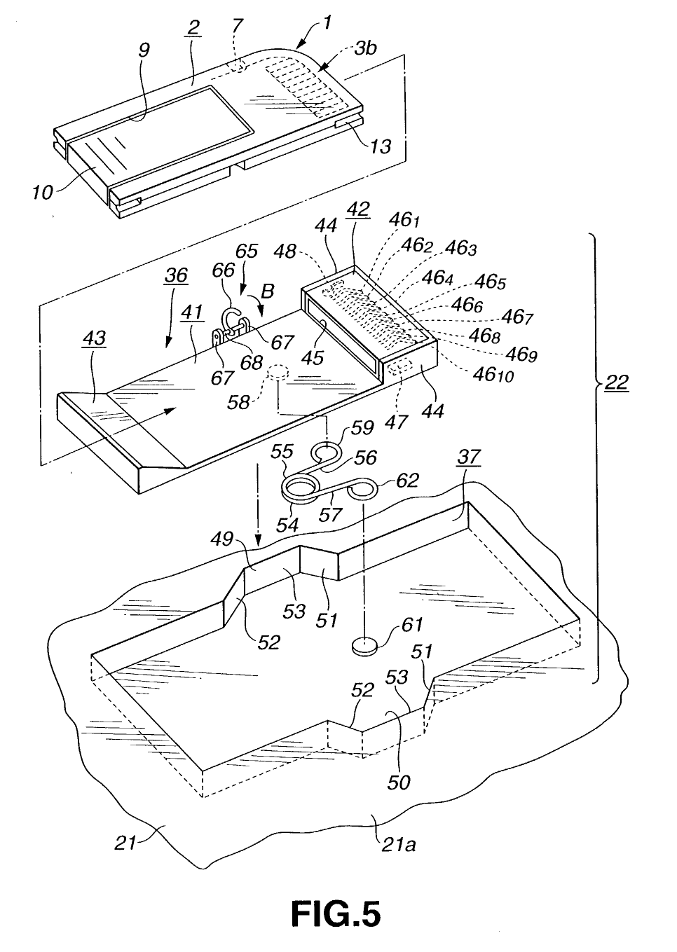

As indicated above, the card holding sections 22a to 22f (hereinafter referred to as “card holding sections 22”) are arranged on the upper surface 21a of the main body 21. Since the card holding sections 22 are provided on the upper surface 21a, forming a matrix thereon, it is easy for users to insert and remove IC cards 1 into and from the apparatus 20 as may be seen from FIG. 4. In the embodiment of FIG. 4, six card holding sections 22 are provided in rows and columns. The structure of the card holding sections 21 will be described. As shown in FIG. 5, each card holding section comprises a card holding member 36 and a guide recess 37. The card holding member 36 is configured to hold an IC card 1. The guide recess 37 receives the card holding member 36, allowing the member 36 to move.

The card holding member 36 for holding an IC card 1 has almost the same size as the bottom 2b of the IC card 1, as can be understood from FIG. 5. The member 36 comprises a support plate 41, a connector 42, and an insertion guide 43. The support plate 41 supports an IC card 1. The connector 42 is provided at one end of the support plate 41 and configured to receive the terminal section 3 of the IC card 1. The insertion guide 43 guides the IC card 1 as the card 1 is inserted, sliding on the support plate 41.

The support plate 41 for supporting an IC card 1 is rectangular, almost as large as the bottom 2b of the IC card 1. Two plates 44 are provided at one end of the support plate 41 and formed at both sides thereof. The plates 44 holds the connector 42 that is the means for transmitting and receiving data to and from the control circuit incorporated in the main body 21.

The connector 42 secured to the plates 44 is substantially rectangular. It has an insertion port 45 in the front. The terminal section 3 of an IC card 1 may be inserted into the connector 42 through the insertion port 45. On the bottom of the connector 42 there are arranged connection terminals 46₁ to 46₁₀. The terminals are to be electrically connected to the electrodes 3b₁ to 3b₁₀ that constitute the terminal section 3. The connection terminals are provided in the same number as the electrodes 3b₁ to 3b₁₀ that constitute the terminal section 3. The connection terminals 46₁ to 46₁₀ are shaped in the form of letter L. The bent part of each connection terminal projects upward; it is pressed onto the associated electrodes 3b₁ to 3b₁₀ of the IC card 1, elastically deformed. When the IC card 1 is inserted into the card holding member 36, the connection terminals 46₁ to 46₁₀ move from the open side of the engagement recesses 3c provided in the terminal section 3 of the card 1 and electrically contact the electrodes 3b₁ to 3b₁₀. A flexible printed substrate (not shown) connects the connection terminals 46₁ to 46₁₀ to the electric circuit contained in the main body 21 of the apparatus.

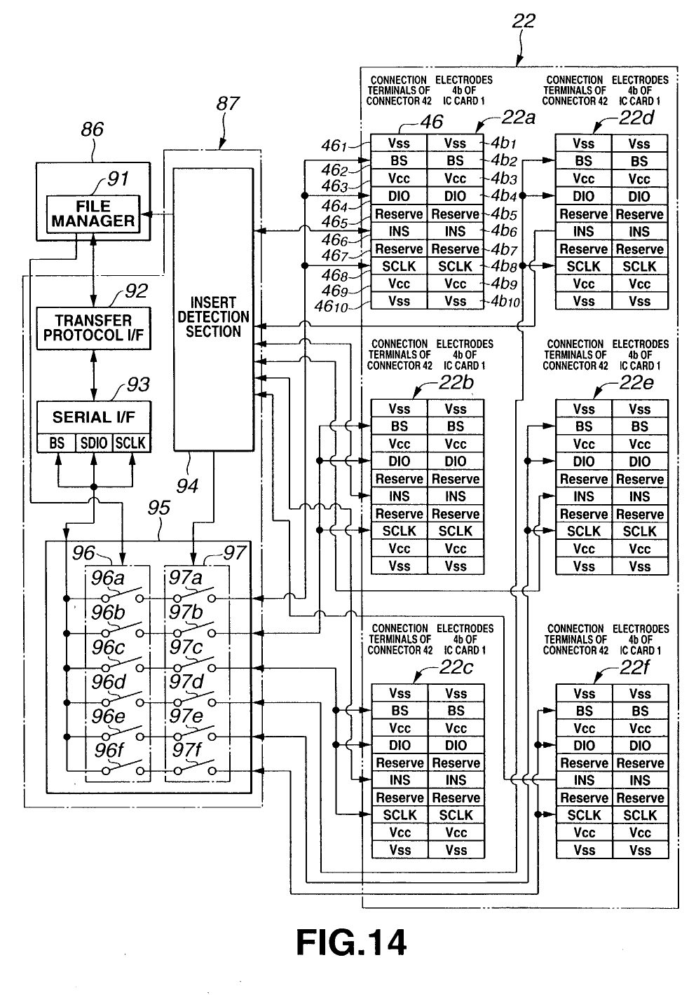

The connection terminals 46₁ to 46₁₀ will be described. As shown in FIG. 14, the connection terminals 46₁ and 46₁₀ are used as terminals for the detection voltage VSS and electrically connected to the electrodes 3b₁ and 3b₁₀. The connection terminal 46₂ is used as the input terminal for the serial protocol bus-state signal BS and is electrically connected to the electrode 3b₂. The connection terminals 46₃ and 46₉ serve as terminals for a power-supply voltage VCC and are electrically connected to electrodes 3b₃ and 3b₉. The connection terminal 46₄ is used as a data terminal, i.e., the input/output terminal for the serial protocol data signal and is electrically connected to the electrode 3b₄. The connection terminals 46₅ and 46₇ are provided as reserved terminals and are electrically connected to the electrodes 3b₅ and 3b₇. The connection terminal 46₆ serves to determine whether an IC card 1 has been inserted into a recording/reproduction apparatus and is electrically connected to the 3b₆. The connection terminal 46₈ is used as an input terminal for the serial clock signal SCLK and is electrically connected to the electrode 3b₈.

As FIG. 5 shows, a guide strip 47 is provided on one side of the connector 42 and may be set in the insertion guide groove 13 of the IC card 1. An elastic engagement strip 48 is provided on the other side of the connector 42 and may be set in the recess 7 that prevents the IC card 1 from slipping out. When the terminal section 3 of the IC card 1 inserted through the insertion port 45, the guide strip 47 comes into the insertion guide groove 13, to guide the terminal section 3. When the IC card 1 is placed in the card holding member 36, the elastic engagement strip 48 comes into the recess 7, to prevent the IC card 1 from moving from the prescribed position in the member 36.

When the IC card 1 is inserted, the connection terminals 46₁ to 46₁₀ of the connector 42 described above come into the engagement recesses 3c of the terminal section 3. At the same time, the elastic engagement strip 48 comes into engagement with the recess 7. The IC card 1 is thereby held at a prescribed position.

The insertion guide 43 is provided at the one end of the support plate 41 other than the end at which connector 42 is provided. The guide 43 is formed integral with the support plate 41. As shown in FIG. 7, the insertion guide 43 has a surface that inclines down toward in the card-inserting direction. The IC card 1 is inserted, with its distal end first contacting the inclining surface of the guide 43 and then sliding on the support plate 41.

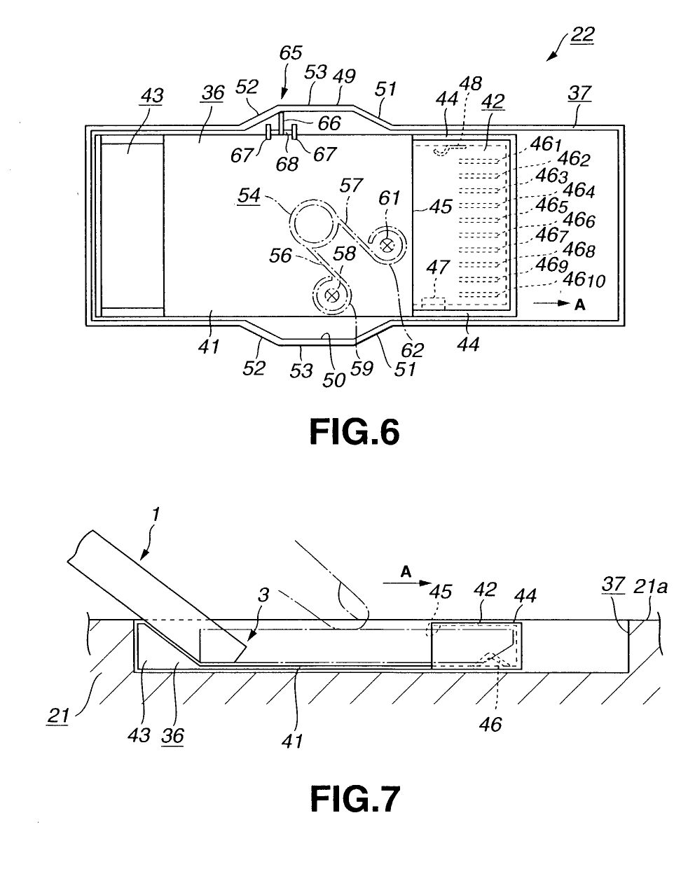

The guide recess 37 for receiving the card holding member 36 is made in the upper surface 21a of the main body 21. As FIGS. 5 and 6 show, the short sides of the recess 37 have substantially the same length as the short sides of the card holding member 36. The long sides of the recess 37 are longer than the long sides of the card holding member 36. Hence, the card holding member 36 can move in the lengthwise direction of the guide recess 37, or in the direction of arrow A shown in FIG. 6 and in the direction opposite thereto.

Notches 49 and 50 are cut in the long sides of the guide recess 37, making it easy for the user to remove the IC card 1 from the card holding sections 22. Each of the notches 49 and 50 has two inclined surfaces 51 and 52 and a horizontal surface 53. The surfaces 51 and 52 are continuous to a long side of the guide recess 37. The horizontal surface 53 lies between the inclined surfaces 51 and 52 and extends parallel to the long side of the guide recess 37. To remove the IC card 1, the user puts the fingers into the notches 49 and 50 and holds the IC card 1 at both sides thereof. The user can then pull the IC card 1 out of the card holding section 22. The inclined surface 51 of the notch 49, which lies near the connector 42, define the cam of a holding mechanism that holds the IC card 1 in the card holding member 36 as will be described later.

As shown in FIGS. 5 and 6, a toggle spring 54 connects the support plate 41 of the card holding member 36 to the bottom of the guide recess 37. The toggle spring 54 serves as a means for moving the card holding member 36 between a card inserting/removing position and a data recording/reproducing position. The toggle spring 54 comprises a coil 55, a first arm 56, and a second arm 57. The coil 55 has been formed by winding a wire. The first arm 56 extends from one end of the coil 55. The second arm 57 extends from the other end of the coil 55. A first engagement member 59 is provided at the distal end of the first arm 56, to set into engagement with the first engagement projection 58 provided on the support plate 41 of the card holding member 36. A second engagement member 62 is provided at the distal end of the second arm 57, to set into engagement with the second engagement projection 61 provided on the bottom of the guide recess 37. The toggle spring 54 holds the card holding member 36 in the guide recess 37 of the main body 21 as long as the first engagement member 59 remains engaged with the first engagement projection 58 and the second engagement member 62 remains engaged with the second engagement projection 61. The spring 54 can therefore bias the IC card 1 toward the card inserting/removing position and the data recording/reproducing position.

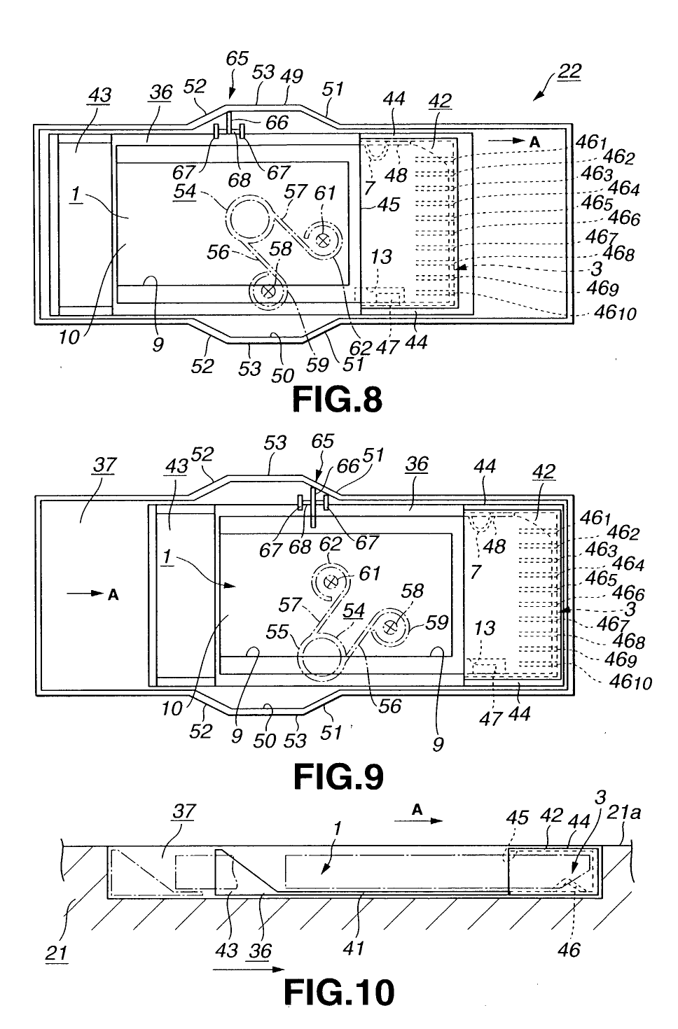

The toggle spring 54 connects the card holding member 36 to the bottom of the guide recess 37 made in the upper surface 21a of the main body 21. While the member 36 remains in the card inserting/removing position, the toggle spring 54 biases the member 36 in the direction of arrow A as illustrated in FIGS. 6 and 8 to enable the user to remove the IC card 1. When the user pushes the IC card 1 with the fingers, in the direction of arrow A, the card holding member 36 is moved in the direction of arrow A from the card inserting/removing position. When the card holding member 36 reaches the midpoint of the guide recess 37, the toggle spring 54 exerts its bias in the reverse direction. The member 36 is therefore moved in the direction opposite to the direction of arrow A (FIG. 7) to the data recording/reproducing position as shown in FIG. 9.

When the user moves the IC card 1 with the fingers, toward the card inserting/removing position, the card holding member 36 is moved toward this position, too. When the card holding member 36 reaches the midpoint of the guide recess 37, the toggle spring 54 exerts its bias in the reverse direction. The member 36 receives this bias of the spring 54 and further moves in the direction opposite to the direction of arrow A (FIG. 9). The member 36 finally reaches the card inserting/removing position, as illustrated in FIGS. 6 and 8.

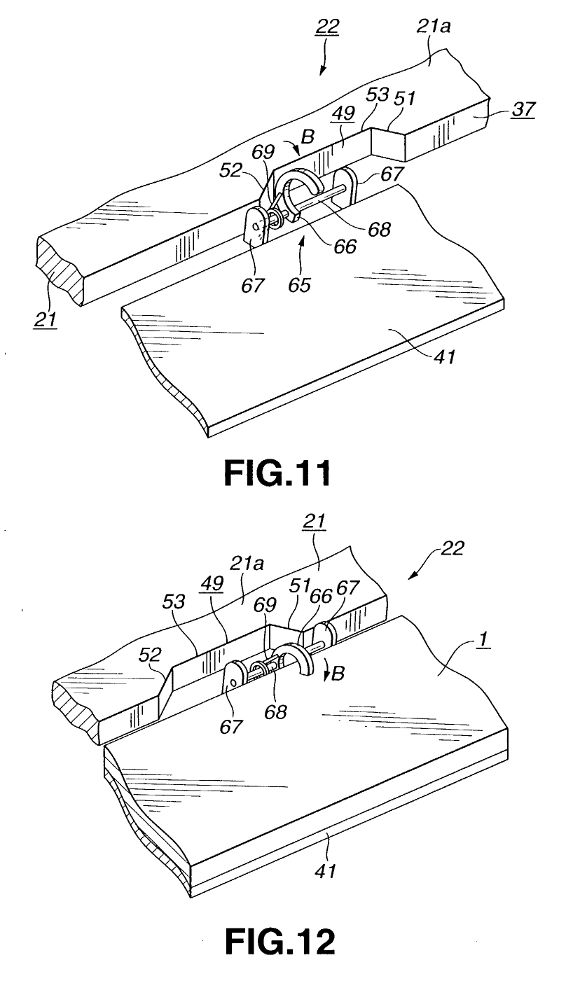

As FIGS. 11 and 12 show, the card holding section 22 has a holding mechanism 65. The holding mechanism 65 is configured to hold the IC card 1, preventing the same form moving in the card holding member 36.

As seen from FIG. 11, the holding mechanism 65 has a holding member 66 for holding the IC card 1 in the card holding member 36. The holding member 66 is shaped in the form of letter C. Support strips 67 provided at the middle part of one long side of the support plate 41 support the holding member 66. More specifically, the holding member 66 is secured at one end to an axle 68, which is rotatably supported by the support strips 67. The holding member 66 shaped in the form of letter C is fastened to the axle 68, with its opening facing the IC card 1. The holding member 66 can therefore rotate around the axle 68 in the direction of arrow B (FIG. 11) and the direction opposite thereto. The holding mechanism 65 has a torsion coil spring 69 that serves as a bias member that biases the holding member 66 to rotate the same in the direction opposite to the arrow B (FIG. 11). The torsion coil spring 69 comprises a coiled part and two arms. The coiled part is wound around the axle 68. One arm is coupled to the holding member 66, and the other arm is coupled to one of the support strips 67. Thus, the spring 69 biases the holding member 66 to rotate the same in the direction opposite to the arrow B (FIG. 11).

As shown in FIG. 11, the holding member 66 is positioned near the notch 49 that is cut in one side of the guide recess 37. It lies at the horizontal surface 53 of the notch 49 as long as the card holding member 36 remains at the IC-card insertion/removal position shown in FIGS. 6 and 8. Once The holding member 66 is rotated in the direction opposite to arrow B (FIG. 11) by virtue of the bias of the torsion coil spring 69, the IC card 1 can be inserted into the card holding member 36. When the card holding member 36 is moved to the recording/reproducing position shown in FIG. 9, the holding member 66 shaped in the form of letter C is pushed onto the inclined surface 51 of the notch 49 as shown in FIG. 12. More precisely, that part of the member 66, which opposes the horizontal surface 53 while the member 66 remains in the insertion/removal position, is pushed onto the inclined surface 51. Then, the holding member 66 rotates around the axle 68 in the direction of arrow B shown in FIGS. 11 and 12, against the bias of the torsion coil spring 69. The holding member 66 shaped like letter C abuts, at its other end, on the top 2e of the IC card 1 that is held in the card holding member 36. Thus, the member 36 holds the IC card 1. In the card holding member 36, the IC card 1 is thereby held at a specific position. Thus, the inclined surface 51 of the notch 49 functions as a cam that pushes the holding member 66, causing the member 66 to rotate against the bias of the torsion coil spring 69.

When the card holding member 36 is moved to the insertion/removal position to move the IC card 1 from the recording/reproducing position, the holding member 66 moves to the position where it faces the horizontal surface 53. The holding member 66 is released from the inclined surface 51 that functions as a cam. Then, the bias of the torsion coil spring 69 rotates the holding member 66 in the direction opposite to arrow B shown in FIG. 11. The other end of the holding member 66 leaves the top 2e of the IC card 1. The IC card 1 can therefore be removed.

The IC card 1 is inserted into and removed from the card holding section 22 thus configured, as will be explained below. As indicated above, the card holding member 36 is connected to the bottom of the guide recess 37 made in the upper surface 21a of the main body 21. The toggle spring 54 biases the card holding member 36 to rotate the same in the direction opposite to arrow A as shown in FIG. 6, if the card holding member 36 does not hold the IC card 1. In this case, the member 36 lies at the IC-card insertion/removal position. The holding member 66 of the holding mechanism 65 opposes the horizontal surface 53 of the notch 49. The member 66 therefore rotates in the direction opposite to arrow B shown in FIG. 11, by virtue of the bias of the torsion coil spring 69. The IC card 1 can thereby be held in the card holding member 36.

The IC card 1 is inserted into the card holding member 36 lying in the insertion/removal position, with its terminal section 3 abutting on the inclined surface of the insertion guide 43 as is illustrated in FIG. 7. The IC card 1 is then moved, sliding on the support plate 41 from the insertion guide 43. As shown in FIG. 8, the terminal section 3 enters the insertion port 45 of the connector 42. The connection terminals 46₁ to 46₁₀ are thereby fitted into the engagement recesses 3c. Therefore, the electrodes 3b₁ to 3b₁₀ are electrically connected to the connection terminals 46₁ to 46₁₀. When the IC card 1 is inserted into the connector 42, the guide strip 47 enters the insertion guide groove 13. The IC card 1 is thereby guided. At the same time, the elastic engagement strip 48 comes into engagement with the recess 7. This prevents the IC card 1 from slipping out of the card holding member 36.

When the user pushes, with fingers, the IC card 1 in the direction of arrow A (FIG. 8) to a midpoint in the guide recess 37, the toggle spring 54 starts exerting the bias in the reverse direction. The card holding member 36 holding the IC card 1 receives the bias of the toggle spring 54 and is further moved in the direction opposite to arrow A (FIGS. 7 and 8), reaching the recording/reproducing position in the guide recess 37. One end of the substantially C-shaped holding member 66, which opposes the horizontal surface 53 in the insertion/removal position, is then pressed, as shown in FIG. 12, onto the inclined surface 51 of the notch 49, which lies near the connector 42. The holding member 66 therefore rotates around the axle 68 in the direction of arrow B shown in FIGS. 11 and 12, against the bias of the torsion coil spring 69. The other end of the substantially C-shaped holding member 66 abuts on the top 2e of the IC card 1 held, holding the IC card 1 at a specific position in the card holding member 36.

When the card holding member 36 is moved in the direction opposite of arrow A as shown in FIG. 9, from the recording/reproducing position to the midpoint of the guide recess 37, the toggle spring 54 exerts the bias in the reverse direction. The member 36 receives the bias of the toggle spring 54. As shown in FIG. 8, it further moved in the direction of arrow A to the insertion/removal position. At this position, the holding member 66 of the holding mechanism 65 moves to a position near the horizontal surface 53. The holding member 66 is released from the inclined surface 51 that functions as a cam and is rotated in the direction to arrow B (FIG. 11), by virtue of the bias of the torsion coil spring 69. The other end of the holding member 66 leaves the top 2e of the IC card 1. The IC card 1 can therefore be removed. At the insertion/removal position, the IC card 1 may be held at both sides, with the user's fingers put into the notches 49 and 50. The user can remove the IC card 1 from the card holding member 36.

Card holding sections 22 of the type described above are provided in the upper surface 21a of the main body 21. IC cards 1 of the type described above are held in the sections 22, respectively, and arranged forming a matrix. The labels 10 on the IC cards 1 turn to outside. The user can therefore easily know the contents recorded in the IC cards 1 held in the card holding sections 22. The user need not insert or remove the IC cards 1 as in the conventional data-recording/reproducing apparatus. In each card holding section 22, the toggle spring 54 biases the card holding member 36, moving the same between the insertion/removal position and the recording/reproducing position, after the user pushes the card holding member 36 in a specific direction. This enables the user to perceive the IC card 1 has moved to the recording/reproducing position or to the insertion/removal position. Additionally, the main body 21 can hold a plurality of IC cards 1 at a time. With the recording/reproduction apparatus 20 it is easy for the user to perform the management of the small IC cards 1.

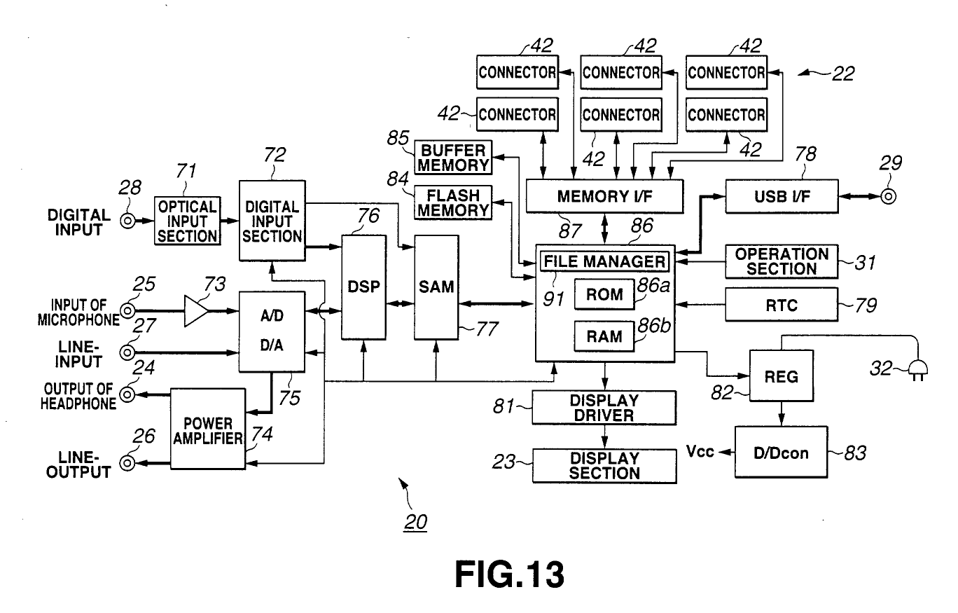

The circuit configuration of the recording/reproduction apparatus 20 will be described. As is shown in FIG. 13, the recording/reproduction apparatus 20 comprises an optical input section 71 and a digital input section 72. The optical input section 71 receives an optical signal from the digital input terminal 28 and performs opto-electric conversion on the optical signal. The digital input section 72 performs an input interface process on the electric signal the optical input section 71 has generated. The optical input section 71 converts the optical signal input from the optical disc drive to the digital input terminal 28 through the optical cable, into an electric signal. The digital input section 72 receives the electric signal in accordance with a transmission format.

The recording/reproduction apparatus 20 further comprises a microphone amplifier 73, a power amplifier 74, an AD/DA converter 75, a DSP (Digital Signal Processor) 76, and a SAM (Security Application Module) 77. The microphone amplifier 73 amplifies the audio data input to the microphone terminal 25. The power amplifier 74 amplifies the signals, such as audio data, output from the headphone terminal 24 and line-output terminal 26. The AD/DA converter 75 converts the analog signals input from the microphone amplifier 73 and line-input terminal 27, to digital signals. The converter 75 converts digital signals to analog signals, too. The analog signals are supplied via the power amplifier 74 to the headphone terminal 24 and line-output terminal 26. The DSP 76 compresses the digital data supplied from the AD/DA converter 75 and expands the data recorded in the IC cards 1. The data expanded is supplied to the AD/DA converter 75. The SAM 77 encrypts data and expands the data encrypted.

The DSP 76 compresses the digital signal input from the digital input section 72 or the digital data generated by the AD/DA converter 75, generating data of JPEG (Joint Photographic Expert Group) or MPEG (Motion Picture Expert Group) format 1, 2. The data thus compressed is supplied to the SAM 77 and will be encrypted by the SAM 77. Further, the DSP 76 outputs the data expanded by the SAM 77 or the data compressed and stored in the IC card 1, to the AD/DA converter 75.

The SAM 77 encrypts data and expands the data encrypted. More specifically, the SAM 77 encrypts the data supplied from the DSP 76 and expands the data encrypted and recorded in the IC card 1 or the like. The data encrypted and the data expanded is supplied from the SAM 77 to the DSP 76. The encryption key is stored in a flash memory 84. The encryption key is transferred between the flash memory 84 and a CPU 86, whereby data is encrypted and expanded.

The recording/reproducing apparatus 20 comprises a USB interface 78, a real-time clock 79, and a display driver 81. The USB interface 78 is connected to the USB connector 29. The real-time clock 79 measures time, counting days and hours. The display driver 81 causes the display section 23 to display data. The USB interface 78 is a communications interface configured to transmit and receive data to and from an external apparatus, such as a computer, which is connected to the USB connector 29. It transmits and receives various data items, such as control data, data to be processed, image data, audio data and the like, to and from the external apparatus. The display driver 81 causes the display section 23 to display the data recorded in the IC card 1, such as the image data, and the information about the data recorded in the IC card 1.

The recording/reproducing apparatus 20 further comprises a regulator 82 and a DC/DC converter 83. The regulator 82 rectifies the AC current supplied from the power-supply connector 32, thereby generating a DC current. The DC/DC converter 83 converts the voltage applied from the regulator 82, to an operating voltage for the circuits incorporated in the apparatus 20.

The recording/reproducing apparatus 20 further comprises the flash memory 84, a buffer memory 85, the CPU (Central Processing Unit) 86, and a memory interface 87. The flash memory 84 stores system information and the like. The buffer memory 85 is provided to receive the data stored in the IC card 1 and temporarily stores this data. The CPU 86 controls the other components of the apparatus 20. The memory interface 87 is connected to the connectors 42 of the six card holding sections 22. The flash memory 84 stores system information about the operation in the main body 21. The system information includes a recording mode in which music data is recorded into the IC cards 1, a reproduction mode in which the music data is reproduced from the IC cards 1, a display mode in which the display section 23 displays the image data stored in the IC cards 1. The flash memory 84 stores an encryption key, too. The SAM 77 described above uses the encryption key to encrypt data and expand the data encrypted. The buffer memory 85 is provided to store temporarily the data read from the IC card 1 held in one card holding sections 22, to effect dubbing of the data in the IC card 1 held in another card holding sections 22.

The CPU 86 controls all other components of the apparatus 20. It has a ROM (Read Only Memory) 86a and a RAM (Random Access Memory) 86b. The ROM 86a stores the operation program for the main body 21. The RAM 86b serves as a work area, in which the program read from the ROM 86a is stored temporarily. In the CPU 86, the program is read from the ROM 86a into the RAM 86b. The program is then executed, controlling the components of the apparatus 20, other than the CPU 86. The CPU 86 has a file manager 91, too. The file manager 91 has read the management file that is designed to control the main data stored in the IC cards 1. The CPU 86 can access one or more IC cards 1 held in the card holding sections 22, in accordance with the file manager 91.

As FIG. 14 shows, the memory interface 87, i.e., the interface for the connectors 42 of the six card holding sections 22, has a transfer protocol interface 92, a serial interface 93, an insertion-detecting section 94, and a selection section 95. The transfer protocol interface 92 accomplishes an access to the register 12b and page buffer 12c incorporated in the IC card 1 illustrated in FIG. 3. The serial interface 93 defines a protocol that transfers data through three signal lines, i.e., a serial clock signal SCLK line, a bus state signal BS line and a serial data input/output signal SDIO line. The insertion-detecting section 94 determines whether an IC card 1 has been reliably connected to the connector 42. The selection section 95 ensures the connection of the serial interface 93 with the card holding sections 22.

The serial interface 93 transfers data through the serial clock signal SCLK line, the bus-state signal BS line and the serial data input/output signal SDIO line. These signal lines are connected to the connection terminals 46₂, 46₄ and 46₈ of the connector 42 incorporated in each of the card holding sections 22a to 22f through the selection section 95. When the IC card 1 is inserted into the card holding member 36 of the card holding section 22 as shown in FIG. 8 and the card holding member 36 moves to the recording/reproducing position as shown in FIG. 10, the IC card 1 is connected to the main body 21. That is, the serial interface 12d shown in FIG. 3 is connected to the serial interface 93.

The insertion detecting section 94 that determines whether an IC card 1 has been reliably connected to the card holding section 22 is connected to the connection terminals 46₆ of each of the card holding sections 22a to 22f. The section 94 determines that the IC card 1 is held in the card holding section 22a to 22f, by detecting the terminal voltage of the electrode 3b₆ of the terminal section 3 of the IC card 1. That is, when the card holding member 36 moves to the recording/reproducing position shown in FIG. 10, the insertion detecting section 94 becomes able to detect the terminal voltage of the electrode 3b₆ of the terminal section 3 of the IC card 1. It detects the terminal voltage of the electrode 3b₆, thereby determining which card holding section 22 the IC card 1 is connected to, and generates a detection signal. The insertion detecting section 94 supplies the detection signal to the file manager 91 provided in the CPU 86. The detection signal changes over the enable switch of the selection section 95.

As illustrated in FIG. 14, the selection section 95 has selection switches 96a to 96f (hereinafter referred to as “selection switch 96”) and enable switches 97a to 97f (hereinafter referred to as “enable switch 97”). The selection switches 96a to 96f are used to select one of the card holding sections 22a to 22f, respectively. The enable switches 97a to 97f inhibit the connector 42 of any card holding section 22 that holds no IC cards 1. The selection switches 96a to 96f are connected in series to the enable switches 97a to 97f. The switches 96a to 96f and the switches 97a to 97f are connected between the serial interface 93, one the one hand, and the connection terminals 46₂, 46₄ and 46₈ of the card holding sections 22a to 22f. The selection switches 96 are provided in the same number as the connectors 42 in the card holding section 22. They are connected at one end to the enable switches 97a to 97f, and at the other end to the serial interface 93. The file manager 91 provided in the CPU 86 opens or closes the selection switches 96a to 96f. The connector 42 of any card holding section 22 that holds an IC card 1 is thereby selected so that data may be reproduced from the IC card 1.

The enable switches 97a to 97f are connected at one end to the connection terminals 46₂, 46₄ and 46₈ of the card holding sections 22a to 22f, and at the other end to the selection switches 96a to 96f. The enable switches 97a to 97f are provided to prevent any card holding section 22 that holds no IC cards 1, from being selected. The insertion detecting section 94 controls the enable switches 97a to 97f. The selection switches 96a to 96f select the card holding sections 22a to 22f, respectively, when the enable switches 97a to 97f determine that the sections 22a to 22f hold IC cards 1 into and from which data is to be recorded and reproduced.

The functions of the CPU 86 and memory interface 87 may be defined by hardware or software.

It will be explained how a desired one of the IC cards 1 is selected after the IC cards 1 have been inserted into the card holding sections 22a to 22f of the memory interface 87. First, the power switch is turned on, supplying power to the main body 21. The insertion detecting section 94 detects the terminal voltage of the electrode 3b₆ of each of the IC cards 1 held in the card holding sections 22a to 22f. The insertion detecting section 94 determines that an IC card 1 has been inserted into the card holding section 22, if the terminal voltage of the electrode 3b₆ of the terminal section 3 is higher than a threshold value. If the terminal voltage is lower than the threshold value, the section 94 determines that an IC card 1 has not been inserted into the card holding section 22. Thus, the insertion detecting section 94 determines whether IC cards 1 are held in the respective card holding sections 22a to 22f. The insertion detecting section 94 generates a detection signal that indicates which card holding sections hold IC cards 1 and which card holding sections hold no IC cards 1. The detection signal is supplied to the file manager 91 incorporated in the CPU 86. At the same time, the insertion detecting section 94 supplies the detection signal to the selection section 95.

The insertion detecting section 94 turns on or off the enable switches 97a to 97f in accordance with the detection signal. To be more specific, the insertion detecting section 94 turns on the enable switch (one of switches 97a to 97f) of any card holding section (any one of sections 22a to 22f) that holds an IC card 1, thus enabling the user to use the card holding section holding an IC card 1. The section 94 turns off the enable switch (one of switches 97a to 97f) of any card holding section (any one of sections 22a to 22f) that holds no IC cards 1, thus disabling the user to use the card holding section holding no IC cards 1. At the same time, the CPU 86 that has received the detection signal controls the display driver 81, which causes the display section 23 to display the images of the card holding sections 22 that the user can use.

The user look at the image of the card holding sections 22 displayed by the display section 23. Alternatively, the user looks at the card holding sections 22a to 22f arranged, forming a matrix displayed on the upper surface 21a of the main body 21. The user then operates the operation section 31, selecting the card holding section 22 of the desired address. The section 22 generates an operation signal, which is supplied to the CPU 86. In the CPU 86, the file manager 91 controls the selection switches 96 in accordance with the operation signal. More precisely, the file manager 91 turns on the selection switch 96 of the card holding section 22 of the address the user has selected, and turns off the selection switches 96 of the other card holding sections 22. The selection switch 96 and enable switch 97 connected to the selected card holding section 22 are closed, whereas one or both of the selection switch 96 and enable switch 97 connected to any other card holding section 22 are opened.

After one card holding section 22 into which the user has inserted an IC card 1 has been selected, the user may operates the operation section 31 to reproduce the music data from the IC card 1 held in the card holding section 22. In this case, the operation section 31 generates an operation signal, which is supplied to the CPU 86. The file manager 91 of the CPU 86 connects the serial interface 12d to the serial interface 93. The music data is thereby read from the flash memory 11 provided in the IC card 1, through the serial clock signal SCLK line, the bus state signal BS line and the serial data input/output signal SDIO line. The music data thus read is supplied to the DSP 76. The DSP 76 expands the music data that has been compressed. The music data expanded is supplied to the AD/DA converter 75. The AD/DA converter 75 converts the music data, which is a digital signal, to an analog signal. The analog signal is supplied to the power amplifier 74. The music data is output from the speaker connected to the line-output terminal 26 or from the headphone connected to the headphone terminal 24.

After the user selects one card holding section 22 that holds an IC card 1, digital contents, such as music data, can be dubbed from the optical disc drive (i.e., an external apparatus) into the IC card 1 held in the card holding section 22. How the music data is dubbed so will be explained. First, an operation signal is input to the CPU 86 from the operation section 31, so that the music data may be dubbed in the IC card 1 from the magnetic disc set in the optical disc drive. The optical disc drive supplies the optical signal to the digital input terminal 28 and thence to the optical input section 71. The optical input section 71 converts the optical signal to an electric signal and performs a reception process on the electric signal. The DSP 76 compresses the data. The CPU 86 records the data compressed, in the IC card 1 held in the card holding section 22 that the user has selected.

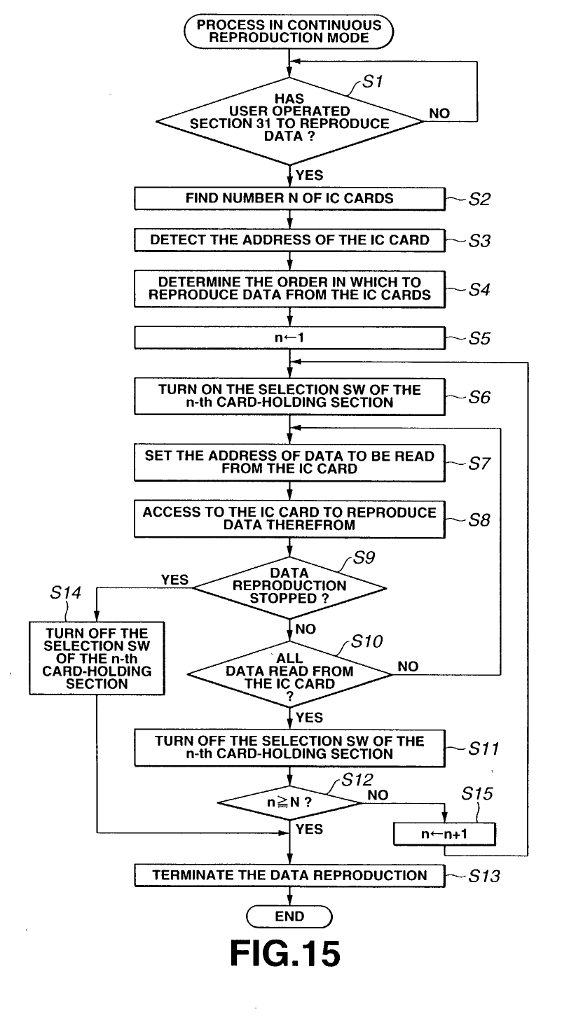

Assume that some of the card holding sections 22a to 22f hold IC cards 1. How the music data is continuously reproduced from these IC cards 1 will be described, with reference to FIG. 15.

First, in Step S1, the user has operated the operation section 31 to reproduce data in the continuous reproduction mode. The section 31 generates an operation signal, which is input to the CPU 86. The CPU 86 starts the reproduction of data in the continuous reproduction mode. The process then goes to Step S2. If no operation signal is input to the CPU 86, Step S1 is repeated.

In Step S2, the CPU 86 finds the number N of the IC cards 1 that are held in the card holding sections 22a to 22f. That is, the CPU 86 detects the terminal voltages of the electrodes 3b₆ of the IC cards 1 held in some of the card holding sections 22a to 22f and calculates the number N from the detection signals input from the insertion detecting section 94. Since the present embodiment has six card holding sections, the maximum value of N is 6. When the number N is 1, data cannot be reproduced in the continuous reproduction mode. The minimum value of N is therefore 2. After the CPU finds the number N, the process goes to Step S3.

In Step S3, the CPU 86 determines which card holding sections hold IC cards 1. That is, the CPU 86 determines the addresses of the card holding sections holding IC cards 1, based on the detection signals input from the insertion detecting section 94. The detection signals are output to the selection section 95, too. The enable switches 97 of the card holding sections 22 that hold no IC cards 1 are thereby turned off. This disables the user to select the address of any card holding section 22 that holds no IC cards 1. After the CPU 86 determines the addresses of the card holding sections 22 holding IC cards 1, the process goes to Step S4.

In Step S4, the CPU 86 controls the display driver 81, which causes the display section 23 to display the addresses of the card holding sections 22 that hold IC cards 1. Further, the CPU 86 makes the display section 23 display the information relates to the music data stored in the IC cards 1, for example, the title of music pieces. In the recording/reproducing apparatus 20, the card holding sections 22a to 22f are provided in the upper surface 21a of the main body 21. Therefore, the user can read the labels 10 glued to the IC cards 1 and recognize the contents of the IC cards 1. The user operates the operation section 31, which generates an operation signal. Based on the operation signal the CPU 86 determines the order in which the IC cards 1 should be subjected to data reproduction. The process goes to Step S5. The IC cards 1 may be subjected to the data reproduction in a random order or in the descending order of tie addresses of the card holding sections 22a to 22f.

In Step S5, the CPU 86 sets a variable n at 1 to reproduce data from the IC card 1 which is held in the card holding section 22 and from which data should be reproduced first. The process then advances to Step S6. In Step S6, the file manager 91 of the CPU 86 turns on the selection switch 96 associated with the card holding section 22 the user has selected, while turning off the other selection switches 96. Thus, data can be reproduced from only the IC card 1 of the address the user has selected. Thereafter, the process goes to Step S7.

In Step S7, the CPU 86 sets the address of the music data to be read from the IC card 1. In Step S8, it makes a reading access. The serial interface 12d is thereby connected to the serial interface 93. The CPU 86 reads the music data from the flash memory 11 incorporated in the IC card 1. The music data is supplied to the DSP 76 through the serial clock signal SCLK line, the bus state signal BS line and the serial data input/output signal SDIO line. The DSP 76 expands the music data that has been compressed. The music data expand is supplied to the AD/DA converter 75. The AD/DA converter 75 converts the music data, which is a digital signal, to an analog signal. The analog signal is output to the power amplifier 74. Finally the music data is output from the speaker connected to the line-output terminal 26 or from the headphone connected to the headphone terminal 24.

In Step S9, the CPU 86 determines whether the user has operated the operation section 31 to stop the continuous data reproduction. If YES, the CPU 86 goes to Step S14. If the user does not operate the section 31 to stop the continuous data reproduction, the CPU 86 goes to Step S10.

In Step S10, the CPU 86 determines whether all music data has been read from the IC card 1 from which data should be reproduced first. If the data has been read from the IC card 1, the process goes to Step S11. If the data has not been read from the IC card 1, the process returns to Step S7. The process is therefore repeated.

If it is determined in Step S11 that all music data has been read from the IC card 1, the CPU 86 turns off the selection switch 96 of the card holding section 22 holding the IC card 1 from which all data has been reproduced. The process then advances to Step S12.

In Step S12, the CPU 86 determines whether the variable n is equal to or greater than the number N of IC cards 1 held in the card holding sections 22. If the variable n is equal to or greater than the number N, the process goes to Step S13. If variable n is smaller than the number N, the process advances to Step S15.

In Step S13, the CPU 86 determines that data has been reproduced from all IC cards 1 held in the card holding sections 22 and then finishes performing the continuous data reproduction. If the user operates the operation section 31 in Step S9 to stop the continuous data reproduction, the CPU 86 stops reading data from the IC card 1 in Step S14. More precisely, the CPU 86 turns off the selection switch 96 in Step S14, thereby stopping the continuous data that is carried out in Step S13.

If variable n is found smaller than the number N in Step S12, the CPU 86 increases the variable n by one in Step S15, in order to reproduce data from the next IC card 1. The process then returns to Step S6. In Step S6, the CPU 86 turns on the selection switch 96 of the card holding section 22 that holds the IC card 1 from which data should be reproduced next.

As indicated above, the card holding sections 22a to 22f remain provided in the upper surface 21a of the main body 21 even while the music data is being reproduced continuously from the IC cards 1 held in the card holding sections 22a to 22f. The user can select any desired IC card 1 to reproduce data therefrom, just looking at the labels 10 put on the IC cards 1 held in the card holding sections 22a to 22f. The user need not be bothered to look at the IC card 1 information the display section 23 is displaying. Thus, the user can easily select the address of the card holding section 22 that holds the IC card 1 he or she wants.

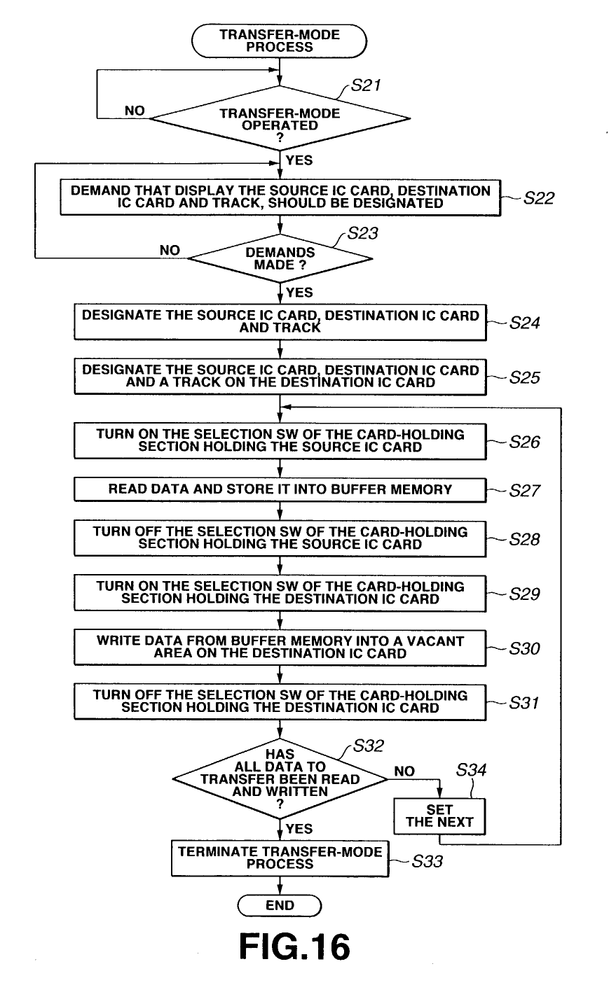

The transfer-mode process of transferring the data recorded in one IC card to another IC card and recording the data on the other IC card will be described, with reference to FIG. 16. First, in Step S21, the user may operate the operation section 31 to initiate the transfer-mode process. In this case, the operation section 31 generates an operation signal. The operation signal is supplied to the CPU 86. The CPU 86 starts performing the transfer-mode process. The process goes to Step S22. If no operation signals are input to the CPU 86, Step S21 will be repeated.

In Step S22, the CPU 86 demands that the address of the card holding section 22 holding the IC card 1 from which data should be transferred be selected, that the track on the IC card 1 to which the data should be transferred be designated, and that the address of the card holding section 22 holding the IC card 1 to which the data should be transferred be selected. More specifically, the CPU 86 makes these demands on the display section 23 via the display driver 81. Based on the results of detection obtained by the insertion detecting section 94, the CPU 86 causes the display section 23 to designate the IC card 1 from which data should be transmitted and the IC card 1 to which the data should be transferred.

In Step S23, it is determined whether the IC card 1 from which data should be transmitted, the IC card 1 to which the data should be transferred and the track on the IC card 1 to which the data should be transferred have been designated. If YES, the CPU 86 goes to Step S24. If NO, the process returns to Step S22, in which the CPU 86 demands again that the addresses of the card holding sections holding the IC cards 1, from which and to which data should be transferred, be selected.

In Step S24, the file manager 91 provided in the CPU 86 designates the addresses of the card holding sections holding the IC cards 1, from which and to which data should be transferred, and designates the address of the recording track on the IC card 1 to which data should be transferred, too. The CPU 86 then goes to Step S25.

In Step S25, the CPU 86 set, as read addresses, the address of the recording track on the source IC card 1 and the address of the recording track on the destination IC card 1. The CPU 86 goes to Step S26. In Step S26, the CPU 86 turns on the selection switch 96 of the card holding section 22 that holds the source IC card 1. This makes it possible to read data from the recording track on the source IC card 1. Thereafter, the CPU 86 advances to Step S27.

In Step S27, the CPU 86 reads data from the source IC card 1 and stores the data into the buffer memory 85. The data is read in units of amounts, each not exceeding the storage capacity of the buffer memory 85.

After storing the data into the buffer memory 85, the CPU 86 goes to Step S28. In Step S28, the CPU 86 turns off the selection switch 96 of the card holding section 22 holding the IC card 1 from which the data is being read. In Step S29, the CPU 86 turns on the selection switch 96 of the card holding section 22 holding the destination IC card 1, so that the data may be transferred from the buffer memory 85 to the destination IC card 1. In Step S30, the data stored in the buffer memory 85 is transferred to a vacant area on the destination IC card 1.

When the transfer of data from the buffer memory 85 to the destination IC card 1 is completed, the process advances to Step S31. In Step S31, the CPU 86 turns off the selection switch 96 of the card holding section 22 that holds the destination IC card 1. The process goes to Step S32, in which the CPU 86 determines whether all data has been transferred from the source IC card to the destination IC card 1. The process advances to Step S33 if all data has been transferred, and to Step S34 if all data has not been transferred.

If all data has not been transferred, the CPU 86 sets the next read address, i.e., the address of the source IC card 1 in Step S34. Then, the process returns to Step S26, in which the CPU 86 again turns on the selection switch 96 of the card holding section 22 that holds the source IC card 1. The remaining data is thereby read from the source IC card 1 into the buffer memory 85.

As described above, the card holding sections 22a to 22f remain provided in the upper surface 21a of the main body 21 even while data is being transferred between two of the IC cards 1 held in the card holding sections 22a to 22f. Hence, the user can select the source IC card 1 and the destination IC card 1, merely by looking at the labels 10 put on the IC cards 1 held in the card holding sections 22a to 22f. He or she need not take trouble of looking at the IC card 1 information the display section 23 is displaying. Thus, the user can easily select the address of the card holding sections 22 that hold the source IC card 1 and the destination IC card 1, respectively.

The recording/reproducing apparatus described above has six cards holding sections 22 in the upper surface 21a of the main body 21 and arranged, forming a matrix. Nonetheless, the number of card holding sections is not limited to six. Further, the card holding sections may be provided in any other surface of the main body 21. For example, they may be provided in the front 21b (serving as the control panel) or in the side or sides of the main body 21. Card holding sections 22 may be arranged in a row or a column, in each surface of the main body 21. The direction in which the IC cards 1 are inserted and removed from the respective card holding section 22 is not limited to the direction described above. They may be inserted and removed at the front 21b of the main body 21 to make these operations easy.

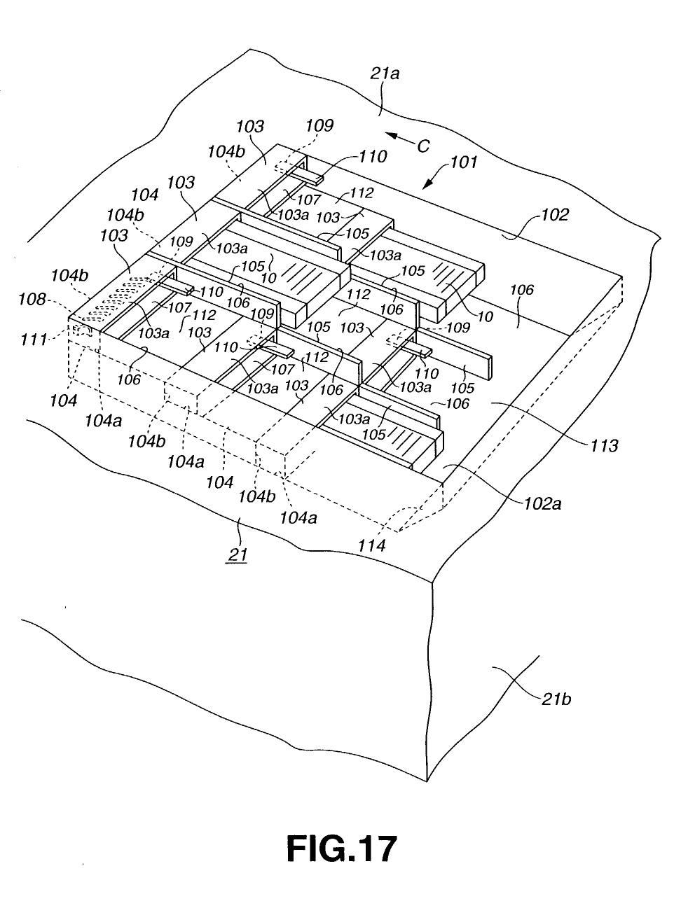

The card holding sections 22 of the recording/reproducing apparatus 20 may be replaced by a card holding section 101 illustrated in FIGS. 17 and 18. As FIGS. 17 and 18 show, the card holding section 101 holds IC cards 1 in rows, such that the IC cards of each row are staggered with respect to one another.

The card holding section 101 has a holding recess 102 that is designed to hold IC cards 1 in staggered fashion. The holding recess 102 is substantially rectangular, extending in the direction in which the IC cards 1 may be inserted and removed. The recess holding 102 can hold at most nine IC cards 1. The bottom of the holding recess 102 has three steps, each lower to the next one toward the center in the lengthwise direction. Holding sections 104 are provided at one side of the recess 102 that has three steps. The holding section 104 are configured to hold connectors 103, each of which is means for transmitting and receiving data to and from one IC card 1. Each holding section 104 comprises a horizontal part 104a and a vertical part 104b. The horizontal part 104a holds a connector 103. The vertical part 104b aligns the connector 103 at a prescribed position. In the holding recess 102 there are provided insertion guide walls 105 that guide IC cards 1 being inserted into the card holding section 101. The walls 105 are spaced apart at the same intervals that are almost equal to the width W1 of the IC card 1 shown in FIG. 1. The insertion guide walls 105 partition the recess 102 into card holding compartments 106. As shown in FIGS. 17 and 18, the proximal end of each horizontal part 104a functions to support an IC card 1. The distal end of the horizontal part 104a is connected to the next lower-stage connector 103. The horizontal part 104a has such a length that it would not cover the label 10 put on the IC card 1 that is partly held in the next lower-stage connector 103.

The connector 103 fastened to the holding section 104 is similar in structure to the connector 103 described above. The connector 103 is rectangular as a whole. It has an insertion port 107 in the front. Through the port 107 the terminal section 3 of an IC card 1 can be inserted into the connector 103. Connection terminals 108 are provided on the inner bottom of the connector 103. The terminals 108 can be electrically connected to the electrodes 3b constituting the terminal section 3 of the IC card 1. The connection terminals 108 are bent in the form of letter L. The bent part of each terminal 108 protrudes upwards and is elastically bend when it is pressed onto the electrode 3b of the IC card 1. The connection terminals 108 are thereby electrically connected to the electrodes 3b of the terminal section 3. A guide strip 109 is provided at one side of the connector 103. The guide strip 109 can be set in the insertion guide groove 13 of the IC card 1. The guide strip 109 is integral with a guide strip 110, which is provided on one inner side of the holding recess 102 or on one surface of a guide wall 105. Both guide strips 109 and 110 are fitted into the insertion guide groove 13 when the terminal section 3 of the IC card 1 is inserted into the connector 103 through the insertion port 107 thereof. The strips 109 and 110 therefore guide the IC card 1 being inserted into the connector 103. An elastic strip 111 is provided on the other side of the connector 103. When the IC card 1 is held in the connector 103, the strip 111 is fitted into the recess 7 made in one side of the IC card 1. Thus, the elastic strip 111 prevents the IC card 1 from moving from the prescribed position. The connectors 103 are fastened to the holding sections 104 of the respective card holding compartments 106, by caulking or similar means, each with its insertion port 107 facing the other side of the holding recess 102. The top plates 103a of the second- and third-stage connectors 103, which are secured to the horizontal parts 104a, each form a support section 112 jointly with the horizontal part 104a. The support section 112 holds the IC card 1 that has been inserted into the upper-stage connector 103.

The bottom 102a of the holding recess 102 has such a size that a clearance 113 may be provided at the other side of the recess 102 when an IC card 1 is inserted into the third-stage connector 103. Since the holding recess 102 is large enough to provide the clearance 113 when an IC card 1 is moved into the third-stage connector 103, the IC card 1 is smoothly inserted into the third-stage connector 103. The holding recess 102 has an inclined surface 114 at the other side. The inclined surface 114, which is continuous to the bottom 102a, guides the IC card 1 as the IC card 1 is removed from the holding recess 102.

In the card holding section 101, an IC card 1 is inserted into one connector 103 as is illustrated in FIG. 18. To be more specific, the user first positions the IC card 1, with the terminal section 3 abutting on the support section 112. The user then lays the IC card 1 in the holding recess 102. Thereafter, the user moves the IC card 1 in the direction of arrow C shown in FIGS. 17 and 18, from the front 21b of the main body 21. To pull the IC card 1 out of the connector 103, the user moves the IC card 1 moves the IC card 1 in the direction opposite to arrow C shown in FIGS. 17 and 18. The IC card 1 can therefore be pulled out from the front 21b of the main body 21. It is easy to remove the IC card 1 from the card holding section 101, because the IC card 1 is pushed up at its back 2f, which slides on the inclined surface 114 of the holding recess 102.

In the card holding section 101, a plurality of IC cards 1 are held in the holding recess 102, partly overlapping one another. The card holding section 101 can be smaller than the card holding sections 22 described above. The support sections 112, each comprising a horizontal part 104a and the top plates 103a of a connector 103, are provided in the holding recess 102. Therefore, the label 10 of the IC card 1 held in a connector 103 is not covered with the IC card 1 held in the next upper-stage connector 103. This enables the user to know easily the data items that are recorded in the IC cards 1 held in the card holding sections 22. It is not necessary for the user to insert or remove IC cards 1 as with the conventional recording/reproducing apparatus. In addition, the user can insert and remove IC cards 1 easily since the IC cards can be inserted and removed at the front 21b of the main body 21.

The card holding section 101 has been described. Nonetheless, the section 101 may hold more or less IC cards than nine. To hold less IC cards 1, fewer steps are made in the holding recess 102 or less columns of connectors 103 are provided. Conversely, to hold more IC cards 1, it suffices to make more steps in the holding recess 102 or to provide more columns of connectors 103.

The recording/reproducing apparatus 20, which is configured to record and reproduce data in and from IC cards 1, has been described with reference to some drawings. The embodiment may be modified, nevertheless. For example, the data communication between the terminal section of each IC card 1 and the connector of a card holding section may be accomplished by radio. The embodiment may be either a recording apparatus or a reproducing apparatus. Further, the main body 21 may have covers that close the card holding sections 22 or a cover that closes the card holding section 101, in order to prevent foreign matter, such as dust, from entering the sections 22 or the section 101.

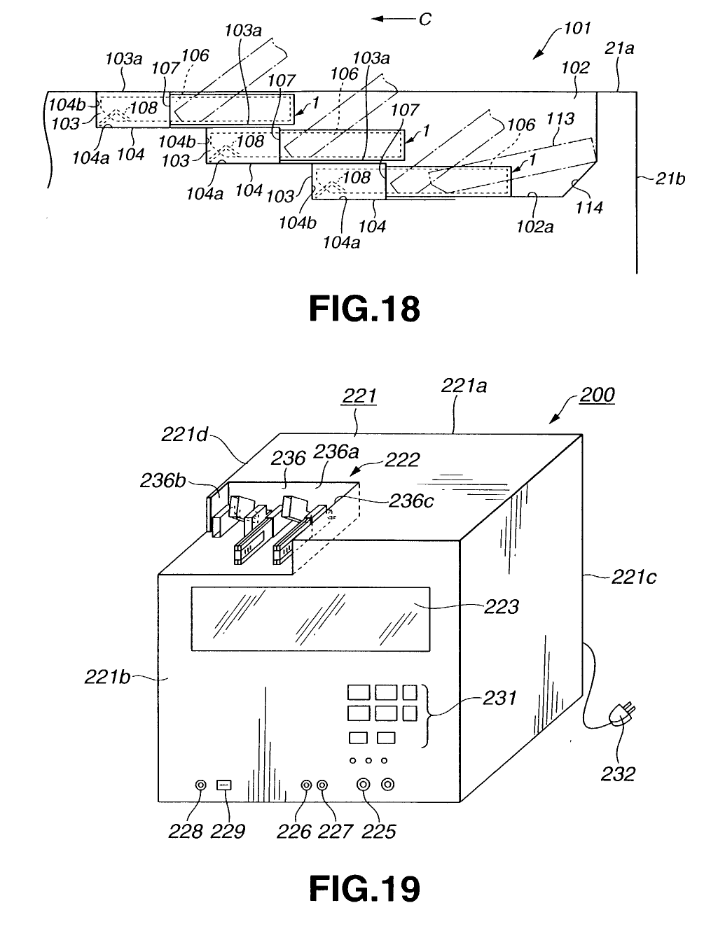

Another embodiment of the recording/reproducing apparatus 20 according to this invention will be described, with reference to the drawings. As may be understood from FIG. 19 shows, this recording/reproducing apparatus 220 is a stationary one. The recording/reproducing apparatus 220 has a rectangular main body 221. Speakers, a disc drive and the like are connected to the main body 221. The main body 221 has a card holding section 222 at a front corner of the upper surface 221a, which is the top of the main body 221. The card holding section 222 is configured to hold IC cards 1 that are recording media. The section 222 has six connectors into which six IC cards 1 may be inserted. Each IC card 1 is held in one connector, with its other side 2d and its back 2f lying almost in flush with the upper surface 221a and front 21b of the main body 221, respectively, so that data may be recorded or reproduced from the IC card 1. To remove the IC card 1 from the connector, the user may hold, with fingers, the back 2f of the IC card 1 and then rotate the IC card 1 upward from the upper surface 221a. Since the card holding section 222 lies in a front corner of the main body 221, it exposes the back 2f of each IC card 1 held in it. This renders it easy for the user to hold the IC card 1 with fingers and to rotate the IC card 1 upwards.

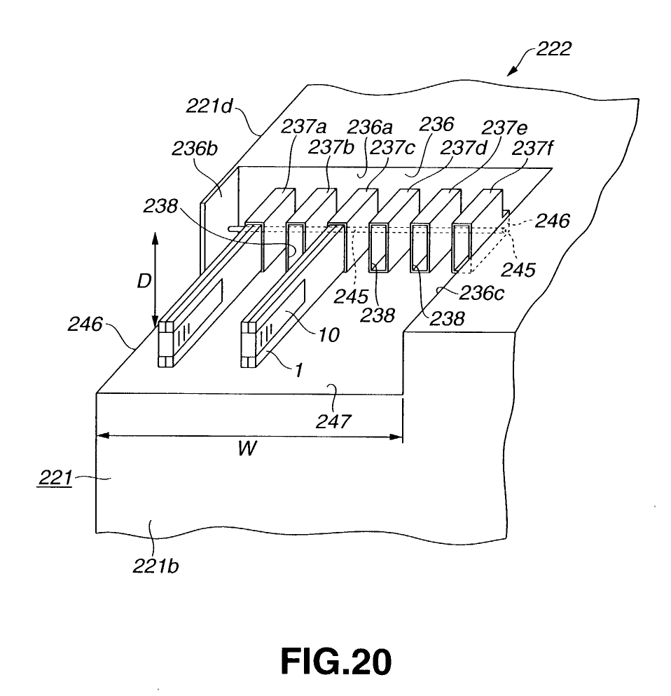

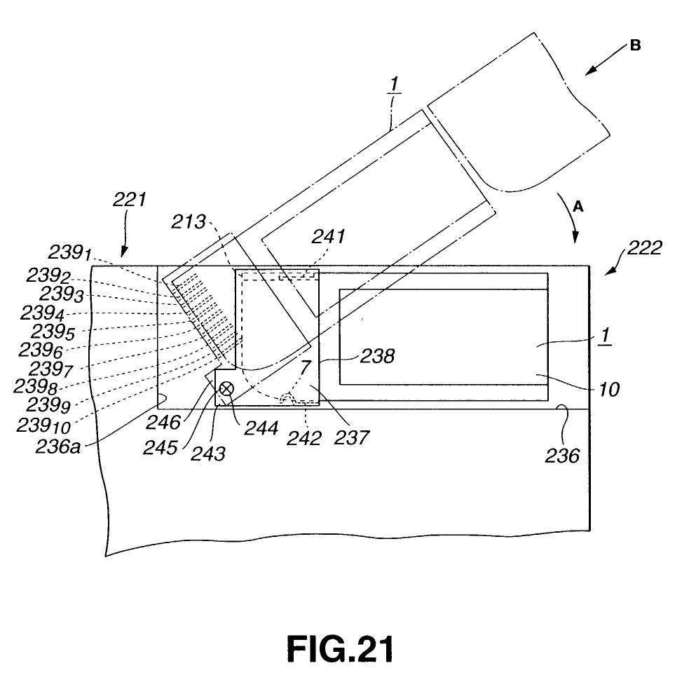

As illustrated in FIGS. 20 and 21, the card holding section 222 has a holding recess 236 and connectors 237a to 237f. The holding recess 236 can receive, for example, six IC cards 1. The connectors 237a to 237f are provided to hold the six IC cards 1 that may be set in the holding recess 236 and function as means for transmitting and receiving data.

As FIG. 20 shows, the holding recess 236 is provided in one corner of the upper surface 221a of the main body 221. IC cards 1 are held in the holding recess 236, each positioned with its front 2a near the back 221c of the main body 221, its back 2f near the front 221b of the main body 221, and its other side 2d substantially in flush with the upper surface 221a of the main body 221. That is, the holding recess 236 has a depth D that is almost equal to the width W1 of the IC cards 1, a length L greater than that L1 of the IC cards 1, and a width W large enough to arrange six IC cards 1 side by side.

In the holding recess 236, six connectors 237a to 237f (hereinafter referred to as “connectors 237,” too) are provided to hold six IC cards 1, respectively. The connectors 237a to 237f are almost rectangular. Each connector has an insertion port 238 in the front. Through the port 238 the terminal section 3 of an IC card 1 can be inserted into the connector. The connectors 237a to 237f have such a size that they would not cover the labels 10 put on the IC cards 1 when the terminal section 3 of the IC cards 1 are held in them. Connection terminals 239₁ to 239₁₀ are provided on the inner bottom of each of the connectors 237a to 237f. The connection terminals are electrically connected to the electrodes 3b₁ to 3b₁₀ that constitute the terminal section 3 of an IC card 1. The connection terminals 239₁ to 239₁₀ are provided in the same number as the electrodes 3b₁ to 3b₁₀ of the terminal section 3. The connection terminals 239₁ to 239₁₀ are bent in the form of letter L. The bent part of each connection terminal protrudes upwards and is elastically bend when it is pressed onto electrodes 3b₁ to 3b₁₀ of the IC card 1. The connection terminals 239₁ to 239₁₀ are fitted into the engagement recesses 3c of the terminal section 3 when the IC card 1 is inserted into the connectors 237a to 237f. The terminals 239₁ to 239₁₀ have their bent parts pressed onto the electrodes 3b₁ to 3b₁₀. The terminals 239₁ to 239₁₀ are therefore electrically connected to the electrodes 3b₁ to 3b₁₀. A flexible printed board (not shown) connects the connection terminals 239₁ to 239₁₀ to the electric circuit (not shown) incorporated in the main body 221.

As shown in FIG. 21, a guide strip 241 is provided on one side of the connector 239. The guide strip 241 may be fitted in the insertion guide groove 13 of an IC card 1. An elastic engagement strip 242 is provided on the other side of the connector 239. The elastic engagement strip 242 may be fitted in the recess 7 made in one side of the IC card 1 to prevent the IC card 1 from slipping out of the connector 239. The guide strip 241 is fitted into the insertion guide groove 13 when the terminal section 3 of the IC card 1 is inserted into the connector 239 through the insertion port 238 thereof. The strip 241 thus guides the terminal section 3 into the connector 239. The elastic engagement strip 242 is fitted into the recess 7 when the IC card 1 is set in the connector 239, thus preventing the IC card 1 from moving in the holding recess 236.

When an IC card 1 is inserted into any one of connectors 237a to 237f, the connection terminals 239₁ to 239₁₀ are fitted into the engagement recesses 3c of the terminal section 3 of the IC card 1 and the elastic engagement strip 242 is fitted into the recess 7. The connector 237 therefore holds the IC card 1.

The connectors 237a to 237f have a support strip 243 each, which is provided on the back of the connector. The support strip 243 supports the connector 237, allowing the same to rotate. The support strip 243 has a support hold 244. An axle 245 is provided at the rear wall 236a of the holding recess 236. The connectors 237a to 237f are mounted on the axle 245 that extends between the side walls 236b and 236c of the holding recess 236. The axle 245 passes through the support hole 244 of the support strip 243. The connectors 237a to 237f are mounted on the axle 245, spaced apart from one another at regular intervals. Each connector 237 holding an IC card 1 can rotate around the axle 245, moving the IC card 1 between two positions. The first position exists in the holding recess 236. At the second position, the back 2f of the IC card 1 projects from the holding recess 236.

The sequence of inserting IC cards 1 into the connectors 237a to 237f, respectively, will be described with reference to FIG. 21. To insert an IC card 1 into a connector 237, the user rotates the connector 237 around the axle 245 in the direction opposite to arrow A shown in FIG. 21. The connector 237 is thereby positioned, with its insertion port 238 turned up. The IC card 1 can therefore be inserted into and removed from the connector 237 through the insertion port 238. The user moves the IC card 1 in the direction of arrow B shown in FIG. 21, guiding the terminal section 3, or distal end of the IC card 1, into the connector 237. The connection terminals 239₁ to 239₁₀ of the connector 237 are thereby fitted into the engagement recesses 3c of the IC card 1. At the same time, the electrodes 3b₁ to 3b₁₀ are electrically connected to the connection terminals 239₁ to 239₁₀. When the IC card 1 is inserted into the connector 237, the guide strip 241 is fitted into the guide groove 13. The IC card 1 is thus guided into the connector 237. Further, once the elastic engagement strip 242 is fitted into the recess 7, the IC card 1 is prevented from slipping out of the connector 237. While the IC card 1 partly inserted in the connector 237 remains at its insertion/removal position, its back 2f projects from the upper surface 221a of the main body 221. Therefore, the user can see the label 10.

Thereafter, the user holds the connector 237 now holding the IC card 1, with the fingers, and rotates the connector 237 in the direction of arrow A. The connector 237 is thereby moved from the insertion/removal position to a prescribed position in the holding recess 236. At the prescribed position, data can be recorded in and reproduced from the IC card. To know what is recorded in the IC cards 1 held in the holding recess 236, the user may rotate the connectors 237 holding these IC cards 1 in the direction opposite to arrow A (FIG. 21), moving the connectors 237 to their insertion/removal positions. At their insertion/removal positions, the IC cards 1 project from the upper surface 221a of the main body 221. The user can therefore see the labels 10 on the IC cards 1.

To remove an IC card 1 from the holding recess 236, the user holds, with fingers, the connector 237 holding the IC card 1 and lying in the holding recess 236. Then, the user rotates the connector 237 in the direction opposite to arrow A shown in FIG. 21. Thereafter, the user pulls the IC card 1 in the direction opposite to arrow B shown in FIG. 21, removing the IC card 1 from the connector 237.

The card holding section 222 described above is provided in one corner of the upper surface 221a of the main body 221. It has two openings 246 and 247 at the front 221b and one side 221d of the main body 221, respectively. The user can therefore easily inserts and remove IC cards into and from the card holding section 222. Through the opening 247 the user can see through the opening 247 the label 10 on the IC card 1 which is held in the holding recess 236 and which is located closer to the side 221d than any other IC cards 1. To read the label 10 on the IC card 1 inserted in the holding recess 236, the user rotates, with fingers, the connector holding this IC card 1 in the direction opposite to arrow A (FIG. 21). The label 10 on the IC card 1 is thereby turned outside. The user can therefore easily read the label 10. The user can record and reproduce data in and from any IC card 1 held in a connector 237 even while the connector 237 lies in the insertion/removal position. Since the card holding section 222 can hold a plurality of IC cards 1 at a time, the user can achieve the management of small IC cards 1.

The circuit configuration of the recording/reproducing apparatus 220 is almost the same as the circuit configuration illustrated in FIG. 13. The circuit components of the apparatus 220, which are identical to those shown in FIG. 13, will not be described.

The memory interface 267, i.e., the interface for the six connectors 237a to 237f of the card holding section 222, is similar in structure to the memory interface 87 that has been described with reference to FIG. 13.

The sequence of steps, from the step of inserting an IC card 1 into any one of the connectors 237 of the memory interface 267 to the step of selecting a desired IC card 1, are the same as in the embodiment shown in FIG. 13.

IC cards 1, each with music data recorded in it, are inserted into some of the six connectors 237a to 237f. The music data can be continuously reproduced from these IC cards 1 in the same manner as described with reference to FIG. 15.

As described above, the card holding section 222 provided in the upper surface 221a of the main body 221 can hold six IC cards 1 at most. The number of IC cards 1 that can be held in the section 222 at a time is not limited to six. Moreover, the card holding section 222 may not be provided in the upper surface 221a, but in the front 221b (i.e., the control panel) or in one side of the main body 221.

As FIG. 19 shows, the recording/reproducing apparatus 220 comprises a display section 223, a headphone terminal 224 and a microphone terminal 225, which are provided in the front 221b of the main body 221. The display section 223 is a liquid crystal display or the like. A headphone and a microphone, i.e., a device for collecting sound, may be connected to the headphone terminal 224 and microphone terminal 225, respectively. A line-output terminal 226 and a line-input terminal 227 are provided in the front 221b of the main body 221, too. Moreover, a digital input terminal 228 is provided in the front 221b. Further, a UBS (Universal Serial Bus) connector 229 is provided in the front 221b of the main body 221.

An operation section 231 is provided on the front 221b of the main body 221. The operation section 231 comprises a power-supply button, a reproduction button, a recording button, a volume button, an edition button, a menu button and the like. The power-supply button is pushed to start or stop the supply of power. The reproduction button is depressed to start the reproduction of the data recorded in IC cards 1. The record button is operated to start the recording of data in IC cards 1. The volume button is depressed to control the volume of sound reproduced. The edition button is pushed to start the edition of the data recorded in IC cards 1. The menu button is pushed to select one of various operation menu items of the main body 221.

This invention may provide another recording/reproducing apparatus, which will be described below.

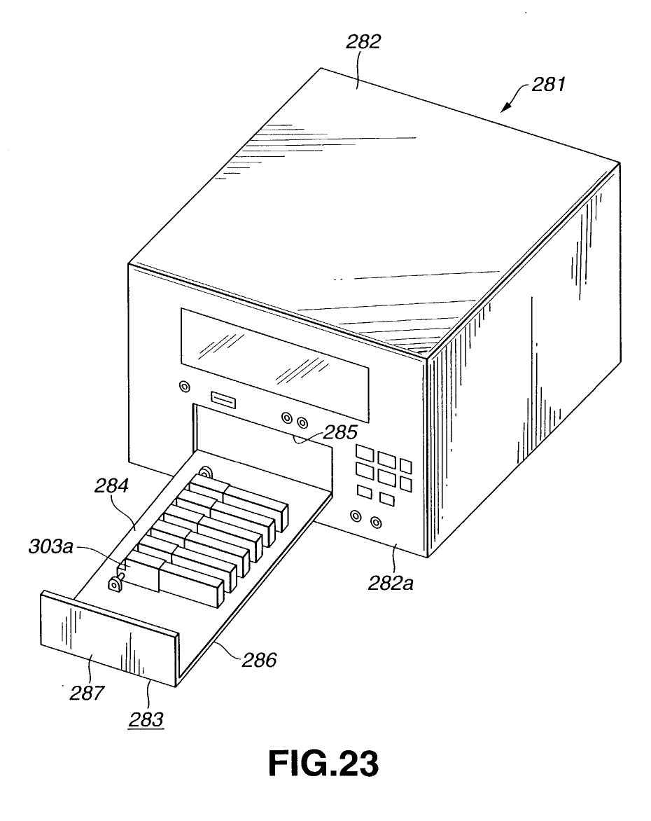

As FIG. 23 shows, this recording/reproducing apparatus 281 has a tray 283 that can slide into and from the main body 282 of the apparatus 281. A card holding section 284 is provided on the tray 283, for holding a plurality of IC cards 1, for example six IC cards, at a time.

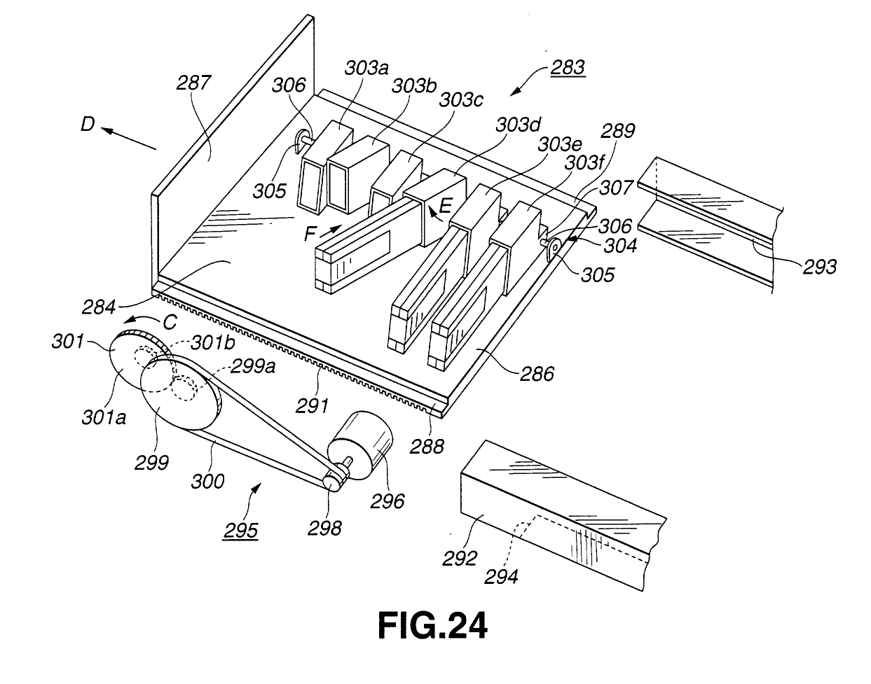

As illustrated in FIG. 23, the tray 283 can move from and into the main body 282 through the insertion/removal port 285 made in the front 292a of the main body 282, which serves as a control panel. The insertion port 285 is rectangular and large enough to allow the tray 283 holding IC cards 1 to moved from and into the main body 282. As FIGS. 23 and 24 show, the tray 283 provided at the insertion/removal port 285 has a tray body 286 and a cover 287. The tray body 286 is rectangular and supports the card holding section 284. The cover 287 extends from the tray body 286 in a substantially vertical direction, closing the insertion/removal port 285. The tray body 286 is large enough to hold six rectangular IC cards 1, which are arranged in a row, each extending in the direction substantially at right angles to the direction of moving the tray 283. Guide rails 288 and 289 are laid on the sides of the tray body 286, so that the tray 283 may smoothly move into and from the main body 282. A rack 291 is laid on the guide rail 288 and engages with a tray drive mechanism 295.

As shown in FIG. 24, guide-rail holders 292 and 293 are provided, each having a C-shaped cross section. The holders 292 and 293 hold the guide rails 288 and 289, respectively. The guide-rail holder 292 has a notch 294 at one end. The rack 291 is exposed outside through the notch 294 and fastened to the tray drive mechanism 295.

As seen from FIG. 24, the tray drive mechanism 295 for moving the tray 283 comprises a drive motor 296, a first pulley 298, a second pulley 299, an endless belt 300, and a drive gear unit 301. The first pulley 298 is fastened to the shaft of the drive motor 296. The second pulley 299 is mounted on the main body 282. The endless belt 300 is wrapped around the first and second pulleys 298 and 299. The drive gear unit 301 comprises a gear section 299a, a first gear 301a, and a second gear 301b. The gear section 299a is formed integral with the second pulley 299. The first gear 301a meshes the gear section 299a. The second gear 301b, which has a smaller diameter than the first gear 301a, meshes the rack 291.

The tray 283 is moved from the main body 282, in the direction of arrow D shown in FIG. 24, when the drive motor 296 rotates the first gear 301a in the direction of arrow C shown in FIG. 24. The tray 283 is moved into the main body 282, the direction opposite to arrow D, when the drive motor 296 rotates the first gear 301a in the direction opposite to arrow C (FIG. 24).

On the main body 286 of the tray 283 there is provided a card holding section 284. The card holding section 284 can hold a plurality of IC cards 1, for example six IC cards at most. Like the card holding section 222 described earlier, the section 284 has connectors 303a to 303f (hereinafter referred to as “connectors 303,” too). The section 222 further has a support mechanism 104 that holds the connectors 303, allowing them to rotate. The connectors 303a to 303f are arranged in a row, each extending in the direction substantially at right angles to the direction of moving the tray 283.

The support mechanism 304 comprises a pair of support strips 305, an axle 306, and rotating strips 307. The support strips 305 are formed integral with the tray body 286. The axle 306 is supported by the support strips 305 can rotate around its axis. The rotating strips 307 are secured at one end to the backs of the connectors 303 and at the other end to the axle 306. The connectors 303 can therefore be rotated around the axle 306 between an insertion/removal position and a specific position in the card holding section 284.

In the recording/reproducing apparatus 281 described above, IC cards 1 are inserted and removed into and from the connectors 303 as will be explained below. At first, the user pushes the operation button arranged on the front 282a of the main body 282 to replace an IC card 1 with another. The drive motor 296 is thereby driven in one direction, rotating the drive gear 301 in the direction of arrow C shown in FIG. 24. Fastened to the rack 291 meshes the drive gear 301, the tray 283 moves in the direction of arrow C (FIG. 24), thus projecting from the main body 282. The card holding section 284 mounted on the main body 286 is thereby exposed outside. The user rotates the connector 303 of the address at which he or she wants to insert the IC card 1, around the axle 306 in the direction opposite to arrow E (FIG. 24) and thus moved to the insertion/removal position. The terminal section 3 of the IC card 1 is inserted into the connector 303 now located at the insertion/removal position. Then, the user rotates the connector 337 holding the IC card 1, around the axle 306 to the specific position in the card holding section 284.

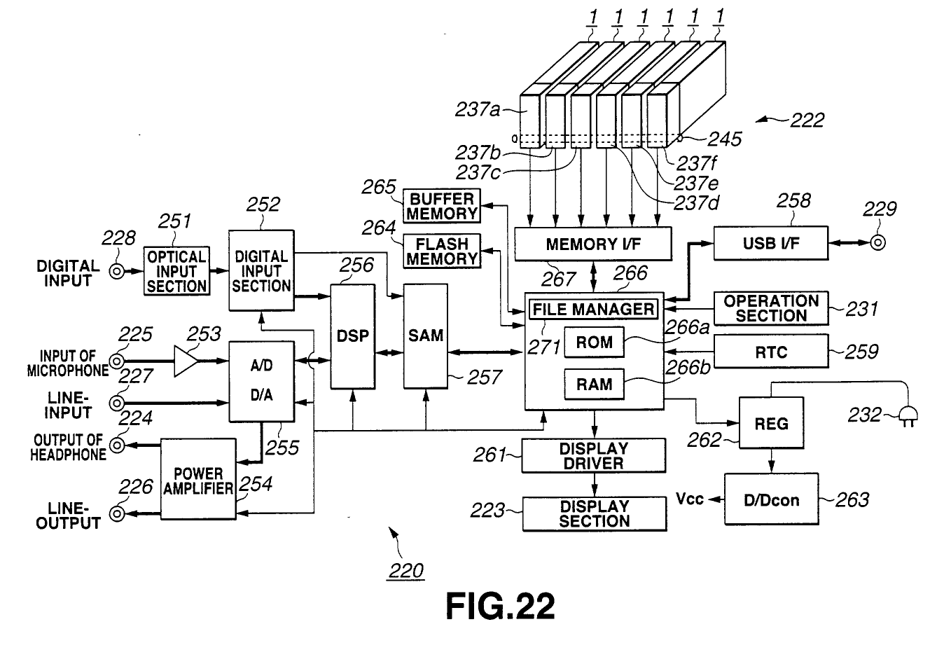

When the operation button is pushed thereafter, the drive gear 301 rotates in the direction opposite to arrow C (FIG. 24). The tray 283 meshes the drive gear 301 moves into the main body 282, that is, in the direction opposite to arrow C (FIG. 24). In this recording/reproducing apparatus 280, data is recorded and reproduced in and from IC cards 1 in the same manner as has been explained with reference to FIG. 22.

In the recording/reproducing apparatus 281 thus constructed, the tray 283 can hold a plurality of IC cards 1. This makes it possible to reproduce or dub data continuously from or in two or more IC cards 1. The IC card 1 held in any connector 303 at the specific position in the card holding section 284 can be identified, merely by rotating the connector 303 from that specific position to the insertion/removal position. Once the IC card 1 is located in the insertion/removal position, the user can see the label 10 on the IC card 1.

The card holding section 284 has been described. The number of IC cards 1 that can be held in the section 284 at a time is not limited to six.

The apparatuses 220 and 280, each designed to record and reproduce data in and from IC cards 1, have been described with reference to some drawings. Nonetheless, the present invention is not limited to the apparatuses 220 and 280. For example, the data communication between the terminal section of each IC card 1 and any connector may be accomplished by radio. Additionally, the apparatuses 220 and 280 may be either recording apparatuses or reproducing apparatuses.

Another embodiment of the invention, i.e., an apparatus 420 designed to record and reproduce data in and from IC cards 1, will be described with reference to some other drawings.

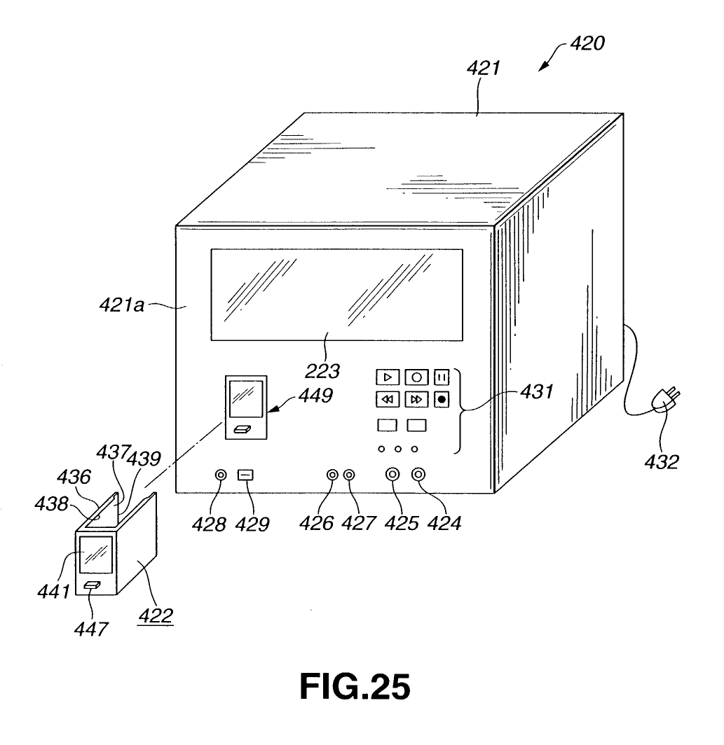

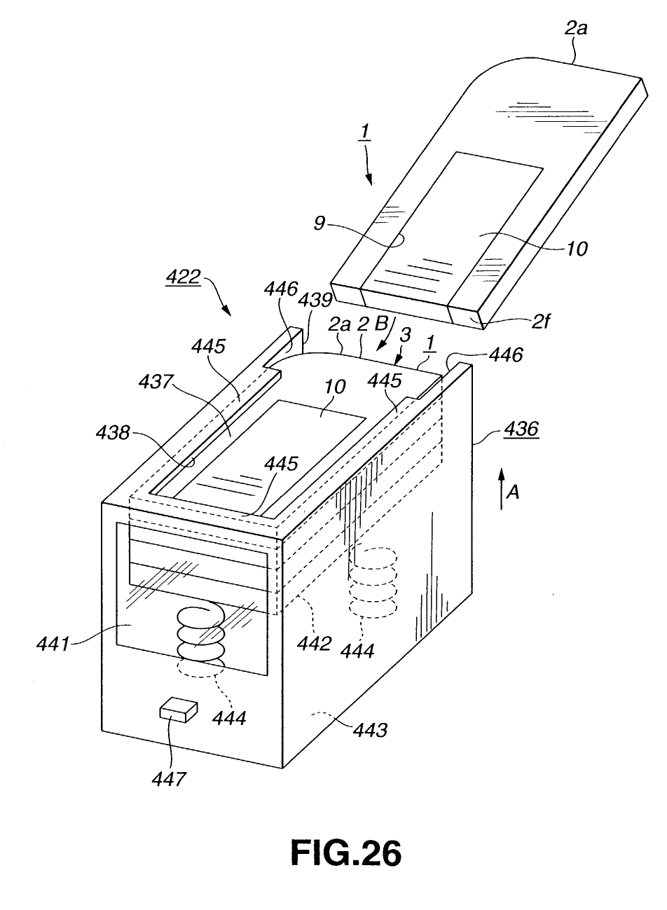

The recording/reproducing apparatus 420 is a stationary one, like the apparatus that has been described with reference to FIG. 19. As shown in FIG. 25, the apparatus 420 comprises a holding mechanism 422 that can be removed from the main body 421. The holding mechanism 422 is substantially rectangular as illustrated in FIG. 26. The mechanism 422 has a receptacle 436, which contains a stack of IC cards 1. The receptacle 436 is a substantially rectangular box made of, for example, synthetic resin by means of injection molding. The receptacle 436 has a card holding section 437, in which IC cards 1 may be laid one upon another. More precisely, the section 437 can contain at most six IC cards 1, each having its bottom 2b facing the top 2e of the IC card located immediately below. The top of the receptacle 436 has a first opening 438, through which IC cards 1 can be inserted and removed into and from the card holding section 437. That side of the receptacle 436, which is first inserted into the main body 421, has a second opening 439. Through the opening 439, any IC card 1 contained in the card holding section 437 is exposed outside. The first opening 438 is large enough to enable the user to see, through it, the label 10 on the uppermost IC card 1 held in the card holding section 437. Hence, the user can know what is recorded in the IC card 1. The terminal section 3 of any IC card 1 held in the card holding section 437 is exposed outside through the second opening 439. The second opening 439 therefore enables the electrodes 3b of the terminal section 3 to be electrically connected to the connectors provided in the main body 421. The front of the receptacle 436, which opposes the back having the second opening 439, has a window 441. Through the window 441, the user can see the IC cards 1 held in the card holding section 437, from outside. The window 441 is a transparent plate made of synthetic resin, which is fitted in an opening cut in the front of the receptacle 436. The back 2f of each IC card 1 held in the card-holding section 437 can be seen from outside, and the user can know how many IC cards are held in the card holding section 437. A knob 447 protrudes from the front of the receptacle 436, in which the window 441 is provided. The user may holds the knob 447 to draw the receptacle 436 from the main body 421.

The card holding section 437 has a support plate 442 for supporting IC cards 1. The support plate 442 can move in the direction the IC cards 1 are laid on upon another, that is, in the direction of arrow A shown in FIG. 26 and the direction opposite thereto. The plate 442 can so move, guided by the inner surfaces of the receptacle 436. Coil springs 444 are interposed between the support plate 442 and the inner bottom 443 of the receptacle 436. The coil springs 444 bias the support plate 442 toward the first opening 438, namely in the direction of arrow A (FIG. 26).

A stopper 445 is provided at the rim of the second opening 439 made in the top of the receptacle 436. The stopper 445 prevents the support plate 442 from projecting from the first opening 438 due to the bias of the coil springs 444 The stopper 445 also prevents the IC card 1 stored in the receptacle 436 from projecting from the first opening 438 due to the biased support plate 442 by the coil spring 444. The stopper 445 has notches 446 at the end close to the second opening 439. The notches 446 facilitate the insertion of IC cards 1 into the receptacle 436.

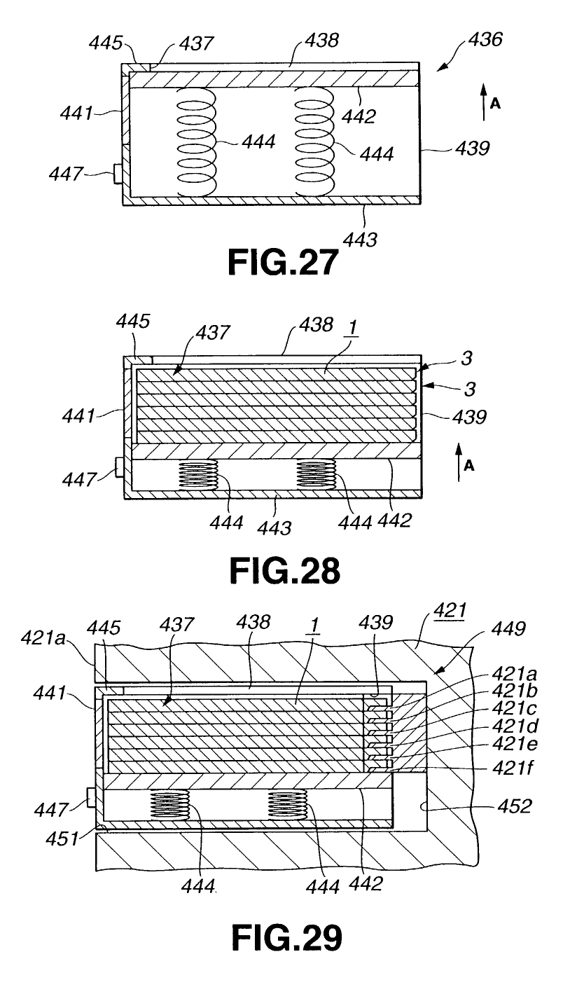

In the holding mechanism, when the receptacle 436 contains no IC cards 1 as shown in FIG. 27, the support plate 442 abuts on the stopper 445, biased by the coil springs 444 in the direction of arrow A. To insert an IC card 1 into the receptacle 436 in this condition, the user holds the IC card 1, with the back 2f thereof pressed onto that part of the support plate 442 which is not covered by the stopper 445. The user then pushes the IC card 1 in the direction of arrow B as is illustrated in FIG. 26. The support plate 442 is thereby rotated in the direction opposite to arrow A (FIG. 26) against the bias of the coil springs 444. When the IC card 1 is completely mounted on the support plate 442, the support plate 442 is again biased in the direction of arrow A by the coil springs 444. The top 2e of the IC card 1 abuts on the stopper 445. The IC card 1 is therefore held in the card holding section 437, exposed to the outside through the second opening 439. As FIG. 28 shows, the card holding section 437 may hold a stack of six IC cards 1, each having its bottom 2b contacting the top 2e of the IC card 1 positioned immediately below. To remove the uppermost IC card 1 from the card holding section 437, the user holds the card 1 with fingers and pulls it in the direction opposite to arrow B (FIG. 26). When the uppermost IC card 1 is removed from the card holding section 437, the top 2e of the second uppermost IC card 1 abuts oil the stopper 445.

As FIG. 29 illustrates, the holding mechanism 422 described above is inserted into a holding section 449 provided in the front 21a of the main body 421. The holding section 449 has an insertion port 451, through which the mechanism 422 can be inserted into the main body 421. Through the insertion port 451, the receptacle 436 is inserted, first at the end having the second opening 439. Connectors 452a to 452f (hereinafter referred to as “connectors 452,” too) are provided on the inner surface of the holding section 449, which opposes the second opening 439 of the receptacle 436. The connectors 452a to 452f can be connected to the terminal sections 3 of six IC cards 1, respectively. Each connector has connection terminals 453₁ to 453₁₀, which are to be electrically connected to the electrodes 3b₁ to 3b₁₀ that constitute the terminal section 3. The connection terminals 453₁ to 453₁₀ are provided in the same number as the electrodes 3b₁ to 3b₁₀ that constitute the terminal section 3 of an IC card 1.

The receptacle 436 is inserted into the holding section 449, first with the end having the second opening 439. When the receptacle 436 is completely inserted into the holding section 449, the connection terminals 453 of each connector 452 are electrically connected to the electrodes 3b constituting the terminal section 3 of one IC card 1 held in the receptacle 436. In this condition, data is recorded in or reproduced from the IC card 1 held in the receptacle 436. The user can see the IC cards in the receptacle 436 through the window 441 and know how many IC cards are contained in the receptacle 436. The user may hold the knob 447 with fingers, to draw the receptacle 436 from the holding section 449.

In the recording/reproducing apparatus 420 shown in FIG. 25, the holding mechanism 422 can hold a plurality of IC cards 1. The receptacle 436 can be inserted into the holding section 449. This makes it easy for the user to perform the management of the small IC cards 1. Since the mechanism 422 can hold many IC cards, the apparatus 420 can record a great amount of data in the IC cards, without replacing the IC cards with new ones. Further, a large amount of data can be continuously reproduced from the IC cards 1. With the apparatus 420 it is easy to record data in, and reproduce data from, IC cards 1.

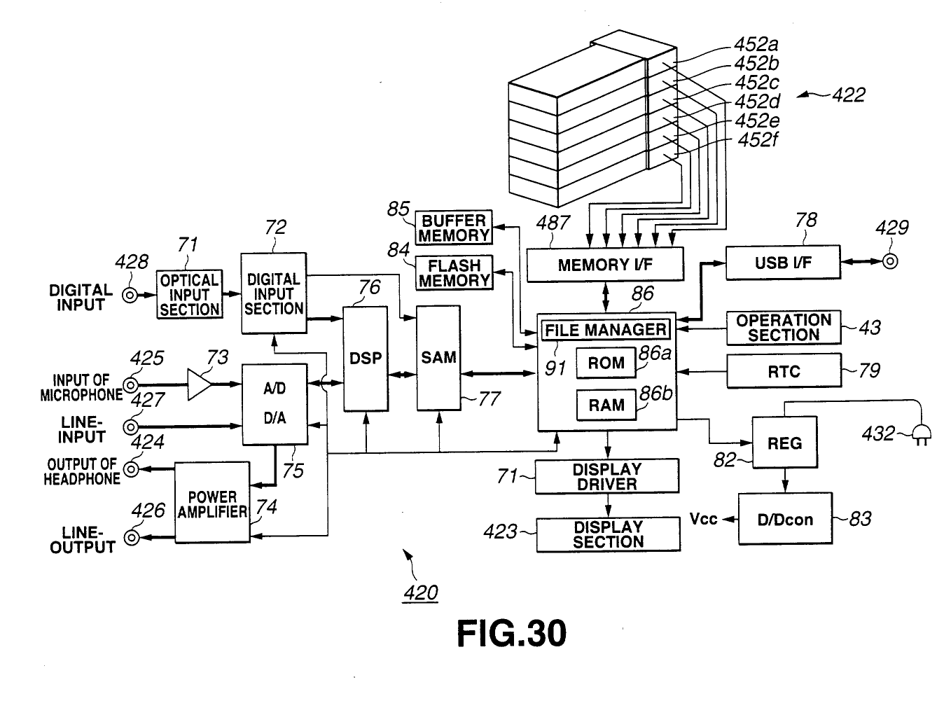

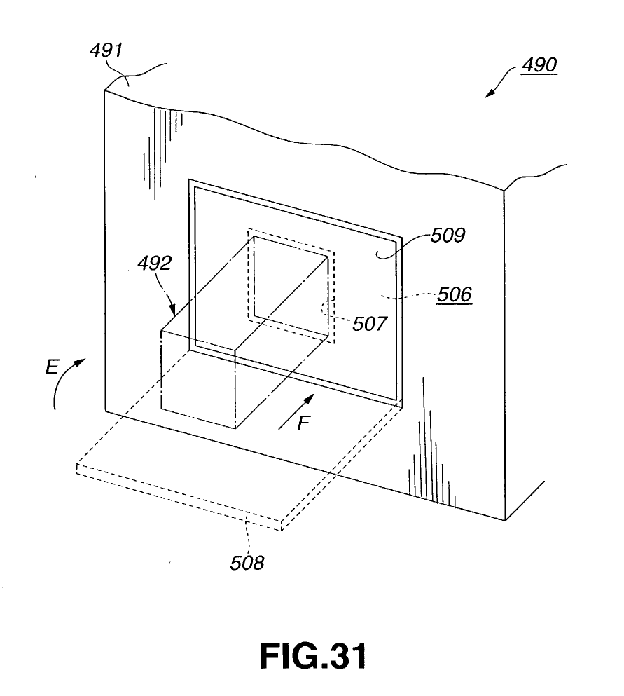

The recording/reproducing apparatus 420 has the circuit configuration of FIG. 30. As clear from FIG. 30, the circuit configuration of the recording/reproducing apparatus 420 is almost the same as that of the apparatus 420, which is shown in the block diagram of FIG. 31. The circuit components of the apparatus, which are identical to those shown in FIG. 31, will not be described in detail.

The memory interface 487, i.e., the interface for the six connectors 452a to 452f, is similar in structure to the memory interface 87 that has been described with reference to FIG. 31.

The sequence of steps, from the step of inserting an IC card 1 into any one of the connectors 452 of the memory interface 487 to the step of selecting a desired IC card 1, are the same as in the recording/reproducing apparatus 420 shown in FIG. 31.

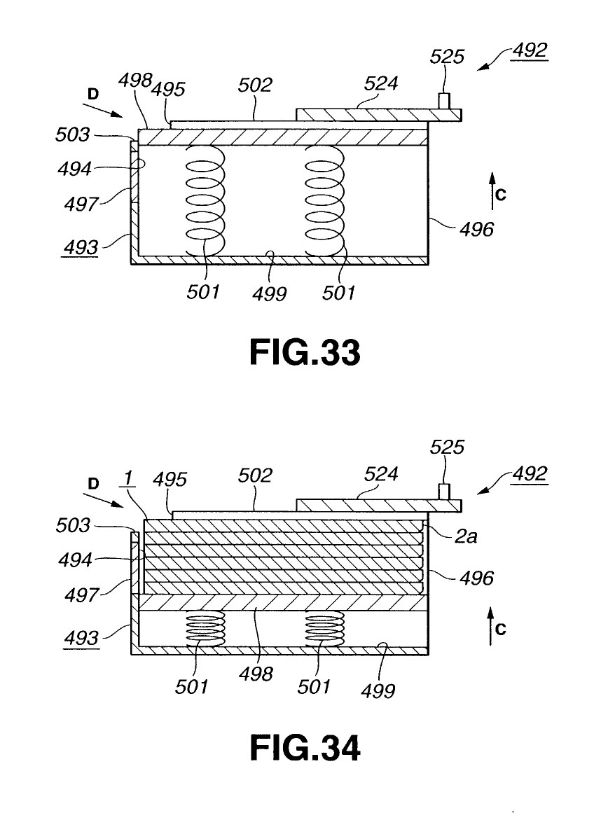

IC cards 1, each with music data recorded in it, are inserted into some of the six connectors 52a to 52f. The music data can be continuously reproduced from these IC cards 1 in the same manner as described with reference to FIG. 33.

The transfer-mode process of transferring the data recorded in one IC card 1 to another IC card 1 is carried out in the same sequence as explained with reference to FIG. 34. The process will not be described in detail.

The receptacle 436 of the holding mechanism 422 can hold at most six IC cards 1. The number of IC cards 1 that can be held in the receptacle 436 is not limited to six.

The present invention can provide a recording/reproducing apparatus of the following structure.

This recording/reproducing apparatus 490 has a holding mechanism 492 in which IC cards 1 are held, stacked one upon another. As shown in FIG. 31, the holding mechanism 492 is moved between a specific position in the main body 491 and an insertion/removal position at which IC cards 1 can be inserted into and removed from the mechanism 492. The circuit configuration of the apparatus 490 will not be described in detail, because it is similar to that of the recording/reproducing apparatus 420 described above.

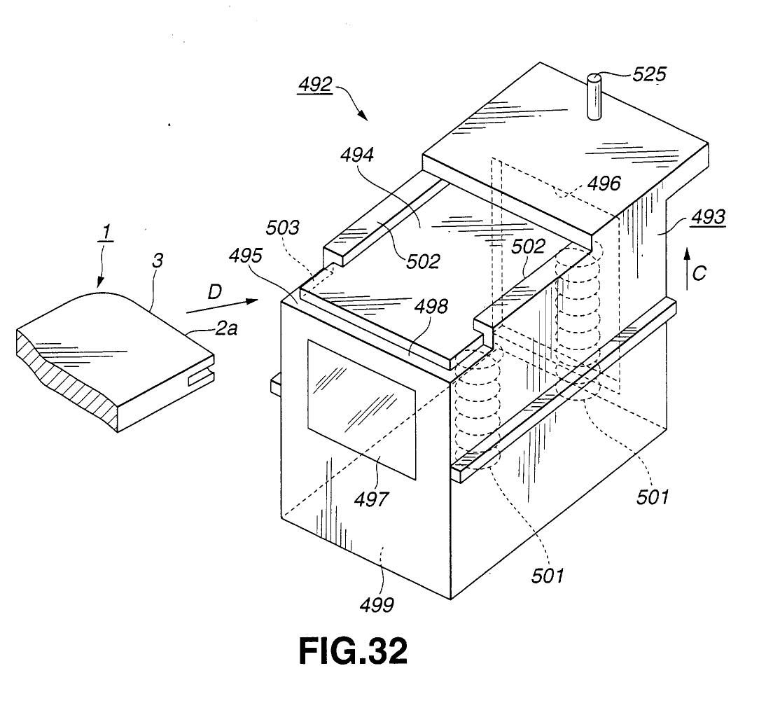

The holding mechanism 492, in which a plurality of IC cards 1 may be laid one upon another, is substantially rectangular as is illustrated in FIG. 32. The mechanism 492 has a receptacle 493 for holding a stack of IC cards 1. The receptacle 493 is a substantially rectangular box made of, for example, synthetic resin by means of injection molding. The receptacle 493 has a card holding section 494, which may contain a stack of IC cards 1. To be more specific, the section 494 can hold at most six IC cards 1, each having its bottom 2b facing the top 2e of the IC card located immediately below. The top of the receptacle 493 has a first opening 495, through which IC cards 1 can be inserted and removed into and from the card holding section 494. That side of the receptacle 493, which is first inserted into the main body 491, has a second opening 496. Through the opening 496, the terminal section 3 of any IC card 1 contained in the card holding section 494 is exposed outside. The first opening 495 is large enough to enable the user to see, through it, the label 10 on the uppermost IC card 1 held in the card holding section 494. The user can therefore know what is recorded in the IC card 1. The terminal section 3 of any IC card 1 held in the card holding section 494 is exposed outside through the second opening 496. The second opening 496 therefore enables the electrodes 3b of the terminal section 3 to be electrically connected to the connectors provided in the main body 421. The front of the receptacle 493, which opposes the back having the second opening 496, has a window 497. Through the window 497, the user can see the IC cards 1 held in the card holding section 494, from outside. The window 497 is a transparent plate made of synthetic resin, which is fitted in an opening cut in the front of the receptacle 493. The back 2f of each IC card 1 held in the receptacle 493 can be seen from outside. The user can therefore know how many IC cards are held in the receptacle 493.

The card holding section 494 has a support plate 498 for supporting IC cards 1. The support plate 498 can move in the direction the IC cards 1 are laid on upon another. That is, the plate 498 can move in the direction of arrow A shown in FIG. 32 and the direction opposite thereto, guided by the inner surfaces of the receptacle 493. Coil springs 501, or bias members, are interposed between the support plate 498 and the inner bottom 499 of the receptacle 493. The coil springs 501 bias the support plate 498 toward the first opening 495, namely in the direction of arrow A shown in FIG. 32.

A stopper 502 is provided at the rim of the second opening 495 made in the top of the receptacle 493. The stopper 502 prevents the support plate 498 from projecting from the first opening 495 due to the bias of the coil springs 501. The stopper 502 also prevents the IC card 1 stored in the card holding section 494 from projecting from the first opening 495 due to the biased support plate 498 by the coil spring 501. The stopper 502 has notches 503 at the end close to the second opening 496 The notches 503 facilitate the insertion of IC cards 1 into the receptacle 493.

When the receptacle 436 contains no IC cards 1 as shown in FIG. 33, the support plate 498 abuts on the stopper 502, biased by the coil springs 501 in the direction of arrow C. To insert an IC card 1 into the receptacle 436 in this condition, the user holds the IC card 1, with the front 2a thereof pressed onto that part of the support plate 498 which is not covered by the stopper 445, or exposed through the notches 503. The user then pushes the IC card 1 in the direction of arrow D as is illustrated in FIG. 32. The support plate 498 is thereby pushed down against the bias of the coil springs 501. The IC card 1 is thereby inserted into the space provided between the stopper 502 and the support plate 498. When the IC card 1 is completely mounted on the support plate 498, the support plate 498 is again biased in the direction of arrow C (FIG. 32) by the coil springs 501. The rim of the top 2e of the IC card 1 abuts on the stopper 502. The IC card 1 is therefore held in the card holding section 494, exposed to the outside through the second opening 496. As FIG. 34 shows, the card holding section 494 may hold a stack of six IC cards 1, each having its bottom 2b contacting the top 2e of the IC card 1 positioned immediately below. To remove the uppermost IC card 1 from the card holding section 494, the user holds the IC card 1 with fingers and pulls it in the direction opposite to arrow D (FIG. 34). When the uppermost IC card 1 is removed from the card holding section 494, the top 2e of the second uppermost IC card 1 abuts on the stopper 502.

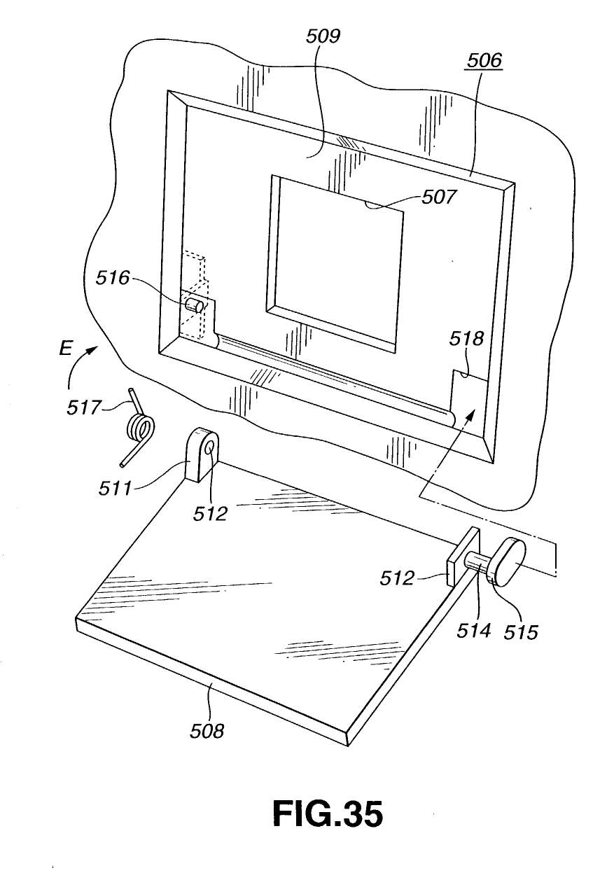

As FIG. 31 illustrates, the holding mechanism 492 described above is inserted into a holding section 506, which is provided in the front 491a of the main body 491. As shown in FIG. 35, the holding section 506 has an insertion/removal port 507 through which the mechanism 492 can be inserted into the front 491a of the main body 491. Through the insertion/removal port 507, the holding mechanism 492 is inserted, first at the end having the second opening 496. The insertion/removal poll 507 is made in a recess 509, which is substantially rectangular and which is made in the front 491a. The recess 509 has a depth almost the same as the thickness of a cover 508. When the cover 508 is fitted into the recess 509 and closes the insertion/removal port 507, it lies substantially in flush with the front 491a of the main body 491. This improves the outer appearance of the main body 491.

As shown in FIG. 35, a support strip 511 is provided on one lower corner of the cover 508 for opening and closing the insertion/removal port 507. The support strip 511 serves to couple the cover 508 to the front 491a, allowing the cover 508 to rotate. The strip 511 has a hole 512 for receiving an axle that is provided on the main body 491. A support strip 513 is provided on the other lower corner of the cover 508. A shaft 514 is formed integral with the support strip 513 and extends outwards. The shaft 514 has a stopper 515 at its distal end. The stopper 515 controls the rotation of the cover 508.

An axle 516 is provided on one lower corner of the recess 509 made in the main body 491. The axle 516 supports the cover 508, allowing the same to rotate. This axle 516 is set in the hole 512 made in the strip 511. A torsion coil spring 517 is mounted on the axle 516. The torsion coil spring 517 biases the cover 508 to rotate the cover 508 in the direction opposite to arrow E shown in FIG. 35. Thus rotated, the cover 508 opens the insertion/removal port 507. The spring 517 comprises a coil and two arms. The coil is wound around the axle 516. The first arm is fastened to the support strip 511, while the second arm is held near the proximal end of the axle 516. Thus arranged, the torsion coil spring 517 biases the cover 508 in the direction opposite to arrow E (FIG. 35). The other lower corner of the recess 509 has a hole 518, in which the shaft 514 provided on the cover 508 is fitted.

The axle 516 is fitted in the hole 512 of the support strip 511 provided in one lower corner of the cover 508. The shaft 514 provided in the other lower corner of the cover 508 is fitted in the hole 518 made in the recess 509. The cover 508 is thereby coupled to the main body 491 and can rotate. Biased by the torsion coil spring 517, the cover 508 is rotated, opening the insertion/removal port 507. The stopper 515 formed integral with the shaft 514 opposes the inner surface of the main body 491, allowing the cover 508 to open and close the recess 509 as the holding mechanism 492 is moved by a drive mechanism that will be described later.

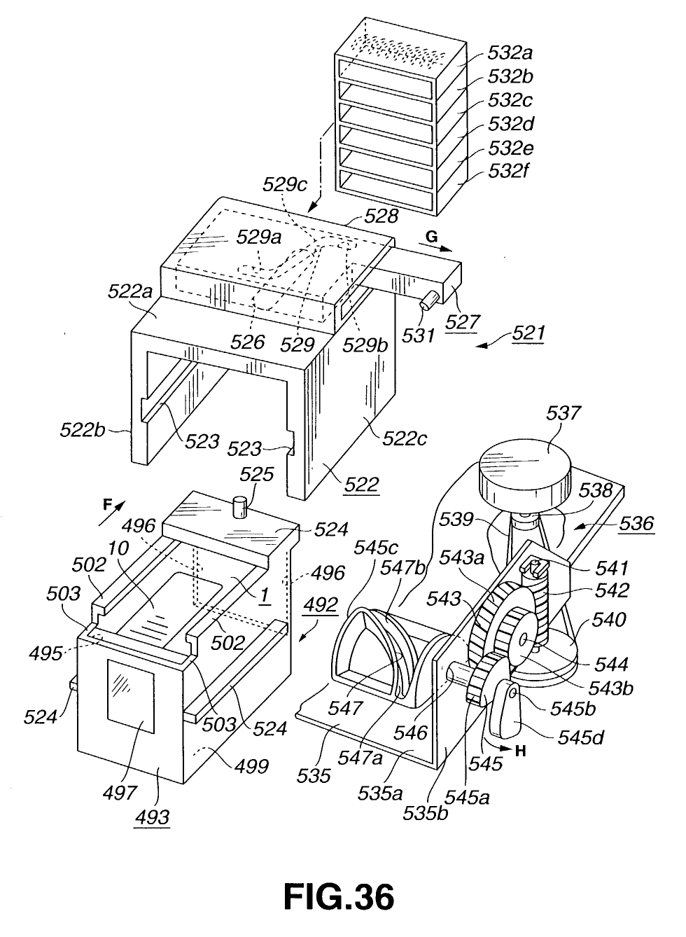

As indicated above, the holding mechanism 492 can move between the specific position in the main body 491 and the insertion/removal position where any IC card 1 can be replaced by another. As shown in FIG. 36, the drive mechanism 521, which moves the holding mechanism 492 between the specific position and the insertion/removal position, has a guide member 522. The guide member 522 guides the holding mechanism 492 between the specific position and the insertion/removal position. The guide member 522 comprises a top plate 522a and side plates 522b and 522c. The side plates 522b and 522c are formed integral with the top plate 522a and extend downwards from the long edges of the top plate 522a. Two grooves 523 are cut in the inner surfaces of the side plates 522b and 522c, respectively, and extend in the direction of driving the holding mechanism 492. Two guide rails 524 are laid on the opposite two sides of the receptacle 493 and extend in the direction of moving the receptacle 493. The guide rails 524 are set in the grooves 523. Hence, the holding mechanism 492 can move back and forth, in the direction of arrow F and the direction opposite to arrow F, as is illustrated in FIG. 36. A top plate 524 is provided on the receptacle 493, near the second opening 496. The top plate 524 closes a part of the first opening 495. The top plate 524 cooperates with the stopper 502 to prevent the support plate 498 and the IC cards 1 on the support plate 498 from projecting from the first opening 495, due to the bias of the coil springs 501. A stop pin 525 protrudes from the top plate 524, to control the motion of the receptacle 493 in the direction of arrow F (FIG. 36) and the direction opposite thereto. The stop pin 525 is set in a guide hole 526 that is cut in the top plate 522a of the guide member 522 and further extends outwards.

A control plate 527 is mounted on the top plate 522a of the guide member 522, for controlling the motion of the holding mechanism 492 by utilizing the drive force of the drive mechanism 521. The control plate 527 can move in the direction of arrow G shown in FIG. 36 and the direction opposite thereto, which are substantially at right angles to the direction in which the holding mechanism 492 moves. The control plate 527 can move in the direction of arrow G (FIG. 36) and the direction opposite thereto, as it is guided by a guide cover 528 that is mounted on the top plate 522a. The control plate 527 has a cam groove 529, which receives the stop pin 525 protruding from the top plate 524 of the receptacle 493. As shown in FIG. 36, the cam groove 529 consists of two horizontal parts 529a and 529b and a slanting part 529c. The horizontal parts 529a and 529b are spaced apart in the direction substantially perpendicular to the direction in which the holding mechanism 492 moves. The slanting part 529c connects the horizontal parts 529a and 529b. The first horizontal part 529a is located near the insertion/removal port 507 of the main body 491. The second horizontal part 529b is located in the rear part of the control plate 527. The horizontal parts 529a and 529b are spaced apart by a distance equal to the distance the holding mechanism 492 can move. The slanting part 529c serves as a cam to guide the control pin 525 between the first horizontal part 529a and the second horizontal part 529b. The holding mechanism 492 moves to the insertion/removal position outside the main body 491, while the stop pin 525 remains in the first horizontal part 529a. While the stop pin 525 remains in the second horizontal part 529b, the holding mechanism 492 moves to the specific removal position in the main body 491. A connection pin 531 projects from one end of the control plate 527 that is substantially rectangular. The connection pin 531 connects the control plate 527 to a drive mechanism that drives the control plate 527 in the direction of arrow G (FIG. 36) and the direction opposite to arrow G.

Connectors 532a to 532f (hereinafter referred to as “connectors 532,” too) are provided at the back of the guide member 522. The connectors 532 can be electrically connected to the terminal section 3 of the IC cards 1 held in the receptacle 493. Each of the connectors 532a to 532f has connection terminals 533 to be electrically connected to the electrodes 3b₁ to 3b₁₀ constituting the terminal section 3 of an IC card 1. Since the connection terminals 533 are similar to the terminals 453₁ to 453₁₀ of the connector 52 described above, they will not be described in detail. The connection terminals 533 are provided in the same number as the electrodes 3b₁ to 3b₁₀ that constitute the terminal section 3 of an IC card 1.

As FIG. 36 shows, the drive mechanism 536 that drives the control plate 527 comprises a chassis 535, a drive motor 537, a first pulley 538, an endless belt 539, a second pulley 540, a shaft 541, a worm gear 542, an intermediate gear unit 543, an axle 544, and a rotation control member 545. The chassis 535 has a bottom plate 535a. The drive motor 537 is mounted on the bottom plate 535a. The first pulley 538 is mounted on the shaft of the drive motor 537. The endless belt 539 couples the second pulley 540 to the first pulley 538. The second pulley 540 is fastened to the shaft 541, on which the worm gear 542 is mounted. The axle 544 horizontally extends from the side plate 535b of the chassis 535. The intermediate gear unit 543 comprises a first gear 543a and a second gear 543b smaller than the first gear 543a and set in mesh with the first gear 543a. The rotation control member 545 has a sector gear 545a meshes the second gear 543b and is configured to control the rotation of the cover 508.

The rotation control member 545 is rotatably supported by a bearing 546 that is provided on the side plate 535b of the chassis 535. The sector gear 545a is mounted on that end of the axle 545 which lies outside the side plate 535b. The control member 545 has a rotation control part 545c on the end that lies inside the side plate 535. The rotation control part 545c is connected to the connection pin 531 that projects from the control plate 527. The control part 545c is shaped like a semicircular hollow cylinder. It has a cam groove 547 in its curved surface. The cam groove 547 extends slantwise from the upper edge to lower edge of the curved surface. The upper end pall 547a of the cam groove 547 extends in the direction of arrow G (FIG. 36). The upper end part 547a guides the stop pin 525 and the control plate 527, along the first horizontal part 529a of the cam groove 529, thereby to move the holding mechanism 492 moves to the insertion/removal position. The lower end part 547b of the cum groove 547 extends in the direction opposite to arrow G (FIG. 36). The lower end part 547b guides the stop pin 525 along the second horizontal part 529b of the cam groove 529, thereby to move the holding mechanism 492 moves to the specific position in the main body 491.

The control member 545 has an engagement strip 545d that can contact the stopper 515 provided on the cover 508.

In the drive mechanism 536 thus constructed, the first pulley 538 rotates when the drive motor 537 is driven in one direction or the other as shown in FIG. 36. The endless belt 539 drives the second pulley 540. The intermediate gear unit 543 therefore rotates the control member 545 around the shaft 545b, in the direction of arrow H and the direction opposite thereto. As the control member 545 is so rotated, the engagement strip 545d of the control member 545 contacts the stopper 515 provided on the cover 508 which opens the insertion/removal port 507 of the main body 491 by virtue of the bias of the torsion coil spring 517. The engagement strip 545d therefore controls the rotation of the cover 508. On the other hand, the connection pin 531 projecting from the control plate 527 moves between the upper and lower ends of the cam groove 547. As a result, the holding mechanism 492 moves between the insertion/removal position and the specific position in the main body 491, which IC cards 1 may take.

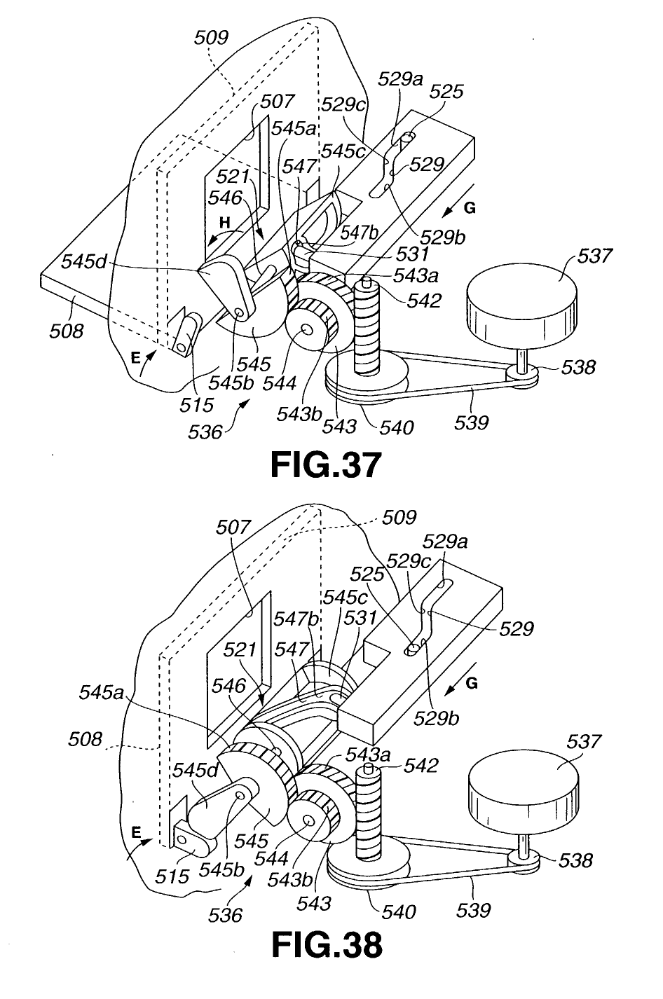

The sequence of steps of moving the holding mechanism 492 moves between the insertion/removal position and the specific position in the main body 491 will be explained. The drive motor 537 of the mechanism 536 is driven in one direction as shown in FIG. 37 while the holding mechanism 492 remains at the insertion/removal position, or outside the main body 491 of the apparatus. The rotation control member 545 is rotated around the shaft 545b in the direction opposite to arrow H (FIG. 37). The engagement strip 545d of the rotation control member 545 no longer contacts the stopper 515 provided on the cover 508. The cover 508 therefore rotates in the direction opposite to arrow E (FIG. 37), biased by the torsion coil spring 517. Thus, the cover 508 opens the insertion/removal port 507 of the main body 491. The connection pin 531 projecting from the control plate 527, which is set in the cam groove 547 of the rotation control member 545, now contacts the upper end part 547a of the cam groove 547. The control plate 527 has been moved in the direction of arrow G shown in FIG. 37. The stop pin 525 provided on the holding mechanism 492 has moved to the first horizontal part 529a of the cam groove 529. The holding mechanism 492 moves in the direction opposite to arrow F shown in FIG. 36 to the insertion/removal position.

While holding mechanism 492 stays at the insertion/removal position, the IC cards 1 can be inserted and removed into and from the card holding section 494. More specifically, the user may insert an IC card 1, first at its front 2a having the terminal section 3, in the direction of arrow D from the front of the receptacle 493, which has the notches 103. When the IC card 1 completely lies on the support plate 498, the support plate 498 is biased in the direction of arrow C as shown in FIG. 36 by the coil springs 501. The IC card 1 abuts on the stopper 502, at the edge of its top 2e. The IC card 1 is thus held in the card holding section 494, with its terminal section 3 exposed through the second opening 496. In the card holding section 494, six IC cards 1, for example, may be stored, each having its bottom 2b opposing the top 2e of the immediately lower IC card, as is illustrated in FIG. 34. To remove the uppermost IC card 1 stored in the card holding section 494, the user holds the IC card 1 with fingers and slides the IC card 1 in the direction opposite to arrow D (FIG. 34). When the uppermost IC card 1 is thus removed from the card holding section 494, the second uppermost IC card 1 abuts on the stopper 502, at the edge of its top 2e.

How the holding mechanism 492 is moved to the card-holding position in the main body 491 will be described. When the drive motor 537 of the drive mechanism 536 is driven in the reverse direction, the rotation control member 545 rotates around the shaft 545b in the direction of arrow H. The engagement strip 545d of the rotation control member 545 comes into engagement with the stopper 515 provided on the cover 508. The cover 508 rotates in the direction of arrow E (FIG. 38), against the bias of the torsion coil spring 517. The insertion/removal port 507 of the main body 491 is thereby closed. At the same time, the connection pin 531 projecting from the control plate 527 stays at the lower end part 547b of the cam groove 547 of the rotation control member 545. Hence, the control plate 527 moves in the direction opposite to arrow G as is illustrated in FIG. 38. The stop pin 525 provided on the holding mechanism 492 moves to the second horizontal part 529b of the cam groove 529. The holding mechanism 492 therefore moves in the direction of arrow F (FIG. 36) to the card-holding position in the main body 491.

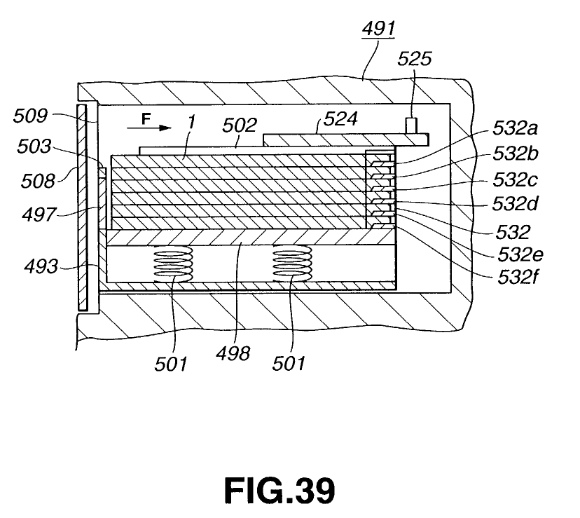

Then, as shown in FIG. 39, the electrodes 3b of the terminal section 3 now held in the receptacle 493 are electrically connected to the terminals 453 of the connector 452 that is provided at the back of the guide member 522. In this condition, data can be recorded and reproduced in and from the IC card 1 held in the receptacle 493.

To move the holding mechanism 492 from the card-holding position to the insertion/removal position of the IC card 1, the drive motor 537 is driven in one direction as shown in FIG. 37. The rotation control member 545 therefore rotates around the shaft 545b in the direction opposite to arrow H shown in FIG. 37. The engagement strip 545d of the rotation control member 545 is thereby released from the stopper 515 provided on the cover 508. Then, the cover 508 rotates in the direction opposite to arrow E (FIG. 37) by virtue of the bias of the torsion coil spring 517, opening the insertion/removal port 507 of the main body 491. At the same time, the connection pin 531 projecting from the control plate 527 moves along the cam groove 547 of the rotation control member 545, reaching the upper end part 547a of the cam groove 547. The control plate 527 moves in the direction to arrow G as is illustrated in FIG. 37, and the stop pin 525 provided on the holding mechanism 492 moves to the first horizontal part 529a of the cam groove 529. The holding mechanism 492 therefore moves in the direction opposite to arrow F (FIG. 36) to the insertion/removal position of the IC card 1.

In the recording/reproducing apparatus 420 so constructed as described above, the holding mechanism 492 can hold a plurality of IC cards 1 and the holding section 506 can holds the receptacle 493. When the holding mechanism 492 holds a plurality of IC cards 1, data can be continuously reproduced from the IC cards 1 and data recorded in an optical disc can be dubbed into the IC cards 1 of various types held in the holding mechanism 492. Thus, with the recording/reproducing apparatus 420 it is easy to record and reproduce data. That is, the apparatus 420 is user-friendly. Further, the apparatus 420 has high operability because the drive mechanism 521 automatically inserts and removes the holding mechanism 492 into and from the holding section 506.

The holding mechanism 492 can hold at most six IC cards 1. Nonetheless, the number of IC cards 1 that can be held in the holding mechanism 492 is not limited to six.

Two recording/reproducing apparatuses 420 and 490, each using IC cards 1 as recording media, have been described with reference to the drawings. Nonetheless, the present invention is not limited to the apparatuses 420 and 490. For example, the data communication between the terminal section of each IC card 1 and any connector may be accomplished by radio. Moreover, the apparatuses may be either recording apparatuses or reproducing apparatuses.

A recording/reproducing apparatus 620 will be described below, which can hold a plurality of IC cards 1 in the form of a stack.

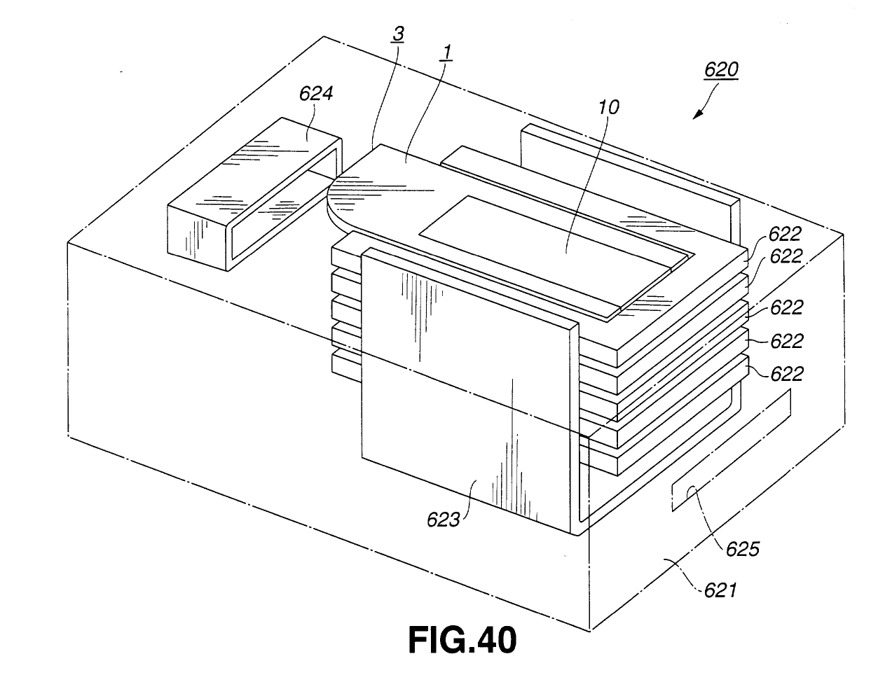

As FIG. 40 shows, the recording/reproducing apparatus 620 has a main body 621. The main body 621 incorporates holding members 622, a receptacle 623, and a recording/reproducing section 624. The holding members 622 are provided to hold an IC card 1 each. The receptacle 623 holds the holding members 622, one above another. The recording/reproducing section 624 is designed to record and reproduce data in and from one of the IC cards 1 held in the receptacle 623. When the user of the recording/reproducing apparatus 620 selects the address of one of the holding members 622, the receptacle 623 is moved up or down to bring the holding member 622 selected, to the level at which the recording/reproducing section 624 is positioned. Then, the holding member 622 holding an IC card 1 is moved to a position. At this position, the IC card 1 is connected to the recording/reproducing section 624. Thereafter, data is recorded in or reproduced from the IC card 1.

The main body 621 has an insertion/removal poll 625 in its front. The holding members 622, each holding an IC card selected by the user, can be removed through the insertion/removal port 625. Another can replace any IC card 1 at a card-exchanging position outside the main body 621.

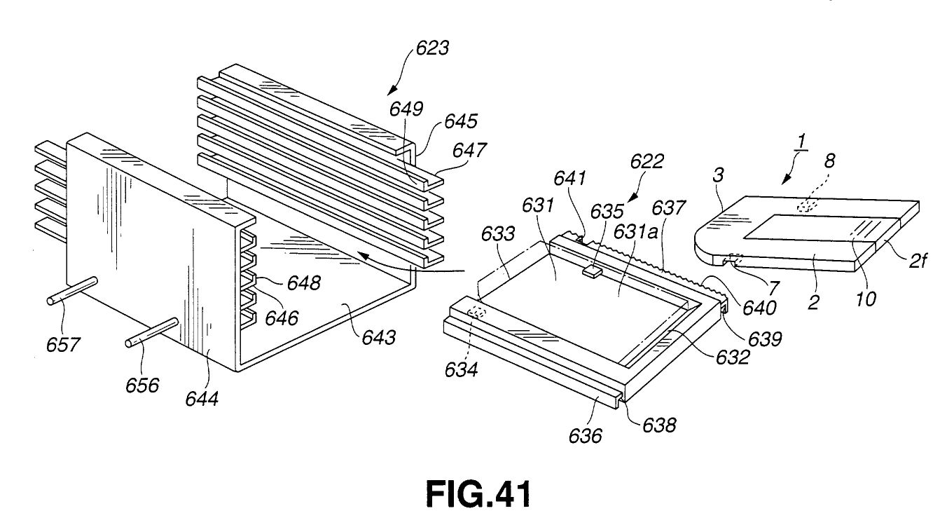

The holding members 622 contained in the receptacle 623 and located one above another are substantially rectangular as is illustrated in FIG. 41. Each holding member 622 has a card holding section 631 on one major surface. The card holding section 631 has a recess large enough to hold an IC card 1. The card holding section 631 has an inclined surface 632 at one end from which an IC card 1 may be inserted into the IC card holding member 622. The inclined surface 632 functions as an IC card 1 guide. The card holding section 631 has an opening 633, through which the terminal section 3 of the IC card 1 held in the member 622 is exposed to the outside. The card holding section 631 has a positioning projection 34 on the bottom 631a. The projection 34 may fit into the positioning recess 7 made in the housing 2 of the IC card 1. The card holding section 631 has an engagement strip 634, which may be fitted into the engagement recess 8 made in the IC card 1. An IC card 1 is inserted into the card holding section 631, with the top 2e turned upward so that the label 10 on the IC card 1 may be seen from the inclined surface 632. The card holding section 631 holds the IC card 1 reliably at a prescribed position when the positioning projection 634 and the engagement strip 635 fit into the positioning recess 7 and the engagement recess 8, respectively. The IC card 1 thus held in the card holding section 631 has its terminal section 3 protruding from the opening 633 and lying outside the card holding section 631. The IC card 1 may be connected to the recording/reproducing section 624. If the user inserts the IC card 1 in a wrong position, for example, with the bottom 2b turned upward, the IC card 1 cannot enter the card holding section 631 by the positioning projection 634 and engaging strip 635. In this case, the user understands that he or she is inserting the IC card 1 in the wrong position.

Two guide rails 636 and 637 are laid on the sides of the holding member 622, which extend in the direction the holding member 622 can move. The guide rails 636 and 637 have grooves 638 and 639, respectively. One of the guide rails, i.e., the rail 636, has a rack gear 640 that engages with an ejection mechanism that moves the holding member 622 to bring the IC card 1 to the card-exchanging position outside the main body 621. The rail 636 has an engagement notch 641 in the end that opposes the recording/reproducing section 624. The notch 641 serves to hold a loading mechanism that can move the holding member 622 to and from the recording/reproducing section 624.

As shown in FIG. 41, five holding members 622, each configured as described above, are provided in the receptacle 623 and arranged, one above another and one parallel to another. That is, the five holding members 622 are arranged, one above another and one parallel to another, in the holding section 643 of the receptacle 623. The holding section 643 is opened at its front that faces the insertion/removal port 625 and at its back that faces the recording/reproducing section 624. Hence, the holding members 622 can move between the card-exchanging position outside the main body 621 and the recording/reproducing position within the recording/reproducing section 624.

The receptacle 623 comprises two side walls 644 and 645 that extend parallel to each other and to the direction in which the holding members 622 constituting the holding section 643 can move. Guide members 646 are arranged on the side wall 644, at intervals almost equal to the thickness of the holding members 622. Similarly, guide members 647 are arranged on the side wall 645, at intervals almost equal to the thickness of the holding members 622. The guide members 646 and 647 are provided to support the holding members 622, allowing the holding members 622 to move. The guide members 646 have a guide strip 648 each, and the guide members 647 have a guide strip 649 each. The guide strips 648 may fit in the grooves 638 of the guide rails 636. The guide strips 649 may fit in the grooves 639 of the guide rails 637. The receptacle 623 can hold the holding members 622, with the guide strips 648 fitted in the grooves 638 and the guide strips 649 fitted in the grooves 639. First and second support pins 656 and 657 are provided on the side walls 644 and 645. The support pins 656 and 657 fasten the receptacle 623 to a lift mechanism for moving the receptacle 623 up and down. Once connected to the lift mechanism by the support pins 656 and 657 to the, the receptacle 623 can be moved up and down.

As indicated above, the recording/reproducing section 624 is designed to write and read data signals into and from the IC cards 1 held in the receptacle 623. This section 624 will be described below.

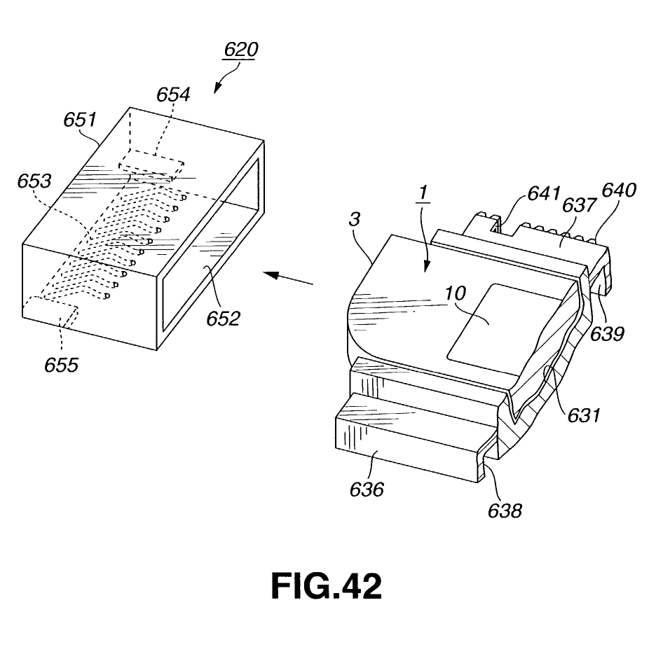

The recording/reproducing section 624 is such a connector 651 as is shown in FIG. 42. The connector 651 is held at a predetermined level and can be connected to the terminal section 3 of an IC card 1. The connector 651 is substantially rectangular and has an insertion port 652 in the front. The terminal section 3 of the IC card 1 can be inserted into the connector 651 through the insertion port 652. Elastic contacts 653 are laid on the inner bottom of the connector 651. The contacts 653 can be electrically connected to the connection terminals 3b that constitute the terminal section 3 of the IC card 1. The contacts 653 are provided in the same number as the connection terminals 3b composing the terminal section 3 of the IC card 1. Each elastic contact 653 is a strip bent in the form of letter L. The bent part of the contact 653 projects upwards and elastically deforms when pushed by a connection terminal 3b of the IC card 1. When the IC card 1 is inserted into the connector 651 through the insertion port 652, the elastic contacts 653 fit into the engagement recesses 3c of the IC card 1, moving from the open ends of the engagement recesses 3c. The contacts 653 are electrically connected to the connection terminals 3b when their bent pats are pressed onto the connection terminals 3b.

The connector 651 has a guide strip 654 on one inner side and an engagement strip 655 on the inner side opposing the first-mentioned inner side. The guide strip 654 can be fitted into the guide groove 13 of an IC card 1. The engagement strip 655 can fitted into the groove 5 of the IC card 1, to prevent erroneous insertion of the IC card 1. The distal end of the IC card 1 held in a holding member 622 is inserted into the connector 651 when the loading mechanism moves the IC card 1 to the recording/reproducing position. This is because the distal end of the card 1 is exposed outside through the opening 633 of the holding member 622. When the terminal section 3 is completely inserted into the connector 651, the elastic contacts 653 are connected to the terminal section 3. Data signals can then be recorded and reproduced in and from the IC card 1. As the IC card 1 held in the holding member 622 is inserted, the guide strip 654 fits into the guide groove 13 of an IC card 1, while the engagement strip 655 fits into the groove 5 of the IC card 1. The terminal section 3 is reliably positioned in the connector 651. Data signals can therefore be recorded and reproduced in and from the IC card 1.

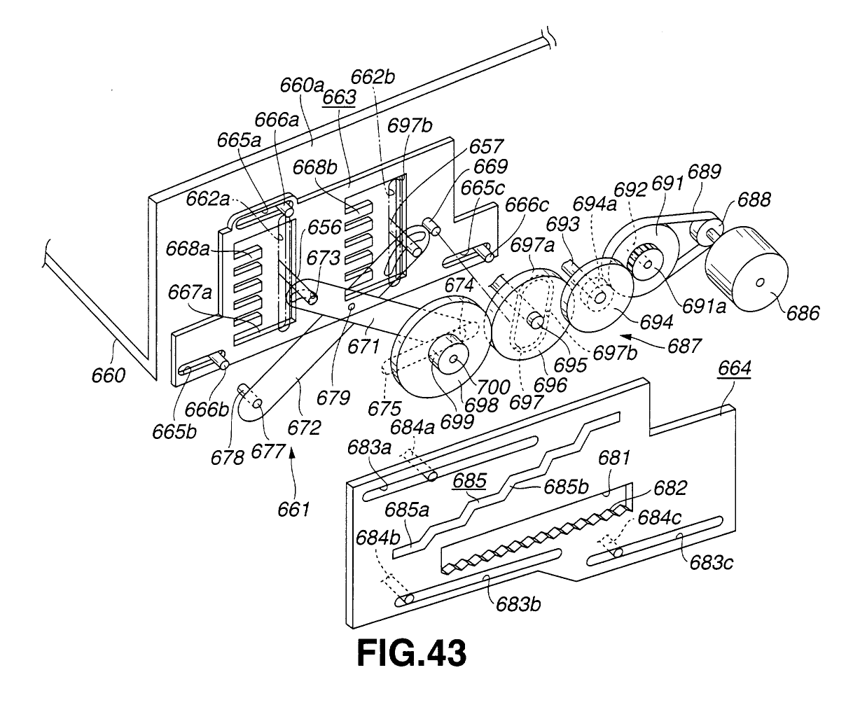

The lift mechanism 661 that supports the receptacle 623 and moves the same up and down will be described, with reference to FIG. 43. A chassis 660 constitutes the main body 621. The chassis 660 comprises side wall 660a and 660b that are parallel to the direction in which the holding members 622 are moved. The support pins 656 and 657 project from the lower parts of the side walls 644 and 645. The first support pin 656 and the second support pint 657 pass through guide holes 662a and 662b made in the side wall 660a and 660b. The guide holes 662a and 662b are elongated, extending in the height direction of the side walls 660a and 660b. That is, they extend substantially at right angles to the direction in which the holding members 622 are stacked. The chassis 660 can therefore be moved tip and down, guided by the guide holes 662a and 662b. The lift mechanism 661 comprises a pair of movable plates 663 and a pair of drive plates 664. The movable plates 663 lie on the outer surfaces of the side walls 660a and 660b, respectively, and can move in the direction in which the holding members 622 are moved. The plates 663 support he receptacle 623. The drive plates 664 can move in the same direction the movable plates 663 move, thereby to move the receptacle 623 up and down.

Each movable plate 663 has elongated guide holes 665a, 665b and 665c. The guide holes is made in the upper-center part of the movable plate 663. The guide holes 665b and 665c are cut in the lower-left and lower-right part of the plate 663. Support pins 666a, 666b and 666c protrude from the outer surface of each side wall (660a, 660b) and are inserted in the guide holes 665a, 665b and 665c of one drive plate 663. The plate 663 can be moved for a distance equal to the length of the guide holes 665a, 665b and 665c. Each movable plate 663 has rectangular openings 667a and 667b that are spaced apart in the direction the plate 663 is moved. A plurality of support strips 668a protrude into the opening 667a from the front edge thereof. Similarly, a plurality of support strips 668b protrude into the opening 667b from the front edge thereof. The movable plates 663 can be moved between a support position and a non-support position. In the support position, the support strips 668a and 668b support the first support pin 656 and the second support pin 657. In the non-support position, the support strips 668a and 668b do not support the first support pin 656 and the second support pin 657. An engagement pin 669 protrudes from each movable plate 663, near the opening 667b. This pin 669 is set in the cam groove 697 cut in a can gear 696, which will be described later in detail. As the cam gear 696 is rotated, the drive plate 664 is moved in the direction the holding members 622 are moved.

Two rotating arms 671 and 672 are provided on the outer surface of each movable plate 662. The arms 671 and 672 cross each other at their center palls. The first rotating arm 671 has an arcuate guide hole 673 in its one end. The first support pin 656 that extends through the opening 667a passes through the guide bole 673. A guide shaft 674 protrudes from the other end of the first rotating arm 671 and is set in the guide hole 675 made in the lower part of the side wall 660a of the chassis 660. The second rotating arm 672 has an arcuate guide hole 676 in its one end. The second support pin 657 that extends through the opening 667b passes through the guide hole 676. The second rotating arm 672 has an axle hole 677 in the lower end. An axle 678 that protrudes from the lower part of the side wall 660a of the chassis 660 passes through the axle hole 677. The first rotating arm 671 and the second rotating arm 672 are coupled at their middle parts by an axle 679 and can rotate around the axle 679. The rotating arms 671 and 672 move the receptacle 623 up and down as the drive plate 664 pushes the second support pin 657 up and down.

The drive plate 664 has a rectangular opening 681 in its center part. A rack 682 is provided on the lower edge of the opening 681. A drive gear 698, which will be described later, meshes the rack 682. The rack 682 serves to move the drive plate 664 in the same direction as the holding members 622. The drive plate 664 has elongated guide holes 683a, 683b and 683c. The guide hole 683a is cut in the upper part of the drive plate 664. The guide holes 683b and 683c are made in the lower part of the dive plate 664. Set in the holes 683a, 683b and 683c are guide pins 684a, 684b and 684c. Therefore, the drive plate 6664 can move for a distance equal to the length of the guide holes 683a, 683b and 683c.

The drive plate 664 has a cam groove 685 in the inner surface. The cam groove 685 serves to move the receptacle 623 up and down. The cam groove 685 consists of horizontal parts 685a and inclined parts 685b. The horizontal parts 685a and inclined parts 685b are alternately arranged, forming a stepwise groove. The cam groove 685 is inclined upwards from the front of the main body 621 toward the back thereof. The second support pin 657 fits in the cam groove 685. As the drive plate 664 moves from the back of the main body 621 toward the front thereof, the pin 657 moves up, step by step, whereby the receptacle 623 is moved upwards.

The movable plate 663 and the drive plate 663, which constitute the lift mechanism 661, receive the drive force from a transmission mechanism 687. The mechanism 687 comprises a drive motor 686 that functions as drive source. A pulley 688 is mounted on the shaft of the drive motor 686. An endless belt 689 is wrapped around the pulley 688 and a driven pulley 688. The belt 698 transmits the drive force of the motor 686 to the driven pulley 691. The driven pulley 691 is mounted on a shaft 692 that projects from the side wall 660a of the chassis 660. The driven pulley 691 has a gear 691a that has a smaller diameter than the pulley 691. The gear 691a meshes a transmission gear 694 that is mounted on the shaft 693 that extends through both side walls 660a and 660b of the chassis 660. The transmission gear 694 has an integral, small-diameter gear 694a. The gear 694a is set in mesh with the cam gear 696 mounted on one end of a shaft 695 that extends through both side walls 660a and 660b of the chassis 660. Another cam gear 696 is mounted on the other end of the shaft 695. The cam gears 696 mounted on the ends of the shaft 695 rotate in the same direction when the motor 686 is driven.

The engagement pin 669 protruding from each movable plate 663 fits in the cam groove 697 of the cam gear 696. The cam groove 697 is elliptical, consisting of two short arcuate parts 697a and two long arcuate parts 697b. While the elliptical groove 697 remains extending horizontally, with the engagement pin 669 fitted in one short arcuate part 697a, the cam gear 696 holds the movable plate 663 at a position where the plate 663 supports neither the first support pin 656 nor the second support pin 657. While the elliptical groove 697 remains extending vertically, with the engagement pin 669 fitted in one long arcuate part 697b, the cam gear 696 holds the movable plate 663 at another position where the plate 663 supports both the first support pin 656 and the second support pin 657. The movable plate 663 moves back and forth twice while the cam gear 696 rotates once.

Shafts 100 protrude from the side walls 660a and 660b, respectively. A drive gear 698 is mounted on each of the shafts 100. A small-diameter gear 699 is formed integral and coaxial with the drive gear 698. The gear 699 meshes the rack 682 provided on the lower edge of the opening 681 made in the drive plate 664. The gear 698 is rotated when it receives the force of the drive motor 686. When so rotated, the gear 698 moves the drive plate 664 in the same direction as the holding members 622. The receptacle 623 is thereby moved up and down.

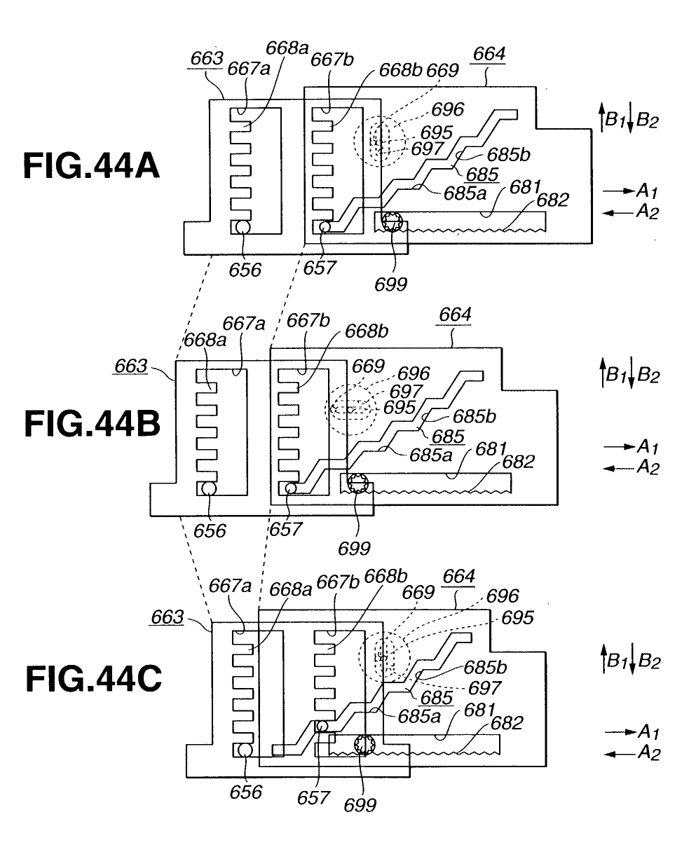

It will be described how the lift mechanism 661 described above operates to lift the receptacle 623 from the lowermost stage to the uppermost stage. When the receptacle 623 lies at the lowermost stage and is most stable as is illustrated in FIG. 44A, the movable plate 663 assumes such a position that the cam groove 697 of the cam gear 696 extends vertically and the engagement pin 669 fitted in one straight part 697b. That is, the movable plate 663 has been moved toward the back of the main body 621 in the direction of arrow A₁ shown in FIG. 44A. The plate 663 supports the first support pin 656 and the second support pin 657. The drive plate 664 has been moved in the direction of arrow A₁, too. Thus, the second support pin 657 is fitted in the lowest horizontal part 685a of the cam groove 685 made in the drive plate 664.

When the motor 686 is driven in the forward direction as shown in FIG. 44B, the cam gear 696 rotates, whereby the cam groove 697 assumes the horizontal position. Since the engagement pin 669 is set in one short arcuate part 697a, the movable plate 663 moves in the direction of arrow A₁ shown in FIG. 44B and reaches the non-support position. The support strips 668a and 668b no longer support the first support pin 656 or the second support pin 657. The support pins 656 and 657 can now move up and down, or in the direction of arrow B₁ and the direction of arrow B₂. At the same time, the drive gear 698 is rotated in one direction, moving the drive plate 664 in the direction of arrow A₂ as is illustrated in FIG. 44B. The rotating arms 671 and 672, which are supported by the support pins 656 and 657, respectively, move the receptacle 623 upwards. That is, the receptacle 623 is moved up or down when the movable plate 663 moves to the non-support position and the drive plate 664 moves to fit the second support pin 657 in the inclined part 685b of the cam groove 685.

As the drive motor 686 is further driven in one direction, the cam gear 696 rotates, assuming the vertical position again, as shown in FIG. 44C. Therefore, the movable plate 663 moves in the direction of arrow A₁ (FIG. 44C), back to the support position. The second support pin 657 moves to the second lowest horizontal part 685a of the cam groove 685. The receptacle 623 is moved up for a predetermined distance. The second support strip 668a supports the first support pin 656, and the second support strip 668b supports the second support pin 657. Thus, the drive plate 664 of the lift mechanism 661 moves up the receptacle 623 when the movable plate 663 lies in the non-support position, not supporting the first support pin 656 or the second support pin 657. The movable plate 663 is then moved back to the support position, thereby to hold the receptacle 623 at a predetermined level.

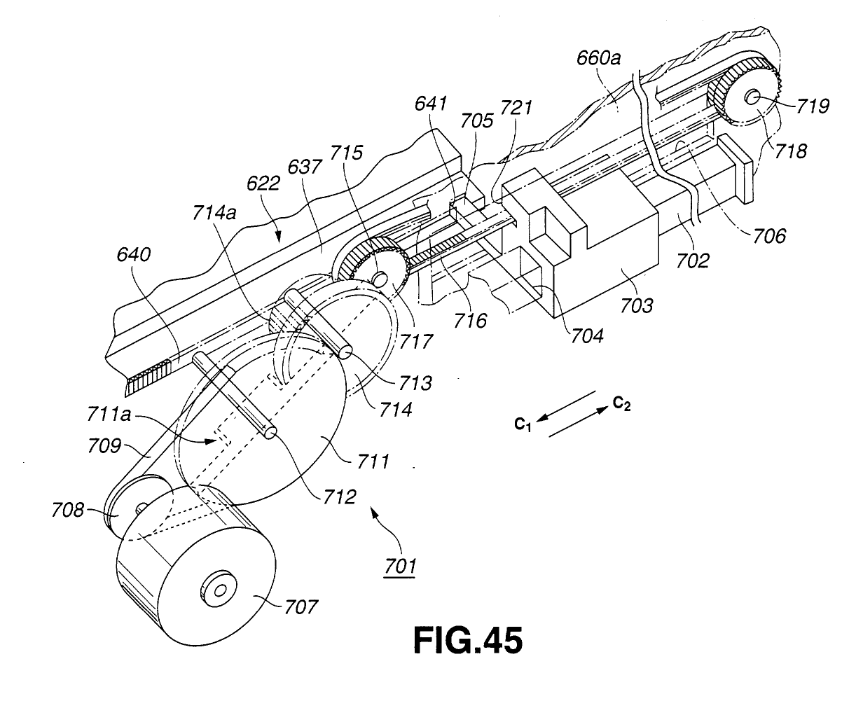

The loading mechanism 701 will be described with reference to FIG. 45. The mechanism 701 is configured to select one holding member 622 from among many contained in the receptacle 623 and to load the holding member 622 into the recording/reproducing section 624. The loading mechanism 701 has a guide shaft 702 and a movable block 703. The guide shaft 702 is held by the side wall 660a of the chassis 660 and can move in parallel in the direction the holding members 622 are moved. The movable block 703 is mounted on the guide shaft 702. The guide shaft 702 has a rectangular cross section. The shaft 702 is supported at one end by a support frame (not shown) that projects from the center part of the side wall 660a. The movable block 703 has a guide hole 704, through which the guide shaft 702 extends. Supported and guided by the guide shaft 702, the block 703 can move in the same direction as the holding members 622 contained in the receptacle 623 are moved. An engagement projection 705 extends from one side of the movable block 703 toward the side wall 660a. The projection 705 is fitted in the engagement notch 641 made in the guide rail 637. The engagement projection 705 protrudes into the chassis 660 through a slit 706 made in the side wall 660a and extending along he guide shaft 702. The engagement projection 705 fits into the engagement notch 641 cut in the holding member 622. When the movable block 703 stays at the front end of the guide shaft 702, or the left end thereof (FIG. 45), the engagement projection 705 moves into the receptacle 623 until it fits into the engagement notch 641 of any one of the holding members 622 stacked in the receptacle 623. In the receptacle 623 the holding members 622 are so positioned that their notches 641 are vertically aligned. Hence, the lift mechanism 661 can move the receptacle 623 up and down even if the engagement projection 705 is set in the engagement notch 641 of a holding member 622.

A loading motor 707 is mounted on the base (not shown) that is formed integral with the side wall 660a. The motor 707 moves the movable block 703 in the direction of arrow C₁ or arrow C₂, in parallel to the direction the holding members 622 are moved. A drive pulley 708 is mounted on the shaft of the loading motor 707. An endless belt 709 is wrapped around the drive pulley 708 and a driven pulley 711. The endless belt 709 transmits the drive force of the loading motor 707 to the driven pulley 711. The driven pulley 711 is mounted on an axle 712 that protrudes from the side wall 660a. The driven pulley 711 has gear 711a. The gear 711a meshes a transmission gear 714 mounted on an axle 713 that protrudes from the side wall 660a. The transmission gear 714 has a small-diameter gear 714a that meshes a first timing gear 717. The first timing gear 717 is mounted on an axle 715 that protrudes from the side wall 660a. The first timing gear 717 is located near the front end of the slit 706. A second timing gear 718 is provided near the rear end of the slit 706 and mounted on an axle 719 that protrudes from the side wall 660a. A timing belt 716 is wrapped around the first timing gear 717 and the second timing gear 718. A part of the timing belt 716 is fastened to the movable block 703, fitted in an engagement groove 721 that is cut in one side of the movable block 703. The movable block 703 is moved in the direction of arrow C₁ or arrow C₂ when the loading motor 707 drives the timing belt 716.

The movable block 703 may be moved along the guide shaft 702, in the direction of arrow C₂ (FIG. 45), with The engagement projection 705 fitted in the engagement notch 641 of one holding member 622 held in the receptacle 623. In this case, the holding member 622 is pulled from the receptacle 623 and moved in the direction of arrow C₂ (FIG. 45). Thus, one of the holding members 622 in the receptacle 623 is selected and drawn from the receptacle 623 after the movable block 703 has been moved to the receptacle 623 in the direction of arrow C₁ shown in FIG. 45.

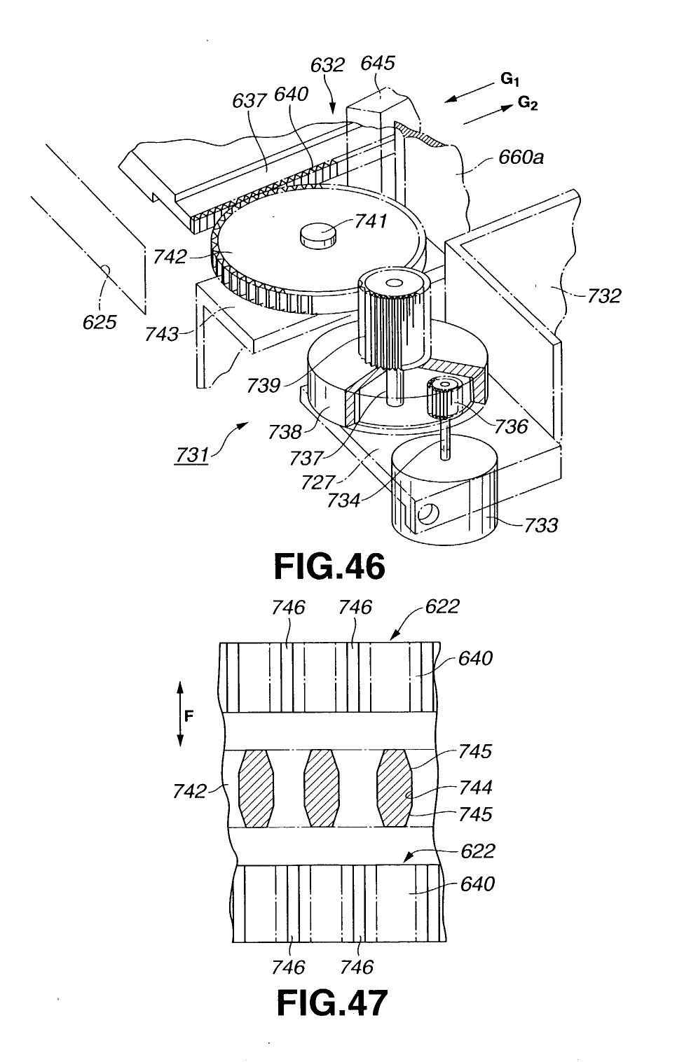

The ejecting mechanism 731 configured to eject a holding member 731 from the insertion/removal port 625 of the receptacle 623 will be described, with reference to FIG. 46. As FIG. 46 shows, the ejecting mechanism 731 comprises a base plate 732 and a drive motor 733. As shown in FIG. 46, the drive motor 733 is attached to the horizontal pat 727, or bent part, of the base plate 732, with its shaft 734 extending upwards. A drive gear 736 is mounted on the shaft 734 of the drive motor 733 and meshes a hollow cylinder gear 738. The cylinder gear 738 is mounted on a shaft 737 and has tooth in the inner circumferential surface. The shaft 737 protrudes upwards from the horizontal part 727 of the base plate 732. A transmission gear 739 is formed integral with the hollow cylinder gear 738. The transmission gear 729 is set in mesh with a drive gear 742 mounted on an axle 741 that protrudes from the side wall 660a of the chassis 660. The axle 741 stands on the horizontal plate 743, which has been provided by bending the front part of the side wall 660a. As shown in FIG. 46, the drive gear 742 meshes the front part of the rack 640 provided on the holding member 622 that has been selected to be drawn from the main body 621. Which holding member 622 in the receptacle 623 the drive gear 742 should mesh depends upon the level at which the receptacle 623 is located. The drive gear 742 is exposed into the receptacle 623 through the opening made in the side wall 645 of the receptacle 623.

When the lift mechanism 661 moves the receptacle 623 up or down, the holding member 622 at the address selected by the user is moved, with its rack 640 set in mesh with the drive gear 742. As shown in FIG. 47, the drive gear 742 has tooth 744. Each teeth 744 extending at right angles to the each rack 640 provided on the holding member 622 has two tapered parts 745 on either end. The ends of the teeth 744 are narrowing toward the racks 640. Therefore, the teeth 746 of the rack 640 can smoothly enter the gaps between the teeth 744 of the drive gear 742 when the holding members 622 are moved in the direction of arrow F shown in FIG. 47. The receptacle 623 is thereby smoothly moved up and down. The holding member 622 selected by the ejecting mechanism 731 is drawn from the receptacle 623 as the drive motor 733 drives the rack 640. The holding member 622 moves in the direction of arrow G₁ (FIG. 46) and finally projects from the main body 621 through the insertion/removal port 625. The holding member 622 is moved into the receptacle 623 in the direction of arrow G₂ (FIG. 46) when the drive motor 733 drives the rack 640 in the opposite direction.

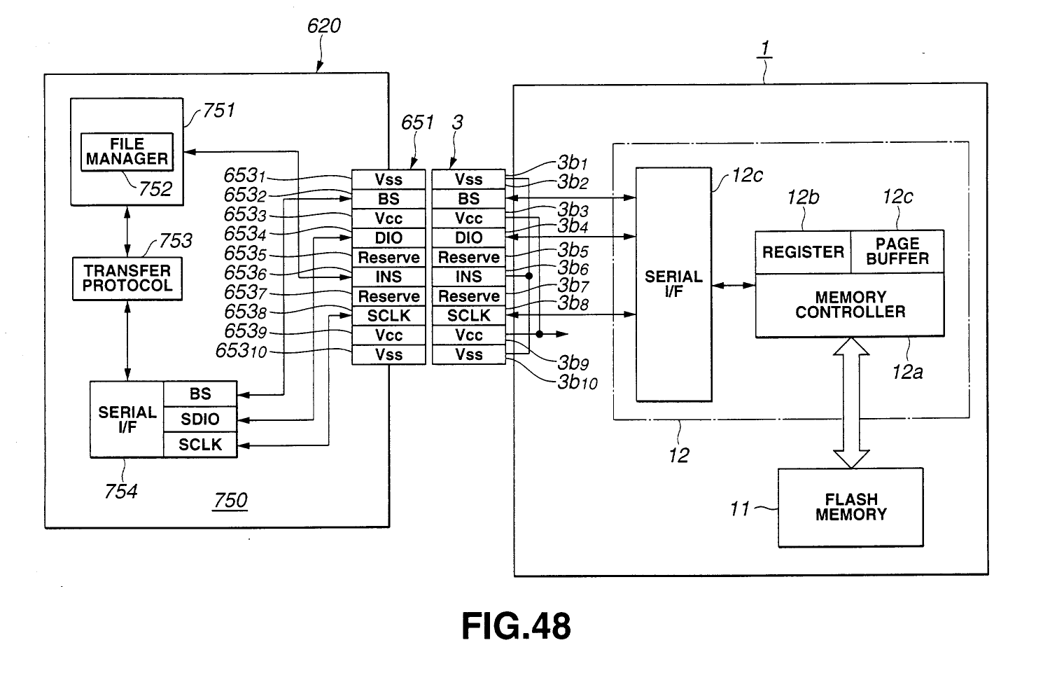

How an IC card 1 is connected to the recording/reproducing apparatus 620 will be described with reference to FIG. 48.

As can be seen from FIG. 48, the circuit configuration of the IC card 1 is similar to the one illustrated in FIG. 3.

The recording/reproducing circuit 750 of the recording/reproducing apparatus 620 comprises a CPU 751, a transfer protocol interface 763, and a serial interface 754. The CPU 751 incorporates a file manager 752 that performs file management in the IC card. The transfer protocol interface 763 makes accesses to the register 12b and the page buffer 12c, both provided in the IC card 1. The serial interface 754 defines a protocol for transferring data through three signals lines, i.e., a serial clock signal SCLK line, a bus state signal BS line and a serial data input/output signal SDIO line.

How the recording/reproducing apparatus 620 holding a plurality of IC cards 1 described above does operate will be explained. First, it will be described how IC cards are exchanged. More specifically, it will be described how the IC card 1 held by the holding member 622 of the address #1, i.e., the holding member located at the uppermost stage.

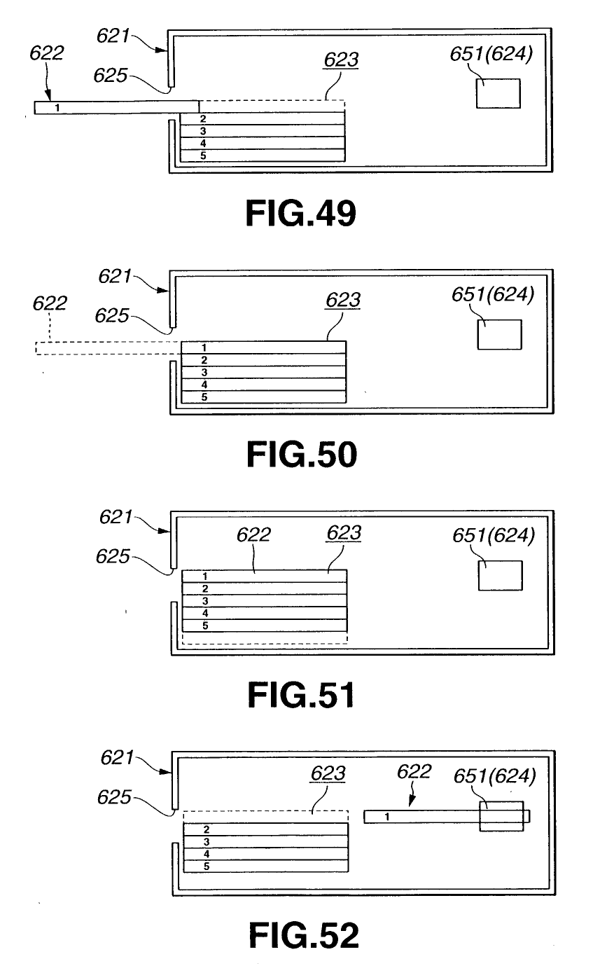

To move the holding member 622 at the address #1, i.e., the uppermost stage, to the card-exchanging position outside the main body 621, the receptacle 623 is moved to the lowest position as is illustrated in FIG. 49. More precisely, the lift mechanism 661 moves the movable plate 663 toward the back of the main body 621, in the direction of arrow A₁ as shown in FIG. 44A. The movable plate 663 reaches a position where it supports the first support pin 656 and second support pin 657 that are provided on the receptacle 623. The first support pin 656 and the second support pin 657 contact the support strips 668a and 668b at the lowermost stage and fit into the notches cut in the lower edges of the openings 667a and 667b. The drive plates 664 are moved, too, in the direction of arrow A₁ as is illustrated in FIG. 44A. The second support pin 657 is fitted in the lowest horizontal part 685a of the cam groove 685 made in the drive plate 664.

At the same time, the drive gear 742 comes into mesh with the rack 640 provided on the holding member 622 held at the address #1, as shown in FIG. 46, in the ejecting mechanism 731. The holding member 622 is moved in the direction of arrow G1 (FIG. 46) as the drive motor 733 is driven. The member 622 moves through the insertion/removal port 625 and finally reaches the card-exchanging position outside the main body 621. At this position, the user removes the IC card from the holding member 622 and inserts another IC card 1 into the holding member 622. After the IC cards are thus exchanged, the drive motor 733 is driven in the reverse direction in the ejecting mechanism 731. The holding member 622 is thereby pulled into the receptacle 623. As shown in FIG. 50, the holding member 622 is moved to the address #1 in the receptacle 623 as is shown in FIG. 50.

It will be described how data signals are recorded and reproduced in and from the IC cards 1 held in the receptacle 623. More correctly, it will be described how to record and reproduce a data signal in and from the IC card 1 held at the address #1. To record a data signal in or reproduce the same from the IC card 1 held at the address #1, the holding member 622 of the address #1 is moved up by one stage as shown in FIG. 51, from the lowest position in the receptacle 623. That is, as FIGS. 44B to 44C show, the drive motor is driven, moving the movable plate 663 of the lift mechanism 661 in the direction of arrow A₂ (FIG. 44B) until the plate 663 reaches the non-support position. The first support pin 656 and the second support pin 657 therefore move to the non-support position and are no longer supported by the support strips 668a and 668b. In the meantime, the drive gear 698 rotates in one direction, moving the drive plate 664 in the direction of arrow A₁ as is illustrated in FIG. 44B. The second support pin 657 therefore moves along the cam groove 685, passes the inclined part 685b and reaches the next horizontal part 685a of the cam groove 685. The first rotating arm 671 and the second rotating arm 672 lifts the receptacle 623 by one stage. The movable plate 663 is moved in the direction of (FIG. 44C), back to the support position. The receptacle 623 now lies at such a position that the holding member 622 stays at the address #1, i.e., the same level as the connector 651 of the recording/reproducing section 624. As FIG. 45 shows, the engagement projection 705 projecting from the movable block 703 of he loading mechanism 701 fits into the engagement notch 641 of the holding member 622 remaining at the address #1.

As illustrated in FIGS. 45 and 52, the holding member 622 at the address #1 causes the loading motor 707 to move the movable block 703 toward the receptacle 623, in the direction of arrow C₂ as is shown in FIG. 45. The movable block 703 therefore arrives at the recording/reproducing position. The terminal section 3 of the IC card 1, which now projects from the opening 633 of the holding member 622, is inserted into the connector 651 through the insertion port 652 thereof. The connection terminals 3b of the IC card 1 are pressed onto, and electrically connected to, the elastic contacts 653 provided in the connector 651.

To be more specific, the CPU 751 detects the voltage on the connection terminal 3b6 of the IC card 1 that is connected to the connector 651. The CPU 751 determines whether this terminal voltage is higher than a threshold value. If the terminal voltage is higher than the threshold value, the CPU 751 determines that the IC card 1 has been reliably connected to the connector 651. If the terminal voltage is lower than the threshold value, the CPU 751 determines that the IC card 1 has not been reliably connected to the connector 651. If the IC card 1 is found reliably connected to the connector 651, the CPU 751 causes the display or the like, provided on the main body 621, to display a message informing the user that data signals be recorded and reproduced in and from the IC card 1. The CPU 751 then reads the data signals from the IC card 1 and records the data into the flash memory 11 incorporated in the IC card 1.

To move the IC card 1 connected to the connector 651, back to the prescribed address in the receptacle 623, the loading motor 707 of the loading mechanism 701 is driven in the reverse direction. The movable block 703 is thereby moved away from the receptacle 623, in the direction of arrow C₁ shown in FIG. 45. The holding member 622 therefore moves from the address #1 to a specific position in the receptacle 623.

In the recording/reproducing apparatus 620 described above, a plurality of IC cards 1 can be held at a time. It is not necessary to replace an IC card with another as in the conventional recording/reproducing apparatus. The apparatus 620 is therefore user-friendly. Further, the apparatus 620 has high operability because IC cards 1 can be automatically inserted and removed into and from the connector 651.

It has been described how the recording/reproducing apparatus 620 record and reproduce data signals in and from an IC card 1, while the elastic contacts 653 remain in contact with the connection terminals 3b. In the present invention, data signals can be exchanged between the apparatus 620 and the IC card 1 by radio. The lift mechanism 661 moves the receptacle 623 up and down to the level at which the connector 651 lies. Instead, the receptacle 623 may be fixed at a specific position, and the lift mechanism 661 may move the connector 651 in vertical direction. As indicated above, five holding members 662 are held in the receptacle 623, one above another. The number of holding members provided is not limited to five, provided that at least two holding members are provided in the receptacle 623.

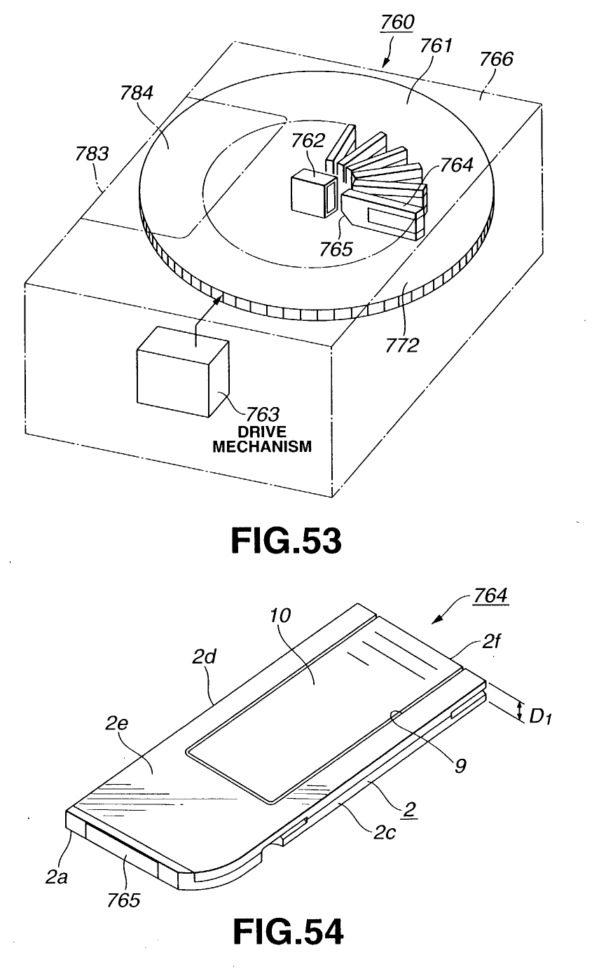

Another recording/reproducing apparatus 760 according to this invention will be described with reference to some drawings. The recording/reproducing apparatus 760 has a turntable on which about 100 IC cards can be held. The apparatus 760 differs, in this respect, from the recording/reproducing apparatuses described above, which holds only a few IC cards. The recording/reproducing apparatus 760 is characterized in that it records and reproduces data in and from IC cards by radio. As shown in FIG. 53, the apparatus 760 comprises a storage unit 761, a recording/reproducing section 762, and a rotary drive mechanism 763. The storage unit 761 can hold about 100 IC cards 764, each standing on one long side. The recording/reproducing section 762 can record and reproduce data in and from any IC card 764 held on the storage unit 761. The rotary drive mechanism 763 is configured to rotate the storage unit 761 so that a selected one of the IC cards 764 held on the storage unit 761 may have its data-receiving/transmitting section oppose the recording/reproducing section 762.

As can been understood from FIG. 54, each IC card 764 that may be used in the apparatus 760 is almost identical in structure to the IC card 1 shown in FIGS. 1 and 2. The components identical to those of the IC card 1 are designated at the same reference numerals and will not be described in detail. This IC card 764 has a data-receiving/transmitting section 765 at the front 2a of the housing 2. The section 765 is an antenna or the like and can transmit and receive data, by radio, to and from the recording/reproducing apparatus 760. As illustrated in FIG. 53, the IC card 764 is held on the storage unit 761, with the section 765 opposing the recording/reproducing section 762 of the apparatus 760. While the IC card 764 remains at the recording/reproducing position, the data-receiving/transmitting section 765 can receive and transmit data from and to the IC card 764.

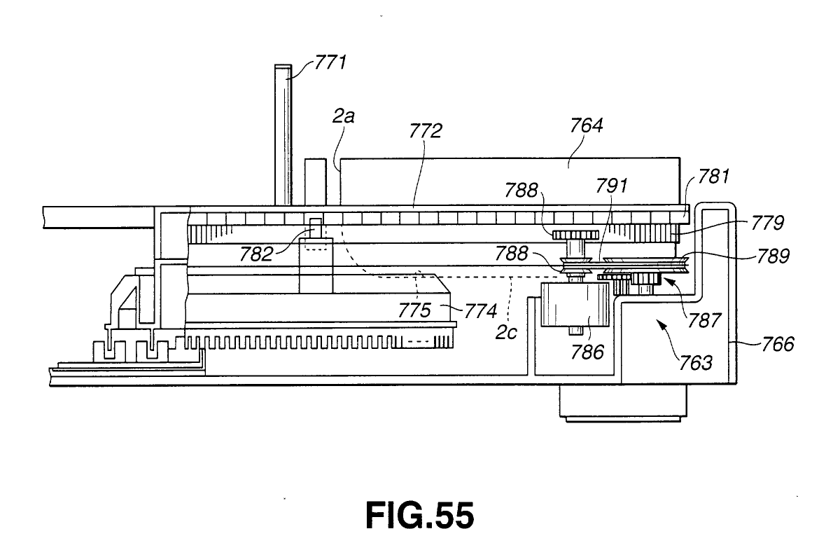

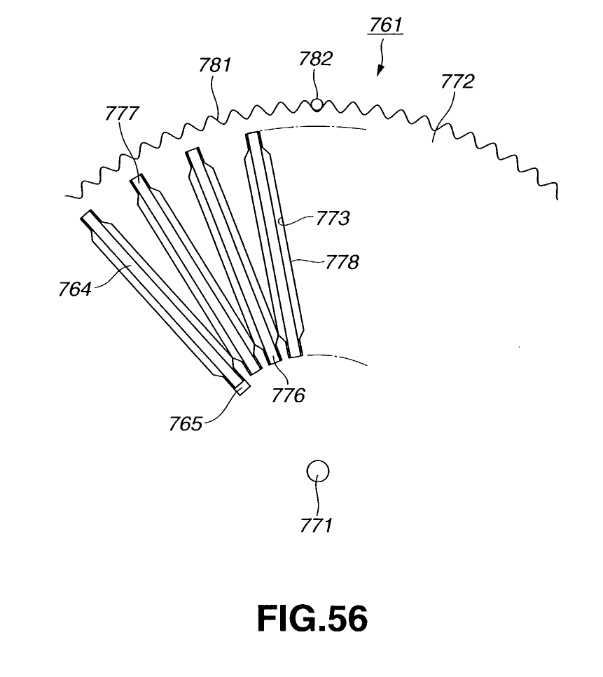

The storage unit 761 is provided within the housing 766, i.e., the main body of the recording/reproducing apparatus 760. As shown in FIGS. 55 and 56, the storage unit 761 comprises a rotary table 772, which is a disc that can rotate around an axle 771 projecting upwards from the bottom of the housing 766. The rotary table 772 is the main body of the storage unit 761. Supported by the axle 771 extending vertically, the rotary table 772 can rotate in the horizontal plane that is parallel to the bottom of the housing 766. In other words, the table 772 can rotate in the horizontal plane located at the same level as the recording/reproducing apparatus 760.

A number of card-holding grooves 773 are cut in one surface of the rotary table 772. The grooves 773 are arranged in a circle around the axle 771 and extend in the radial direction of the table 772, each for holding an IC card 764.

More precisely, the table 772 has 100 card-holding grooves 773. A hollow cylindrical card support 774 is provided on the lower surface of the rotary table 772. The card support 774 is formed with the rotary table 772 and positioned coaxial therewith. The card support 774 has card-supporting grooves 775. The grooves 775 oppose the card-holding grooves 773 made in the rotary table 772, respectively. Each groove 775 supports the front 2a of the IC card 764 held in the associated card-holding groove 773. The card-supporting grooves 775 are made in the upper surface of the card support 774, which faces the rotary support 772.

The grooves 775 extend in the radial direction of the card support 774. Thus, an IC card 764 may has its front 2a supported in one card-supporting groove 77 and its side 2c held in the card-holding groove 773 associated with the card-supporting groove 775. The IC card 764 is therefore prevented from slipping out of the card-holding groove 773. Each card-holding groove 773 and the card-supporting groove 775 associated with the groove 773 define a card holding section.

The card-holding groove 773 made in the rotary table 772 has an outer end part 176 and an inner end part 777. The inner end part 776 is located near the center of the rotary table 772, and the outer end part 777 near the circumference of the table 772. Both end parts 776 and 777 have a width that is almost equal to the thickness D1 of the IC card 764. The middle part 778 of the groove 773, which extends between the end parts 776 and 777, has a width that gradually increases from the center of the table 772 toward the circumference thereof, as is illustrated in FIG. 56. An IC card 764 is inserted into the hard-holding groove 773, with its data-receiving/transmitting section 765 fitted in the inner end part 776 of the groove 773. Once inserted into the card-holding groove 773, the IC card 764 has its end portions fitted in the end parts 776 and 777 of the groove 773 and is therefore firmly held in the groove 773. Thus, the IC card 764 vertically, with its one side fitted in the card-holding groove 773. That is, the IC card 764 is held in the storage unit 761, with its major surfaces extending parallel to the axle 771 which supports the rotary table 772 and which is coaxial therewith. Since the IC card 764 held in the card-holding groove 773 is reliably prevented from moving,the data-receiving/transmitting section 765 remains opposing the recording/reproducing section 762 of the apparatus 760. Data can therefore be reliably transferred between the section 762 and the IC card 764.

The rotary table 772 of the storage unit 761 has gear teeth 779 on its outer circumferential surface. The teeth 779 mesh the transmission gear of a drive mechanism. When the drive mechanism is actuated, the rotary table 772 is rotated abound the axle 771. A groove 781 is cut in the outer circumferential surface of the rotary table 772, between two adjacent teeth 779. The groove 781 is provided for the card-holding grooves 773. As shown in FIG. 56, a rotation-controlling pin 782 fits into the groove 781, inhibiting the rotary table 772 from rotating while data is being recorded in or reproduced from any IC card 764.

The housing 766 contains the storage unit 761 and the recording/reproducing section 762. The storage unit 761 stores and holds the IC cards 764. The recording/reading section 762 is designed to record and reproduce data in and from an IC card selected from those stored in the storage unit 761. As shown in FIG. 53, the storage unit 761 has an insertion/removal port 783, through which IC cards 764 can be inserted into and removed from the storage unit 761. The port 783 is made in the upper surface of the housing 766 and extends in the depth direction of the housing 766. The insertion/removal port 783 is large enough to expose some of the card-holding grooves 773 that are cut in the rotary table 772. To be more specific, the port 783 exposes about a quarter the number of grooves 773 made in the table 772. The IC cards 764 can be removed from the storage unit 761 through the port 783, and other IC cards can be inserted into the unit 761 and then fitted into the card-holding grooves 773. The insertion/removal port 783 is covered with a cover 784 made of transparent synthetic resin covers, while data is being recorded in or reproduced from any IC card 764 or while the recording/reproducing apparatus 760 is not used at all. Hence, nothing would enter the storage unit 761 to contact the IC cards 764 stored in the unit 761. Nor would dust enter the housing 766. The IC cards 764 stored in the storage unit 761 can thus be protected.

As described above, the rotary drive mechanism 763 is configured to rotate the storage unit 761. When the mechanism 763 rotates the storage unit 761, the IC card 764 selected is moved to the recording/reproducing position. Note that this IC card 764 has been selected by operating some of the various keys provided on, for example, a control panel, and is now held in one card-holding section comprising a card-holding groove 773 and a card-supporting groove 775. As shown in FIG. 55, the rotary drive mechanism 763 comprises a drive motor 786 and a reduction gear mechanism 787. The drive motor 786 is provided in a corner of the housing 766. The reduction gear mechanism 787 is a combination of gears. The drive gear 788 of the mechanism 787 meshes the gear teeth 788 that are provided on the outer circumferential surface of the rotary table 722, transmitting the drive force of the motor 786 to the rotary table 722. The drive force of the motor 786 is transmitted to the reduction gear mechanism 787, too, by a transmission belt 791 that is wrapped around pulleys 788 and 789. The pulley 788 is mounted on the output shaft 786a of the drive motor 786. The pulley 789 is a component of the reduction gear mechanism 787. Hence, the reduction gear mechanism 787 reduces the rotation speed of the shaft of the motor 786, and the drive gear 788 transmits the drive force of the motor 786 to the gear teeth 779 The rotary table 772 is thereby rotated. The drive motor 786 can be driven in both the forward direction and the reverse direction. It rotates the storage unit 761 including the rotary table 772, around the axle 771 in the clockwise direction or the counterclockwise direction in accordance with the position of the IC card 764 selected by operating some of the keys that are provided on the control panel.

As FIG. 55 illustrates, the recording/reading section 762 is secured near the axle 771. The recording/reading section 762 can receive and transmit data from and to a n IC card 764, because it opposes the data-receiving/transmitting section 765 of the IC card 764 at the address that the user has selected.

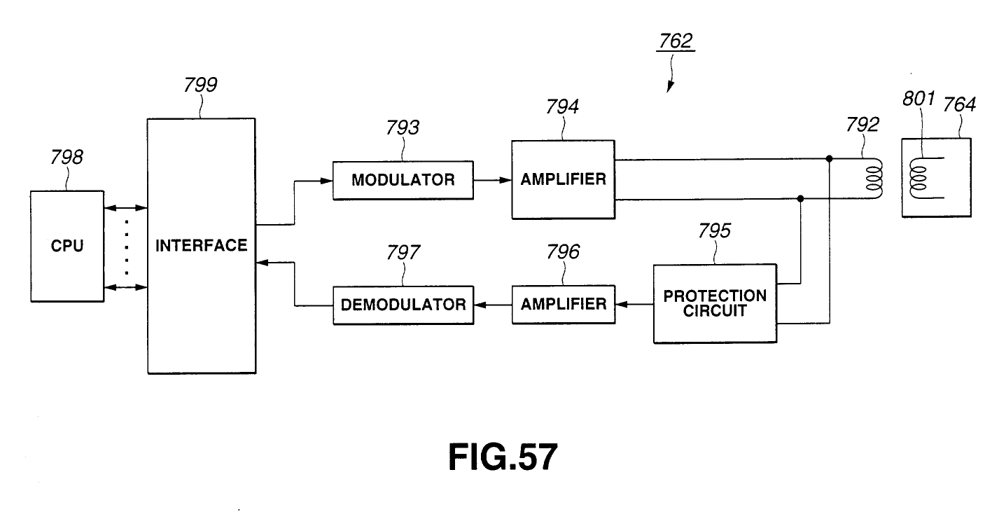

The recording/reading section 762 of the recording/reproducing apparatus 760 will be described in terms of circuit configuration. As FIG. 57 shows, the recording/reading section 762 comprises an antenna 792, a modulator 793, an amplifier 794, a protection circuit 795, an amplifier 796, a demodulator 797, and a CPU 798. The antenna 792 is provided in the form of a coil. The modulator 793 modulates data. The amplifier 794 amplifies the data signal modulated by the modulator 793 in order to drive the antenna 792. The protection circuit 795 is provided to protect the other circuit components. The amplifier 796 amplifies a signal received from an IC card 764. The demodulator 797 demodulates the signal received from the IC card 764 to reproduce the data recorded in the IC card 764. The CPU 798 controls the other components of the recording/reading section 762.

To record a data signal in an IC card 764, the CPU 798 supplies the data signal to the modulator 798 through an interface circuit 799. The modulator 793 modulates the carrier with the data signal in a prescribed modulation scheme, generating a modulated signal. The modulated signal is supplied to the amplifier 794. The amplifier 794 amplifies the modulated signal, thus driving the antenna 792 or supplying a current to the antenna 792. The antenna 792 transmits radio waves based on the data signal to be recorded in the IC card 764, to the antenna 801 that is provided on the IC card 764.

To read the data signal recorded in the IC card 764, into the apparatus 760, the antenna 792 supplies the data signal to the amplifier 796 through the protection circuit 795. The amplifier 796 amplifies the data signal. The demodulator 797 demodulates the data signal amplified by the amplifier 796, reproducing the data signal. The data signal is supplied from the amplifier 796 to the CPU 789 via the interface circuit 799.

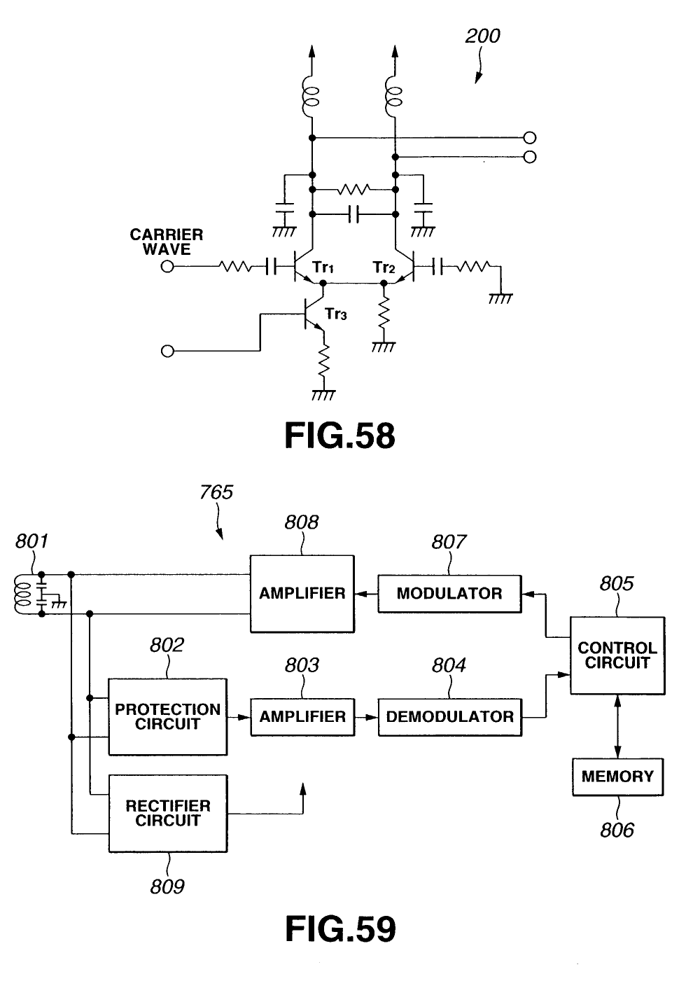

The IC card 764 contains no batteries (i.e., power supplies) so that it may be small and light. The power that drives the circuits built in the IC card 764 is supplied from the recording/reproducing apparatus 760. That is, the recording/reproducing section 762 supplies power to the IC card 764 in static scheme, by superposing power, as well as modulated signals, on the carrier. More precisely, if amplitude modulation is employed as the modulation scheme, the modulator 793 and the amplifier 794 constitute an amplitude-modulation/amplification circuit 800 of the type shown in FIG. 58. The circuit 800 is a differential amplifier that comprises transistors Tr1 and Tr2. One input terminal of the differential amplifier, i.e., the base of the transistor Tr1, receives a carrier. The other input terminal of the differential amplifier, i.e., the base of the transistor Tr2, is connected to the ground by a capacitor and a resistor. A transistor Tr3 is connected between the ground and the node of the emitters of the transistors Tr1 and Tr2. The transistor Tr3 serves to accomplish amplitude modulation. Data is supplied to the base of this transistor Tr3 from the interface circuit 799. In the amplitude-modulation/amplification circuit 800, the transistor Tr3 performs amplitude modulation on a carrier supplied from a carrier oscillator (not shown), with the data supplied from the interface circuit 799. The transistor Tr3 generates an amplitude-modulated signal, which is amplified by the transistors Tr1 and Tr2. The modulation scheme may be PSK modulation or QAM modulation, instead of amplitude modulation, in the present invention.

The circuit configuration of the IC card 764 will be described. As FIG. 59 shows, the IC card 764 comprises an antenna 801, a protection circuit 802, an amplifier 803, a demodulator 804, a control circuit 805, a memory 806, a modulator 807, an amplifier 808, and a rectifier circuit 809. The antenna 801, which is shaped like a coil, receives radio waves transmitted from the recording/reproducing section 762 of the recording/reproducing apparatus 760. The protection circuit 802 is provided to protect the other circuit components. The amplifier 803 amplifies the signal it has received. The demodulator 804 demodulates the signal amplified by the amplifier 803, thus generating a data signal. The control circuit 805 controls the writing and reading of the data signal. The memory 806 is a flash memory or the like that stores the data signal. The modulator 807 modulates a carrier with the data signal read from the memory 806. The amplifier 808 amplifies the signal modulated by the modulator 807, thereby driving the antenna 801. The rectifier circuit 809 converts the signal to a DC voltage.

The antenna 806 receives a data signal. To record the data signal into the memory 806, the antenna 801 supplies the signal to the amplifier 803 through the protection circuit 802. The protection circuit 802 protects the other circuits from, for example, an excessively large current. The amplifier 803 amplifies the signal and supplies it to the demodulator 804. The demodulator 804 detects the signal amplified, i.e., the amplitude-modulated signal received and amplified; it detects the signal by means of, for example, envelope detection, thereby reproducing the data signal. The data signal reproduced is supplied to the control circuit 805. The control circuit 805 performs a control in order to record the data signal in the memory 806. Hence, data signal transmitted from the recording/reproducing apparatus 760 is recorded into the memory 806. The rectifier circuit 809 performs full-wave rectification on the signal it has received, thus smoothing the signal and generating a DC current that is required in the IC card 764. The DC current is supplied to the various circuits incorporated in the IC card 764.

How the recording/reproducing apparatus 760 and the IC cards 764, described above, operate will be described below. First, an IC card 764 is replaced with another, while a card-holding groove 773 remains exposed through the insertion/removal port 783. The IC card 764 is inserted into the storage unit 761 through the poll 783 and fitted into the card-holding groove 773. Held between the inner end part 776 and outer end part 176 of the groove 773, the IC card 764 would not be displaced. When the user selects any desired address, the rotary drive mechanism 763 is driven, rotating the storage unit 761 around the axle 771 to reach the recording/reproducing position. At the recording/reproducing position, the data-receiving/transmitting section 765 of the IC card 764, which the user has designated, opposes the recording/reproducing section 762 of the apparatus 760. Once the data-receiving/transmitting section 765 and the recording/reproducing section 762 faces each other, the rotation-controlling pin 782 fits into the engagement groove 781 of the storage unit 761. The storage unit 761 is thereby prevented from rotating. The recording/reproducing section 762 and the data-receiving/transmitting section 765 therefore remain opposing each other.

In this condition, the recording/reproducing apparatus 760 exchanges data with the IC card 764. More specifically, the recording/reproducing section 762 of the apparatus 760 gives a command to the data-receiving/transmitting section 765 of the IC card 764, as shown in FIG. 59, in order to red the data signal recorded in the IC card 764. In the IC card 764, the control circuit 805 reads data from the memory card 806 in accordance with the command. The data is supplied to the modulator 807. The modulator 807 modulates the data, generating a modulated signal. The modulated signal is supplied to the amplifier 808. The amplifier 808 amplifies the signal, thus driving the antenna 801. The antenna 801 transmits the signal to the recording/reproducing section 762 of the recording/reproducing apparatus 760. In the recording/reproducing section 762, the antenna 792 receives the signal and supplies it to the amplifier 796 via the protection circuit 795 as is illustrated in FIG. 57. The amplifier 796 amplifies the signal, which is supplied to the demodulator 797. The demodulator 797 detects the signal, thus reproducing the data signal. The data signal is supplied to the CPU 798 through the interface circuit 799.

To record the data signal in the IC card 764, the CPU 798 supplies the data signal to the modulator 793 through the interface circuit 799 as is illustrated in FIG. 57. The modulator 793 modulates a carrier with the data signal in the prescribed modulation scheme, generating a modulated signal. The modulated signal is supplied to the amplifier 794. The amplifier 794 amplifies the modulated signal, thus driving the antenna 792, which transmits the modulated signal to the data-receiving/transmitting section 765 of the IC card 764. In the data-receiving/transmitting section 765 shown in FIG. 59, the antenna 801 receives the signal and supplies the same to the amplifier 803 via the protection circuit 802. The amplifier 803 amplifies the signal, which is supplied to the demodulator 804. The demodulator 804 detects the signal, thus generating a data signal. The data signal is supplied to the control circuit 805. The control circuit 805 performs a control in order to record the data signal in the memory 806. The data signal is thereby recorded into the memory 806.

In the recording/reproducing apparatus 760 according to the embodiment described above, IC cards 764 are stored in the storage unit 761, arranged around the center thereof. Hence, more IC cards can be held in the apparatus 760 than in the recording/reproducing apparatus 20 described above. The user need not insert or pull IC cards, one by one, into and from the recording/reproducing apparatus 760. The apparatus 760 is therefore user-friendly.

As indicated above, data is exchanged by radio between the IC card 764 and the recording/reproducing apparatus 760. If the IC card 764 is replaced by an IC card 1 of contact type, it suffices to replace the recording/reproducing section 762 with the connector 651 described above and to employ a transport mechanism that conveys the IC card 1 between the card-holding groove 773 and the connector 651. The number of IC cards 764 than can be stored in the storage unit 761 is not limited to 100. Further, two or more recording/reproducing section 762 may be provided to exchange data with two or more IC cards 764 at a time. In this case, data dubbing can be accomplished.

Industrial Applicability

In an apparatus for recording and/or reproducing data in and/or from IC cards, according to this invention, a plurality of IC cards are held in the main body of the apparatus, each in such a position that the label on it can be seen. It is therefore easy for the user to know what is recorded in each IC card held in the main body. IC cards may be held one above another, in the main body. In this case, the card holding section can be small. Since the card holding section can hold many IC cards, the management of IC cards is easy to perform. Further, the IC cards can be easily moved to the insertion/removal position, where the labels on them can be seen from outside.

With an apparatus for recording and/or reproducing data in and/or from IC cards, according to this invention, the storage mechanism can hold a plurality of IC cards. The storage mechanism can be provided in the main body of the apparatus. This makes it easy to achieve the management of IC cards. Since the storage mechanism can hold many IC cards, data can be continuously reproduced from the IC cards of different types, which are held in the mechanism. It is also possible to dub the data recorded in an optical disk to the IC cards held in the storage mechanism. Thus, simple operation suffices to record and reproduce data in and from IC cards. The apparatus is therefore user-friendly.

In an apparatus for recording and/or reproducing data in and/or from IC cards, according to this invention, a plurality of holding members, each holding an IC card, can be arranged, one above another, in the receptacle. This renders unnecessary for the user to replace the IC cards, one by one, with others. The apparatus is therefore user-friendly.

In an apparatus for recording and/or reproducing data in and/or from IC cards, according to this invention, a number of IC cards can be held in the storage unit. Hence, the user need not replace the IC cards, one by one, with others. This makes the apparatus user-friendly.

1. An apparatus for recording and/or reproducing data in and/or from memory cards used as recording media, each shaped like a plate and incorporating a memory, said apparatus comprising:
storage means provided in the main body of the apparatus, for storing a plurality of memory cards shaped like a plate, incorporating a memory, and having a label, each so positioned that a part of the label is seen from outside the apparatus; and
transmitting/receiving means for transmitting and receiving data from and to the plurality of memory cards stored in the storage means.

2. An apparatus for recording and/or reproducing data in and/or from memory cards used as recording media, each shaped like a plate and incorporating a memory, said apparatus comprising:
a storage section configured to store a plurality of memory cards, each shaped like a plate and incorporating a memory;
a writing/reading section configured to write and read data into and from the memory cards stored in the storage section; and
transport means for moving the storage section and the writing/reading section relative to each other, thereby to set the writing/reading section at a position where data can be written and read into and from the memory cards stored in the storage section.

3. An apparatus for recording and/or reproducing data in and/or from memory cards used as recording media, each shaped like a plate and incorporating a memory, said apparatus comprising:
a plurality of storage means provided on any surface of the main body of the apparatus, for storing a plurality of memory cards shaped like a plate and each incorporating a memory and having a label, each so positioned that a part of the label is seen from outside the apparatus; and
transmitting/receiving means provided in each of the storage means and configured to transmit and receive data from and to the memory card stored in the storage means.

4. The recording and/or reproducing apparatus according to claim 3, further comprising:
transport means for moving the storage means between an insertion/removal position where the memory cards are inserted and removed into and from the storage means, and a writing/reading position where data is written and read into and from the memory cards; and
a plurality of grooves made in any surface of the main body of the apparatus, for receiving the storage means, respectively, that can be moved by the transport means.

5. The recording and/or reproducing apparatus according to claim 4, further comprising:
holding means having a holding member and a cam section and configured to holding the memory cards stored in the storage means, said holding member designed to rotate between a support position where the holding member supports the memory cards and a non-support position where the holding member does not support the memory card, and said cam section provided on the main body of the apparatus and designed to rotate the holding member to the support position when the storage means moves to the writing/reading position.

6. The recording and/or reproducing apparatus according to claim 5, wherein the memory cards are substantially rectangular plates, each having a terminal at one end, for transmitting and receiving data, each storage means set in the groove and able to move has transmitting/receiving means at one end; an insertion guide section having an inclined surface is further provided at the other end of each storage means; the memory card inserted into the storage means is guided by the inclined surface of the insertion guide means, whereby the terminal at one end is connected to the transmitting/receiving means; and the storage means is moved, along with the memory card, from the insertion/removal position to the writing/reading position as the memory card is further inserted, until the memory card is completely held in the storage means.

7. The recording and/or reproducing apparatus according to claim 3, wherein the storage means are arranged in a matrix pattern.

8. The recording and/or reproducing apparatus according to claim 3, wherein the storage means stores the memory cards in staggered fashion such that each memory card does not cover the label on the memory card located immediately below.

9. The recording and/or reproducing apparatus according to claim 8, wherein a stepwise groove is made in any one surface of the main body and has steps, each holding one storage means, holding the transmitting/receiving means at one end and having an inclined part at the other end; and the memory card inserted into the storage means held in the lowest stage of the stepwise groove is guided along the inclined part to connect the terminal of the memory card to the transmitting/receiving means.

10. The recording and/or reproducing apparatus according to claim 3, further comprising control means for controlling the reading means provided in a memory card connected to the transmitting/receiving means of any storage means, thereby causing the reading means to access an address in the memory incorporated in the memory card, in accordance with a user's instruction, thereby to read the data stored at the address provided in the memory.

11. The recording and/or reproducing apparatus according to claim 10, wherein the control means controls the writing means provided in a memory card connected to the transmitting/receiving means of any storage means, thereby causing the writing means to access an address in the memory incorporated in the memory card, in accordance with a user's instruction, thereby to write the data at the address provided in the memory.

12. The recording and/or reproducing apparatus according to claim 11, wherein the control means transfers a command and an address in the memory, to the memory card via the transmitting/receiving means in accordance with the user's instruction, said command designating the reading or writing of data from or into the memory and said address being one at which the reading or writing of data is to be initiated.

13. The recording and/or reproducing apparatus according to claim 12, wherein detecting means is provided to detect the memory cards stored in said plurality of storage means, setting means is provided to set the order in which the memory cards should be subjected to data reproduction, and the control means controls the memory cards such that the memory cards are accessed in the order set by the setting means, thereby to read data from the memory cards.

14. The recording and/or reproducing apparatus according to claim 13, wherein data-source designating means is provided to designate one of the memory cards stored in the storage means, from which data should be transmitted, and to designate a track stored in the memory provided in the memory card designated, data-destination designating means is provided to designate another of the memory cards stored in the storage means, to which data should be transmitted, and the control means controls the memory cards such that the tracks are read from the memory incorporated in the memory card designated by the data-source designating means and the tracks are written in a vacant region of the memory incorporated in the memory card designated by the data-destination designating means.

15. An apparatus for recording and/or reproducing data in and/or from memory cards used as recording media, each shaped like a plate and incorporating a memory, said apparatus comprising:
a plurality of storage means provided in the main body of the apparatus, for storing a plurality of memory cards shaped like a plate and each incorporating a memory;
transmitting/receiving means provided at one end of the storage means and configured to transmit and receive data from and to the memory cards stored in the storage means; and
support means supporting the storage means, allowing the storage means to rotate between an insertion/removal position where the memory cards are inserted and removed into and from the storage means, and a storage position where the memory cards are held in the storage means.

16. The recording and/or reproducing apparatus according to claim 15, wherein each of the storage means has a recess for holding one end of a memory card shaped like a plate; the transmitting/receiving means has connected terminals provided in the recesses of the storage means and electrically connected to the terminals of the memory cards, thereby to transmit and receive data to and from the memory cards; the support means have support pins, each inserted in a support hole made in a corner of one storage means; and the storage means are mounted on the support pins and rotate such that the major surfaces of the memory cards intersect with the support pins at right angles.

17. The recording and/or reproducing apparatus according to claim 16, wherein each of the storage means holds one end of a memory card, thus exposing the label on the memory card to outside.

18. The recording and/or reproducing apparatus according to claim 16, wherein the main body has notches in the corners of the upper surface, the memory cards stored in the storage means are held in the notches while the storage means remain at the storage position, and the memory cards projects from the notches and the labels on the memory card are seen from outside when the storage means are rotated to the insertion/removal position.

19. The recording and/or reproducing apparatus according to claim 16, wherein a tray section is provided to move the storage means from and into the main body, the support pins of the support means are provided on the tray section, the memory cards held in the storage means project from the tray section and the labels on the memory card are seen from outside when the tray section is ejected and the storage means are rotated to the insertion/removal position.

20. The recording and/or reproducing apparatus according to claim 15, further comprising control means for controlling the reading means provided in a memory card connected to the transmitting/receiving means of any storage means, thereby causing the reading means to access an address in the memory incorporated in the memory card, in accordance with a user's instruction, thereby to read the data stored at the address provided in the memory.

21. The recording and/or reproducing apparatus according to claim 20, wherein the control means controls the writing means provided in a memory card connected to the transmitting/receiving means of any storage means, thereby causing the writing means to access an address in the memory incorporated in the memory card, in accordance with a user's instruction, thereby to write the data at the address provided in the memory.

22. The recording and/or reproducing apparatus according to claim 21, wherein the control means transfers a command and an address in the memory, to the memory card via the transmitting/receiving means in accordance with the user's instruction, said command designating the reading or writing of data from or into the memory and said address being one at which the reading or writing of data is to be initiated.

23. The recording and/or reproducing apparatus according to claim 22, wherein detecting means is provided to detect the memory cards stored in said plurality of storage means, setting means is provided to set the order in which the memory cards should be subjected to data reproduction, and the control means controls the memory cards such that the memory cards are accessed in the order set by the setting means, thereby to read data from the memory cards.

24. The recording and/or reproducing apparatus according to claim 23, wherein data-source designating means is provided to designate one of the memory cards stored in the storage means, from which data should be transmitted, and to designate a track stored in the memory provided in the memory card designated, data-destination designating means is provided to designate another of the memory cards stored in the storage means, to which data should be transmitted, and the control means controls the memory cards such that the tracks are read from the memory incorporated in the memory card designated by the data-source designating means and the tracks are written in a vacant region of the memory incorporated in the memory card designated by the data-destination designating means.

25. An apparatus for recording and/or reproducing data in and/or from memory cards used as recording media, each shaped like a plate and incorporating a memory, said apparatus comprising:
storage means having a receptacle configured to hold the memory cards, each shaped like a plate and incorporating a memory, and having an opening through which the memory cards can be inserted and removed, a support plate provided in the receptacle to move in the direction in which the memory cards are arranged one above another and configured to support the memory cards, a bias member biasing the support plate toward the opening, and a stopper section configured to inhibit the support plate biased by the bias member from moving; and
a holding section holding the storage means and having data-transmitting/receiving means for transmitting and receiving data to and from the transmitting/receiving section provided at one end of each memory card.

26. The recording and/or reproducing apparatus according to claim 25, wherein the receptacle has a transparent window through one side of every memory card held in the receptacle.

27. The recording and/or reproducing apparatus according to claim 25, wherein each storage means has a first opening in one surface, through which to insert and remove an memory card, and a second opening continuous to the first opening, through which to expose the transmitting/receiving section provided at one end of the memory card.

28. The recording and/or reproducing apparatus according to claim 25, wherein each storage means has a first opening in one surface, through which to insert and remove an memory card, and a second opening in another surface, through which to expose the transmitting/receiving section provided at one end of the memory card.

29. The recording and/or reproducing apparatus according to claim 25, further comprising a transport mechanism configured to move each storage means between an insertion/removal position where the memory cards are inserted and removed into and from the storage means, and a storage position where the memory cards are held in the storage means.

30. The recording and/or reproducing apparatus according to claim 29, further comprising a cover that opens and closes the holding section as the storage means is moved.

31. The recording and/or reproducing apparatus according to claim 25, further comprising control means for controlling the reading means provided in a memory card connected to the transmitting/receiving means of any storage means, thereby causing the reading means to access an address in the memory incorporated in the memory card, in accordance with a user's instruction, thereby to read the data stored at the address provided in the memory.

32. The recording and/or reproducing apparatus according to claim 31, wherein the control means controls the writing means provided in a memory card connected to the transmitting/receiving means of any storage means, thereby causing the writing means to access an address in the memory incorporated in the memory card, in accordance with a user's instruction, thereby to write the data at the address provided in the memory.

33. The recording and/or reproducing apparatus according to claim 32, wherein the control means transfers a command and an address in the memory, to the memory card via the transmitting/receiving means in accordance with the user's instruction, said command designating the reading or writing of data from or into the memory and said address being one at which the reading or writing of data is to be initiated.

34. The recording and/or reproducing apparatus according to claim 33, wherein detecting means is provided to detect the memory cards stored in said plurality of storage means, setting means is provided to set the order in which the memory cards should be subjected to data reproduction, and the control means controls the memory cards such that the memory cards are accessed in the order set by the setting means, thereby to read data from the memory cards.

35. The recording and/or reproducing apparatus according to claim 34, wherein data-source designating means is provided to designate one of the memory cards stored in the storage means, from which data should be transmitted, and to designate a track stored in the memory provided in the memory card designated, data-destination designating means is provided to designate another of the memory cards stored in the storage means, to which data should be transmitted, and the control means controls the memory cards such that the tracks are read from the memory incorporated in the memory card designated by the data-source designating means and the tracks are written in a vacant region of the memory incorporated in the memory card designated by the data-destination designating means.

36. An apparatus for recording and/or reproducing data in and/or from memory cards used as recording media, each shaped like a plate and incorporating a memory, said apparatus comprising:
a plurality of holders configured to hold the memory cards, respectively, each shaped like a plate and incorporating a memory;
a holding section in which the holders are provided to hold the memory cards;
a writing/reading section configured to write and read data into and from the memory cards held by the holders; and
transport means for moving the holding section or the writing/reading section such that the memory card held in one holder opposes the writing/reading section.

37. The recording and/or reproducing apparatus according to claim 36, wherein the holding section holds the holders, one above another, in the direction that intersects at right angles with the major surfaces of the memory cards held in the holders, the transport means moves the holding section or the writing/reading section in the direction the holders are held one above another, causing making the memory card held in one holder to oppose the writing/reading section.

38. The recording and/or reproducing apparatus according to claim 37, wherein the writing/reading section has a recess for holding one end of a memory card held in the holder and connection terminals provided in the recess to contact the terminals provided at one end of the memory card inserted, and transport means is provided to move the holder toward the writing/reading section or the writing/reading section toward the holder, thereby to insert one end of the memory card into the recess of the writing/reading section and to connect the terminals at one end of the memory card to the connection terminals.

39. The recording and/or reproducing apparatus according to claim 38, further comprising ejecting means for ejecting one of the holders from the holding section.

40. The recording and/or reproducing apparatus according to claim 38, wherein a transmitting/receiving section is provided at one end of each memory card, for transmitting and receiving data to and from the writing/reading section; the holding section has a plurality of grooves arranged in a circumferential direction, said grooves serving as the holders, holding the memory cards in such position that the receiving/transmitting sections lie near an inner periphery and the major surfaces of the memory cards oppose one another; the receiving/transmitting section of each memory card is located at a center part of the holding section; and the transport means rotates the holding means or the writing/reading section, causing the memory card held in one groove to oppose the writing/reading section.

41. The recording and/or reproducing apparatus according to claim 36, further comprising control means for controlling the transport means in accordance with a user's instruction, such that the transport means moves the writing/reading section or the memory card held in any holder, thereby causing the memory card to oppose the writing/reading section, and that writing/reading section accesses an address in the memory incorporated in the memory card, thereby to read the data stored at the address provided in the memory.

42. The recording and/or reproducing apparatus according to claim 41, wherein the control means controls the transport means in accordance with a user's instruction, such that the transport means moves the writing/reading section or the memory card held in any holder, thereby causing the memory card to oppose the writing/reading section, and that writing/reading section accesses an address in the memory incorporated in the memory card, thereby to write data at the address provided in the memory.

43. The recording and/or reproducing apparatus according to claim 42, wherein the control means transfers a command and an address in the memory, to the memory card via the writing/reading section in accordance with the user's instruction, said command designating the reading or writing of data from or into the memory and said address being one at which the reading or writing of data is to be initiated.

44. The recording and/or reproducing apparatus according to claim 43, wherein detecting means is provided to detect the memory cards stored in a plurality of storage means, setting means is provided to set the order in which the memory cards should be subjected to data reproduction, and the control means controls the memory cards such that the memory cards are accessed in the order set by the setting means, thereby to read data from the memory cards.

45. The recording and/or reproducing apparatus according to claim 44, wherein data-source designating means is provided to designate one of the memory cards stored in the holders, from which data should be transmitted, and to designate a track stored in the memory provided in the memory card designated, data-destination designating means is provided to designate another of the memory cards stored in the holders, to which data should be transmitted, and the control means controls the writing/reading section such that the tracks are read from the memory incorporated in the memory card designated by the data-source designating means and the tracks are written in a vacant region of the memory incorporated in the memory card designated by the data-destination designating means.
